(19) United States
(12) Patent Application Publication
(10) Pub. No.: US 2022/0179315 A1
(43) Pub. Date: Jun. 9, 2022

(54) RESIST COMPOSITION AND METHOD OF FORMING RESIST PATTERN

(71) Applicant: TOKYO OHKA KOGYO CO., LTD., Kawasaki-shi (JP)

(72) Inventors: Yasuo SOMEYA, Kawasaki-shi (JP); Takaaki KAIHO, Kawasaki-shi (JP); Minoru ADEGAWA, Kawasaki-shi (JP)

(21) Appl. No.: 17/455,823

(22) Filed: Nov. 19, 2021

(30) Foreign Application Priority Data
Dec. 2, 2020 (JP) 2020-200268

(51) Int. Cl. G03F 7/039; G03F 7/004; G03F 7/16; G03F 7/38; G03F 7/40; G03F 7/32; G03F 7/20

(52) U.S. Cl. CPC G03F 7/0392; G03F 7/0045; G03F 7/162; G03F 7/2006; G03F 7/40; G03F 7/322; G03F 7/38

(57) ABSTRACT

A resist composition containing a compound represented by General Formula (d1-1) or a compound represented by General Formula (d1-2) and containing a polymeric compound (A01) having a constitutional unit (a01) represented by General Formula (a0-1), a constitutional unit (a02) represented by General Formula (a0-2), and a constitutional unit (a03) represented by General Formula (a0-3) wherein, Ra⁰¹ represents a lactone-containing cyclic group having a cyano group or the like. Xaa⁰ represents a group that forms a monocyclic alicyclic hydrocarbon group together with Yaa⁰, and Xab⁰ is a group that forms a monocyclic alicyclic hydrocarbon group together with Yab⁰

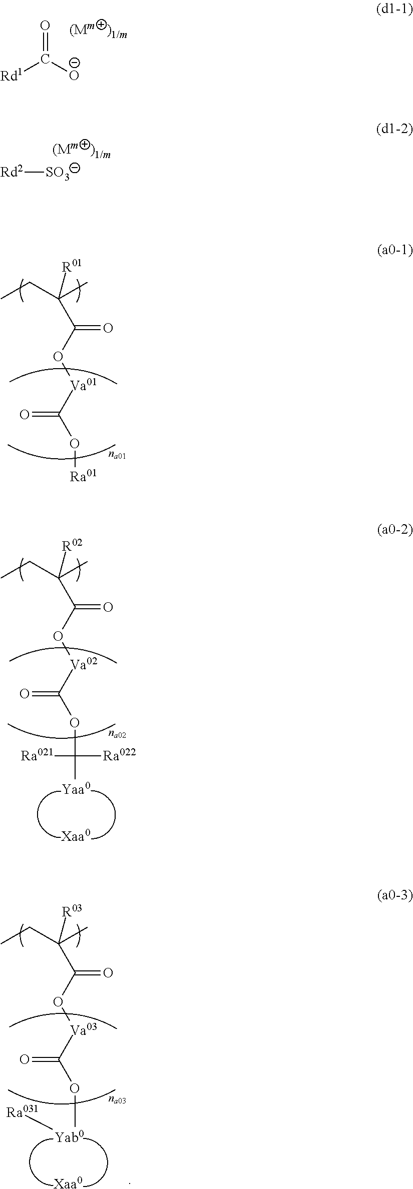

### BACKGROUND OF THE INVENTION

### Field of the Invention

The present invention relates to a resist composition and a method of forming a resist pattern.

Priority is claimed on Japanese Patent Application No. 2020-200268, filed on Dec. 2, 2020, the content of which is incorporated herein by reference.

### Description of Related Art

In recent years, in the production of semiconductor elements and liquid crystal display elements, advances in lithography techniques have led to rapid progress in the field of pattern fining. Typically, these pattern fining techniques involve shortening the wavelength (increasing the energy) of the light source for exposure.

Resist materials for use with these types of light sources for exposure require lithography characteristics such as sensitivity to these light sources for exposure and resolution capable of reproducing a fine-sized pattern.

As a resist material that satisfies these requirements, in the related art, a chemically amplified resist composition containing a base material component that exhibits changed solubility in a developing solution under action of acid, and an acid generator component that generates acid upon exposure has been used.

In the chemically amplified resist composition, a resin having a plurality of constitutional units is generally used in order to improve the lithography characteristics.

For example, Patent Document 1 discloses a resist composition in which a resin having a plurality of constitutional units such as a constitutional unit having a lactone group is combined with a compound that generates acid upon irradiation with active light or radiation. It is described that resist pattern collapse is suppressed, profile deterioration is small, and elution into an immersion liquid is suppressed in liquid immersion lithography in a case where the above resist composition is used.

### CITATION LIST

[Patent Document]

[Patent Document 1] Japanese Unexamined Patent Application, First Publication No. 2009-271253

### SUMMARY OF THE INVENTION

Recently, with further advances in lithography techniques, rapid progress in the field of pattern fining is being achieved together with the expansion of application fields.

In a case of trying to form a fine pattern (for example, a fine line and space pattern) on a substrate using a resist composition in the related art, the uniformity of a space width (the roughness reduction property) in a pattern is still insufficient to satisfy the requirements. In addition, resolution such as pattern collapse also becomes problematic, and the collapse margin is still insufficient to satisfy the requirements.

Furthermore, the finer the pattern is, the more unexposed portions of the resist film are dissolved by the development (the reduction of the developed film), and the level of film remaining in pattern easily decreases.

The present invention has been made in consideration of the above circumstances, and an object of the present invention is to provide a resist composition having a good roughness reduction property, a good collapse margin, and good film remaining in pattern, and a method of forming a resist pattern using the resist composition.

In order to achieve the above-described object, the present invention employs the following configurations.

That is, the first aspect of the present invention is a resist composition that generates acid upon exposure and exhibits changed solubility in a developing solution under action of acid, where the resist composition contains a resin component (A1) exhibits changed solubility in a developing solution under action of acid and one or more compounds (D1) selected from the group consisting of a compound represented by General Formula (d1-1) and a compound represented by General Formula (d1-2), where the resin component (A1) contains a polymeric compound (A01) having a constitutional unit (a01) represented by General Formula (a0-1), a constitutional unit (a02) represented by General Formula (a0-2), and a constitutional unit (a03) represented by General Formula (a0-3).

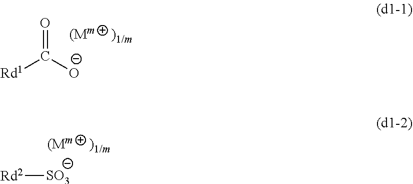

[In the formulae, Rd¹ and Rd² each independently represent a cyclic group which may have a substituent, a chain alkyl group which may have a substituent, or a chain alkenyl group which may have a substituent. However, a carbon atom adjacent to a S atom in Rd² in General Formula (d1-2) has no fluorine atom bonded thereto. m represents an integer of 1 or more, and each M^{m+} independently represents an m-valent organic cation.]

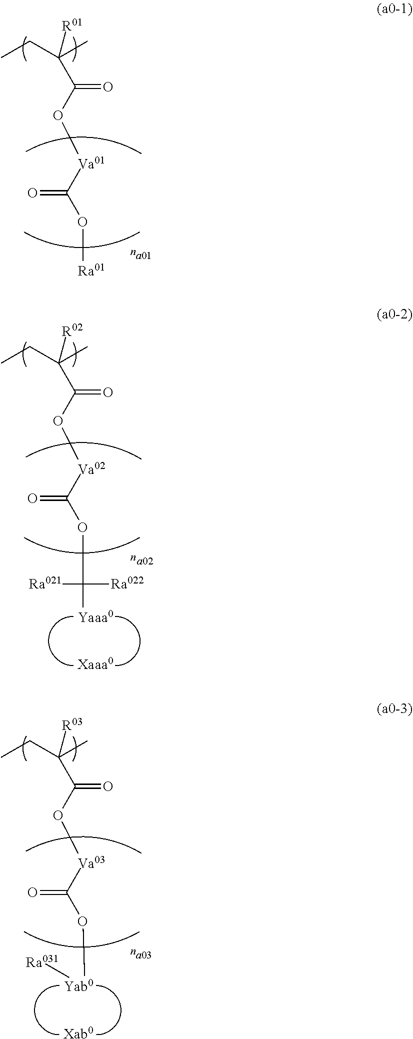

[In General Formula (a0-1), R⁰¹ represents a hydrogen atom, an alkyl group having 1 to 5 carbon atoms, or a halogenated alkyl group having 1 to 5 carbon atoms. Va⁰¹ represents a divalent linking group. nₐ₀₁ represents an integer in a range of 0 to 2. Ra⁰¹ represents a lactone-containing cyclic group having one or more substituents selected from the group consisting of a halogen atom, a carboxy group, an acyl group, a nitro group, and a cyano group. The lactone-containing cyclic group may have a substituent other than the substituents in the above group.

In General Formula (a0-2), R⁰² represents a hydrogen atom, an alkyl group having 1 to 5 carbon atoms, or a halogenated alkyl group having 1 to 5 carbon atoms. Va⁰² represents a divalent linking group. nₐ₀₂ represents an integer in a range of 0 to 2. Ra⁰²¹ and Ra⁰²² each independently represent a chain alkyl group. Yaa⁰ represents a carbon atom. Xaa⁰ represents a group that forms a monocyclic alicyclic hydrocarbon group together with Yaa⁰. Part or all hydrogen atoms contained in this monocyclic alicyclic hydrocarbon group may be substituted.

In General Formula (a0-3), R⁰³ represents a hydrogen atom, an alkyl group having 1 to 5 carbon atoms, or a halogenated alkyl group having 1 to 5 carbon atoms. Va⁰³ represents a divalent linking group. nₐ₀₃ represents an integer in a range of 0 to 2. Ra⁰³¹ represents a chain alkyl group. Yab⁰ represents a carbon atom. Xab⁰ represents a group that forms a monocyclic alicyclic hydrocarbon group together with Yab⁰. Part or all hydrogen atoms contained in this monocyclic alicyclic hydrocarbon group may be substituted.]

The second aspect of the present invention is a method of forming a resist pattern, including a step of forming a resist film on a support using the resist composition according to the first aspect, a step of exposing the resist film, and a step of developing the exposed resist film to form a resist pattern.

According to the present invention, it is possible to provide a resist composition having good roughness reduction property, good collapse margin, and good film remaining in pattern, and a method of forming a resist pattern using the resist composition.

### DETAILED DESCRIPTION OF THE INVENTION

In the present specification and the scope of the present patent claims, the term “aliphatic” is a relative concept used with respect to the term “aromatic” and defines a group or compound that has no aromaticity.

The “alkyl group” contains a monovalent saturated hydrocarbon group that is linear, branched, or cyclic, unless otherwise specified. The same applies to the alkyl group in an alkoxy group.

The “alkylene group” contains a divalent saturated hydrocarbon group that is linear, branched, or cyclic, unless otherwise specified.

Examples of the “halogen atom” include a fluorine atom, a chlorine atom, a bromine atom, and an iodine atom.

The “constitutional unit” means a monomer unit (monomeric unit) that contributes to the formation of a polymeric compound (a resin, a polymer, or a copolymer).

In a case where “may have a substituent” is described, both of a case where a hydrogen atom (—H) is substituted with a monovalent group and a case where a methylene group (—CH₂—) is substituted with a divalent group are included.

The “exposure” is used as a general concept that includes irradiation with any form of radiation.

The “acid decomposable group” indicates a group having an acid decomposability, in which at least parts of bonds in the structure of the acid decomposable group can be cleaved under action of acid.

Examples of the acid decomposable group having a polarity that is increased under action of acid include a group that decomposes under action of acid to generate a polar group.

Examples of the polar group include a carboxy group, a hydroxyl group, an amino group, and a sulfo group (—SO₃H).

More specific examples of the acid decomposable group include a group obtained by protecting the above polar group with an acid dissociable group (for example, a group obtained by protecting a hydrogen atom of the OH-containing polar group with an acid dissociable group).

The “acid dissociable group” indicates both (i) a group having an acid dissociability, in which a bond between the acid dissociable group and an atom adjacent to the acid dissociable group can be cleaved under action of acid; and (ii) a group in which some bonds are cleaved under action of acid, and then a decarboxylation reaction occurs, thereby cleaving the bond between the acid dissociable group and the atom adjacent to the acid dissociable group.

It is necessary that the acid dissociable group that constitutes the acid decomposable group is a group that exhibits a polarity lower than the polarity of the polar group generated by the dissociation of the acid dissociable group. Accordingly, in a case where the acid dissociable group is dissociated under action of acid, a polar group that exhibits a polarity higher than the polarity of the acid dissociable group is generated, thereby increasing the polarity. As a result of the above, the polarity of the entire component (A1) is increased. By the increase in the polarity, the solubility in a developing solution relatively changes. The solubility is increased in a case where the developing solution is an alkali developing solution, whereas the solubility is decreased in a case where the developing solution is an organic developing solution.

The “base material component” is an organic compound having a film forming ability. The organic compounds used as the base material component are roughly classified into a non-polymer and a polymer. As the non-polymer, those having a molecular weight of 500 or more and less than 4,000 are usually used. Hereinafter, the “low molecular weight compound” refers to a non-polymer having a molecular weight of 500 or more and less than 4,000. As the polymer, those having a molecular weight of 1,000 or more are usually used. Hereinafter, the “resin”, the “polymeric compound”, or the “polymer” refers to a polymer having a molecular weight of 1,000 or more. As the molecular weight of the polymer, a polystyrene-equivalent weight average molecular weight determined by gel permeation chromatography (GPC) is used.

The “constitutional unit derived from” means a constitutional unit that is formed by the cleavage of a multiple bond between carbon atoms, for example, an ethylenic double bond.

In the acrylic acid ester, the hydrogen atom bonded to the carbon atom at the α-position may be substituted with a substituent. The substituent (RM) that is substituted for the hydrogen atom bonded to the carbon atom at the α-position is an atom other than a hydrogen atom, or a group. Further, an itaconic acid diester in which the substituent (R′) is substituted with a substituent having an ester bond or an α-hydroxyacryl ester in which the substituent (R′) is substituted with a hydroxyalkyl group or a group obtained by modifying a hydroxyl group of the hydroxyalkyl group can be mentioned as the acrylic acid ester. The carbon atom at the α-position of the acrylic acid ester indicates the carbon atom bonded to the carbonyl group of acrylic acid, unless otherwise specified.

Hereinafter, an acrylic acid ester in which the hydrogen atom bonded to the carbon atom at the α-position is substituted with a substituent is also referred to as the α-substituted acrylic acid ester”.

The “derivative” includes those in which the hydrogen atom at the α-position of an object compound has been substituted with other substituents such as an alkyl group and a halogenated alkyl group; and derivatives thereof. Examples of the derivative thereof include a derivative obtained by substituting the hydrogen atom of a hydroxyl group of an object compound in which a hydrogen atom at the α-position may be substituted with a substituent, with an organic group; and a derivative obtained by bonding a substituent other than a hydroxyl group to an object compound in which a hydrogen atom at the α-position may be substituted with a substituent. The α-position refers to the first carbon atom adjacent to the functional group unless otherwise specified.

Examples of the substituent that is substituted for the hydrogen atom at the α-position of hydroxystyrene include the same one as R^{αx}.

In the present specification and the scope of the present patent claims, an asymmetric carbon may be present or enantiomers or diastereomers may be present depending on the structure represented by the chemical formula. In that case, these isomers are represented by one chemical formula. These isomers may be used alone or in the form of a mixture.

(Resist Composition)

The resist composition according to the present embodiment is a resist composition that generates acid upon exposure and exhibits changed solubility in a developing solution under action of acid.

Such a resist composition contains a base material component (A) (hereinafter, also referred to as a “component (A)”) that exhibits changed solubility in a developing solution under action of acid, and one or more compounds (D1) (hereinafter, also referred to as a “compound (D1)”) selected from the group consisting of a compound represented by General Formula (d1-1) and a compound represented by General Formula (d1-2).

In a case where a resist film is formed using the resist composition according to the present embodiment and the formed resist film is subjected to selective exposure, an acid is generated at exposed portions of the resist film, and the generated acid acts on the component (A) to change the solubility of the component (A) in a developing solution, whereas the solubility of the component (A) in the developing solution is not changed at unexposed portions of the resist film, thereby generating the difference in solubility in the developing solution between exposed portions and unexposed portions of the resist film.

The resist composition according to the present embodiment may be a positive-tone resist composition or a negative-tone resist composition.

Further, in the formation of a resist pattern, the resist composition according to the present embodiment can be applied to an alkali developing process using an alkali developing solution in the developing treatment, or a solvent developing process using a developing solution containing an organic solvent (organic developing solution) in the developing treatment.

That is, the resist composition according to the present embodiment is a “positive-tone resist composition for an alkali developing process” that forms a positive-tone resist pattern in an alkali developing process, and a “negative-tone resist composition for a solvent developing process” that forms a negative-tone resist pattern in a solvent developing process.

<Component (A)>

In the resist composition according to the present embodiment, the component (A) contains a resin component (A1) (hereinafter, also referred to as “component (A1)”) that exhibits changed solubility in a developing solution under action of acid. The resin component (A1) contains a polymeric compound (A01) having a constitutional unit (a01) represented by General Formula (a0-1), a constitutional unit (a02) represented by General Formula (a0-2), and a constitutional unit (a03) represented by General Formula (a0-3).

As the component (A), at least the component (A1) is used, and at least other polymeric compound and a low molecular weight compound may be used in combination with the component (A1).

In the resist composition according to the present embodiment, the component (A) may be used alone or in a combination of two or more kinds thereof.

In regard to component (A1)

The component (A1) has the constitutional unit (a01), the constitutional unit (a02), and the constitutional unit (a03).

<<Constitutional Unit (a01)>>

The constitutional unit (a01) is a constitutional unit derived from a compound represented by General Formula (a0-1).

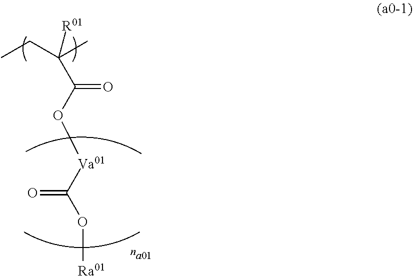

[In General Formula (a0-1), R⁰¹ represents a hydrogen atom, an alkyl group having 1 to 5 carbon atoms, or a halogenated alkyl group having 1 to 5 carbon atoms. Va⁰¹ represents a divalent linking group. nₐ₀₁ represents an integer in a range of 0 to 2. Ra⁰¹ represents a lactone-containing cyclic group having one or more substituents selected from the group consisting of a halogen atom, a carboxy group, an acyl group, a nitro group, and a cyano group. The lactone-containing cyclic group may have a substituent other than the substituents in the above group.

In General Formula (a0-1), R⁰¹ represents a hydrogen atom, an alkyl group having 1 to 5 carbon atoms, or a halogenated alkyl group having 1 to 5 carbon atoms.

The alkyl group having 1 to 5 carbon atoms as R⁰¹ is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group.

The halogenated alkyl group having 1 to 5 carbon atoms as R⁰¹ is a group obtained by substituting part or all hydrogen atoms of the above-described alkyl group having 1 to 5 carbon atoms with a halogen atom. Examples of the halogen atom include a fluorine atom, a chlorine atom, a bromine atom, and an iodine atom, and a fluorine atom is particularly preferable.

R⁰¹ is preferably a hydrogen atom, an alkyl group having 1 to 5 carbon atoms, or a fluorinated alkyl group having 1 to 5 carbon atoms, and in terms of industrial availability, is more preferably a hydrogen atom or a methyl group, and still more preferably a methyl group.

In General Formula (a0-1), Va⁰¹ represents a divalent hydrocarbon group which may have an ether bond.

The divalent hydrocarbon group as Va⁰¹ may be an aliphatic hydrocarbon group or an aromatic hydrocarbon group.

The aliphatic hydrocarbon group as the divalent hydrocarbon group represented by Va⁰¹ may be saturated or unsaturated. In general, it is preferable that the aliphatic hydrocarbon group is saturated.

More specific examples of the aliphatic hydrocarbon group include a linear or branched aliphatic hydrocarbon group and an aliphatic hydrocarbon group containing a ring in the structure thereof.

The linear aliphatic hydrocarbon group described above preferably has 1 to 10 carbon atoms, more preferably 1 to 6 carbon atoms, still more preferably 1 to 4 carbon atoms, and most preferably 1 to 3 carbon atoms.

Specific examples of the linear aliphatic hydrocarbon group include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group described above preferably has 2 to 10 carbon atoms, more preferably 3 to 6 carbon atoms, still more preferably 3 or 4 carbon atoms, and most preferably 3 carbon atoms.

Specific examples the branched aliphatic hydrocarbon group include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

Examples of the aliphatic hydrocarbon group containing a ring in the structure thereof include an alicyclic hydrocarbon group (a group obtained by removing two hydrogen atoms from an aliphatic hydrocarbon ring), a group obtained by bonding an alicyclic hydrocarbon group to the terminal of a linear or branched aliphatic hydrocarbon group, and a group obtained by interposing an alicyclic hydrocarbon group in a linear or branched aliphatic hydrocarbon group. Examples of the linear or branched aliphatic hydrocarbon group include the same one as the above-described linear aliphatic hydrocarbon group or the above-described branched aliphatic hydrocarbon group.

The alicyclic hydrocarbon group preferably has 3 to 20 carbon atoms and more preferably 3 to 12 carbon atoms.

The alicyclic hydrocarbon group may be monocyclic or polycyclic. The monocyclic alicyclic hydrocarbon group is preferably a group obtained by removing two hydrogen atoms from a monocycloalkane. The monocycloalkane preferably has 3 to 6 carbon atoms, and specific examples thereof include cyclopentane and cyclohexane. The polycyclic alicyclic hydrocarbon group is preferably a group obtained by removing two hydrogen atoms from a polycycloalkane, and the polycycloalkane is preferably a group having 7 to 12 carbon atoms. Specific examples thereof include adamantane, norbornane, isobornane, tricyclodecane, and tetracyclododecane.

The aromatic hydrocarbon group as the divalent hydrocarbon group represented by Va⁰¹ is a hydrocarbon group having an aromatic ring.

Such an aromatic hydrocarbon group preferably has 3 to 30 carbon atoms, more preferably 5 to 30 carbon atoms, still more preferably 5 to 20 carbon atoms, particularly preferably 6 to 15 carbon atoms, and most preferably 6 to 10 carbon atoms. Here, the number of carbon atoms in a substituent is not included in the number of carbon atoms.

Specific examples of the aromatic ring which contained in the aromatic hydrocarbon group include: aromatic hydrocarbon rings such as benzene, biphenyl, fluorene, naphthalene, anthracene, and phenanthrene; and aromatic heterocyclic rings in which part of carbon atoms constituting the above-described aromatic hydrocarbon rings have been substituted with hetero atoms. Examples of the hetero atom in the aromatic heterocyclic rings include an oxygen atom, a sulfur atom, and a nitrogen atom.

Specific examples of the aromatic hydrocarbon group include: a group obtained by removing two hydrogen atoms from the above-described aromatic hydrocarbon ring (an arylene group); and a group obtained by substituting one hydrogen atom of a group (an aryl group) formed by removing one hydrogen atom from the aromatic hydrocarbon ring, with an alkylene group (for example, a group formed by further removing one hydrogen atom from an aryl group of an arylalkyl group such as a benzyl group, a phenethyl group, a 1-naphthylmethyl group, a 2-naphthylmethyl group, a 1-naphthylethyl group, or a 2-naphthylethyl group). The alkylene group (an alkyl chain in the arylalkyl group) preferably has 1 to 4 carbon atoms, more preferably 1 or 2 carbon atoms, and particularly preferably 1 carbon atom.

In General Formula (a0-1), nₐ₀₁ represents an integer in a range of 0 to 2, preferably 0 or 1, and more preferably 0.

In General Formula (a0-1), Ra⁰¹ represents a lactone-containing cyclic group (hereinafter, also referred to as a “lactone-containing cyclic group having a cyano group or the like”) having one or more substituents selected from the group consisting of a halogen atom, a carboxy group, an acyl group, a nitro group, and a cyano group.

The “lactone-containing cyclic group” indicates a cyclic group that contains a ring (lactone ring) containing a —O—C(═O)— in the ring skeleton. In a case where the lactone ring is counted as the first ring and the group contains only the lactone ring, the group is referred to as the monocyclic group. Further, in a case where the group has other ring structures, the group is referred to as the polycyclic group regardless of the structures. The lactone-containing cyclic group may be a monocyclic group or a polycyclic group.

Preferred examples of the lactone-containing cyclic group having a cyano group or the like, as Ra⁰¹, include a group represented by General Formula (Ra0-1).

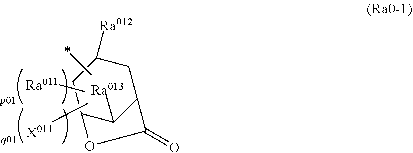

[In the formula, Ra⁰¹² and Ra⁰¹³ each independently represent a hydrogen atom, an alkyl group having 1 to 5 carbon atoms, an alkoxy group, or an alkylthio group, or Ra⁰¹² and Ra⁰¹³ may be bonded to each other to form an alkylene group having 1 to 6 carbon atoms, which may contain an oxygen atom or sulfur atom, an ether bond, or a thioether bond, X⁰¹¹ represents a halogen atom, a carboxy group, an acyl group, a nitro group, or a cyano group. R^{a011} represents an alkyl group having 1 to 6 carbon atoms, which may have a halogen atom, a hydroxyalkyl group having 1 to 6 carbon atoms, in which a hydroxy group moiety may be protected by a protecting group and which may contain a halogen atom, a carboxy group which may form a salt, or a substituted oxycarbonyl group. p₀₁ represents an integer in a range of 0 to 8, and q₀₁ represents an integer in a range of 1 to 9. However, the following is satisfied, p₀₁+q₀₁≤9. In a case where two or more X⁰¹¹'s are present, a plurality of X⁰¹¹'s may be the same or different from each other. In a case where two or more Ra⁰¹¹'s are present, a plurality of Ra⁰¹¹'s may be the same or different from each other. In a case where Ra⁰¹² and Ra⁰¹³ are bonded to each other to form an alkylene group having 1 to 6 carbon atoms, which may contain an oxygen atom or a sulfur atom, X⁰¹¹ and Ra⁰¹¹ may be each independently present as a substituent that is substituted for a hydrogen atom of the alkylene group having 1 to 6 carbon atoms. * represents a bonding site to which an oxygen atom in General Formula (a0-1) is bonded.]

In General Formula (Ra0-1) Ra⁰¹² and Ra⁰¹³ each independently represent a hydrogen atom, an alkyl group having 1 to 5 carbon atoms, an alkoxy group, or an alkylthio group, or Ra⁰¹² and Ra⁰¹³ may be bonded to each other to form an alkylene group having 1 to 6 carbon atoms, which may contain an oxygen atom or sulfur atom, an ether bond, or a thioether bond.

The alkyl group having 1 to 5 carbon atoms is preferably a linear or branched alkyl group, and specific examples thereof include a methyl group, an ethyl group, a propyl group, an isopropyl group, an n-butyl group, an isobutyl group, a tert-butyl group, a pentyl group, an isopentyl group, and a neopentyl group.

The alkoxy group having 1 to 5 carbon atoms is preferably a linear or branched alkoxy group, and specific examples thereof include a group formed by linking the alkyl group mentioned as the alkyl group as Ra⁰¹² and Ra⁰¹³ to an oxygen atom (—O—).

The alkylthio group having 1 to 5 carbon atoms preferably has 1 to 4 carbon atoms, and specific examples thereof include a methylthio group, an ethylthio group, an n-propylthio group, an iso-propylthio group, an n-butylthio group, and a tert-butylthio group.

The alkylene group having 1 to 6 carbon atoms, which is formed by bonding Ra⁰¹² and Ra⁰¹³ to each other, is preferably a linear or branched alkylene group, and examples thereof include a methylene group, an ethylene group, a trimethylene group, and a propylene group. Specific examples of the case where the alkylene group contains an oxygen atom or a sulfur atom include a group obtained by interposing —O— or —S— in the terminal of the alkylene group or between the carbon atoms of the alkylene group, and examples thereof include —O—CH₂—, —CH₂—O—CH₂—, —S—CH₂—, and —CH₂—S—CH₂—.

The group that is formed by bonding Ra⁰¹² and Ra⁰¹³ to each other is preferably an alkylene group having 1 to 6 carbon atoms or —O—, more preferably an alkylene group having 1 to 6 carbon atoms, still more preferably an alkylene group having 1 to 3 carbon atoms, and particularly preferably a methylene group.

Among the above, in Ra⁰¹² and Ra⁰¹³, it is preferable that Ra⁰¹² and Ra⁰¹³ are bonded to each other to form an alkylene group having 1 to 6 carbon atoms. The alkylene group having 1 to 6 carbon atoms is more preferably an alkylene group having 1 to 3 carbon atoms and still more preferably a methylene group.

In General Formula (Ra0-1), Ra⁰¹¹ represents an alkyl group having 1 to 6 carbon atoms, which may have a halogen atom, a hydroxyalkyl group having 1 to 6 carbon atoms, in which a hydroxy group moiety may be protected by a protecting group and which may have a halogen atom, a carboxy group which may form a salt, or a substituted oxycarbonyl group.

Examples of the alkyl group having 1 to 6 carbon atoms include a methyl group, an ethyl group, an n-propyl group, an isopropyl group, an n-butyl group, an isobutyl group, an s-butyl group, a t-butyl group, a pentyl group, and a hexyl group. Among these, an alkyl group having 1 to 5 carbon atoms is preferable, an alkyl group having 1 to 4 carbon atoms is more preferable, an alkyl group having 1 to 3 carbon atoms is still more preferable, a methyl group or an ethyl group is particularly preferable, and a methyl group is most preferable.

The alkyl group having 1 to 6 carbon atoms may have or may not have a halogen atom. The halogen atom is preferably a fluorine atom or a chlorine atom and more preferably a fluorine atom. Examples of the alkyl group having 1 to 6 carbon atoms and having a halogen atom include a chloroalkyl group such as a chloromethyl group; and a fluoroalkyl group (preferably, a fluoroalkyl group having 1 to 3 carbon atoms) such as a trifluoromethyl group, a 2,2,2-trifluoroethyl group, or a pentafluoroethyl group.

Examples of the hydroxyalkyl group having 1 to 6 carbon atoms include a hydroxymethyl group, a 2-hydroxyethyl group, a 1-hydroxyethyl group, a 3-hydroxypropyl group, a 2-hydroxypropyl group, a 4-hydroxybutyl group, and a 6-hydroxyhexyl group.

The hydroxyalkyl group having 1 to 6 carbon atoms may have or may not have a halogen atom. The halogen atom is preferably a fluorine atom. Examples of the hydroxyalkyl group having 1 to 6 carbon atoms and having a halogen atom include a difluorohydroxymethyl group, a 1,1-difluoro-2-hydroxyethyl group, a 2,2-difluoro-2-hydroxyethyl group, and 1,1,2,2-tetrafluoro-2-hydroxyethyl group.

The hydroxyalkyl group having 1 to 6 carbon atoms, which may have a halogen atom, preferably has 1 to 3 carbon atoms, more preferably 1 or 2 carbon atoms, and still more preferably 1 carbon atom.

The hydroxyalkyl group having 1 to 6 carbon atoms may have or may not have a hydroxy group moiety protected by a protecting group. Examples of the protecting group that protects the hydroxy group moiety include, a group capable of forming an ether bond or an acetal bond together with a methyl group or an oxygen atom constituting a hydroxy group of a methoxymethyl group or the like; and a group capable of forming an ester bond together with an acetyl group or an oxygen atom constituting a hydroxy group of a benzoyl group or the like.

The carboxy group which may form a salt is selected from the group consisting of a carboxy group and a carboxy group forming a salt (salt of the carboxy group). Examples of the carboxy group (the salt of the carboxy group) that forms the above salt include an alkali metal salt of the carboxy group, an alkali earth metal salt of the carboxy group, and a transition metal salt of the carboxy group.

Examples of the substituted oxycarbonyl group include an alkoxycarbonyl group (specifically, an alkyloxycarbonyl group such as a methoxycarbonyl group, an ethoxycarbonyl group, an isopropyloxycarbonyl group, or an n-propoxycarbonyl group; or an alkenyloxycharbonyl group such as a vinyloxycarbonyl group or an arlyloxycarbonyl group) in which an alkoxy group having 1 to 4 carbon atoms is bonded to a carbonyl group, a cycloalkyloxycarbonyl group such as a cyclohexyloxycarbonyl group, and an aryloxycarbonyl group such as a phenyloxycarbonyl group.

In General Formula (Ra0-1), X⁰¹¹ represents a halogen atom, a carboxy group, an acyl group, a nitro group, or a cyano group.

The halogen atom is preferably a fluorine atom.

The acyl group is preferably an acyl group having 1 to 3 carbon atoms, and specific examples thereof include a formyl group, an acetyl group, and a propionyl group.

In General Formula (Ra0-1), X⁰¹¹ is preferably, among the above, a cyano group.

In General Formula (Ra0-1), p₀₁ represents an integer in a range of 0 to 8.

p₀₁ is preferably an integer in a range of 0 to 6, more preferably an integer in a range of 0 to 3, still more preferably 0 or 1, and particularly preferably 0.

In General Formula (Ra0-1), q₀₁ represents an integer in a range of 1 to 9. However, the following is satisfied, p₀₁+q₀₁≤9.

q₀₁ is preferably an integer in a range of 1 to 5, more preferably 1 or 2, and still more preferably 1.

p₀₁ represents an integer in a range of 2 to 8, and in a case where two or more Ra⁰¹¹'s are present, a plurality of Ra⁰¹¹'s may be the same or different from each other.

In a case where q₀₁ represents an integer in a range of 2 to 9 and two or more X⁰¹¹'s are present, a plurality of X⁰¹¹'s may be the same or different from each other.

In a case where Ra⁰¹² and Ra⁰¹³ are bonded to each other to form an alkylene group having 1 to 6 carbon atoms, which may contain an oxygen atom or a sulfur atom, X⁰¹¹ and Ra⁰¹¹ may be each independently present as a substituent that is substituted for a hydrogen atom of the alkylene group having 1 to 6 carbon atoms.

As the lactone-containing cyclic group having a cyano group or the like, as Ra⁰¹, specific examples of the above-described group other than the group represented by General Formula (Ra0-1) include a group obtained by substituting at least one Ra′²¹ of two Ra′²¹'s in groups represented by General Formulae (a2-r-1) to (a2-r-7) with a halogen atom, a carboxy group, an acyl group, a nitro group, or a cyano group; and a group in the groups represented by General Formulae (a2-r-1) to (a2-r-7), which further has, as the substituent, one or more substituents selected from the group consisting of a halogen atom, a carboxy group, an acyl group, a nitro group, and a cyano group.

The constitutional unit (a01) is preferably a constitutional unit represented by General Formula (a01-1).

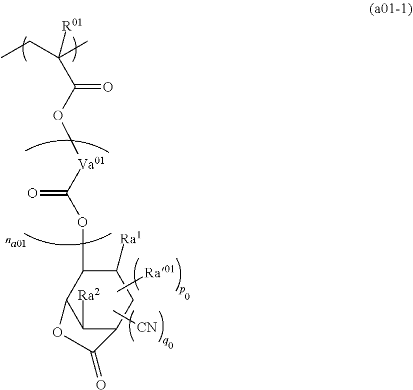

[In General Formula (a01-1), R⁰¹ represents a hydrogen atom, an alkyl group having 1 to 5 carbon atoms, or a halogenated alkyl group having 1 to 5 carbon atoms. Va⁰¹ represents a divalent linking group. nₐ₀₁ represents an integer in a range of 0 to 2. Ra¹ and Ra² each independently represent a hydrogen atom, an alkyl group having 1 to 5 carbon atoms, an alkoxy group, or an alkylthio group, or Ra¹ and Ra² may be bonded to each other to become an alkylene group having 1 to 6 carbon atoms, which may contain an oxygen atom or sulfur atom, or to become an ether bond or a thioether bond. Ra′⁰¹ represents a halogen atom, an alkyl group having 1 to 6 carbon atoms, which may have a halogen atom, a hydroxyalkyl group having 1 to 6 carbon atoms, in which a hydroxy group moiety may be protected by a protecting group and which may have a halogen atom, a carboxy group which may form a salt, or a substituted oxycarbonyl group. p₀ represents an integer in a range of 0 to 8. In a case where two or more Ra′⁰¹'s are present, a plurality of Ra′⁰¹'s may be the same or different from each other. q₀ represents an integer in a range of 1 to 9.]

R⁰¹, Va⁰¹, and nₐ₀₁ in General Formula (a01-1) are each the same as R⁰¹, Va⁰¹, and nₐ₀₁ in General Formula (a0-1).

Examples of Ra¹ and Ra² in General Formula (a01-1) each include the same ones as Ra⁰¹² and Ra⁰¹³ in General Formula (Ra0-1).

Examples of the alkyl group having 1 to 6 carbon atoms, which may have a halogen atom, the hydroxyalkyl group having 1 to 6 carbon atoms, in which a hydroxy group moiety may be protected by a protecting group and which may have a halogen atom, the carboxy group which may form a salt, and the substituted oxycarbonyl group, as Ra′⁰¹ in General Formula (a01-1), each include the same ones as Ra⁰¹¹ in General Formula (Ra0-1).

p₀ in General Formula (a01-1) is an integer in a range of 0 to 8, preferably an integer in a range of 0 to 3, more preferably 0 or 1, and still more preferably 0.

q₀ in General Formula (a01-1) is an integer in a range of 1 to 9, preferably an integer in a range of 1 to 3, more preferably 1 or 2, and still more preferably 1.

The constitutional unit (a01) is more preferably a constitutional unit represented by General Formula (a01-1-1).

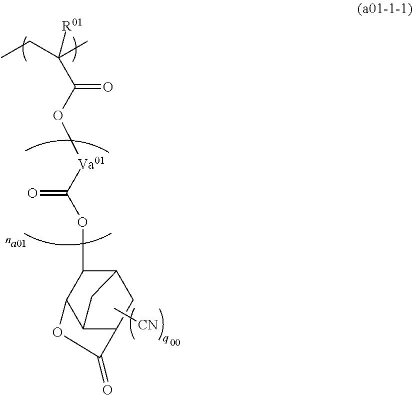

In General Formula (a01-1-1), R⁰¹ represents a hydrogen atom, an alkyl group having 1 to 5 carbon atoms, or a halogenated alkyl group having 1 to 5 carbon atoms. Va⁰¹ represents a divalent linking group. nₐ₀₁ represents an integer in a range of 0 to 2. q₀₀ represents an integer in a range of 1 to 3.

R⁰¹, Va⁰¹, and nₐ₀₁ in General Formula (a01-1-1) are each the same as R⁰¹, Va⁰¹, and nₐ₀₁ in General Formula (a0-1).

In General Formula (a01-1-1), q₀₀ represents an integer of 1 to 3, preferably 1 or 2, and more preferably 1.

Suitable specific examples of the constitutional unit (a01) are as follows.

In each of the formulae shown below, R^{α} represents a hydrogen atom, a methyl group, or a trifluoromethyl group. n_{α} represents an integer in a range of 0 to 2 and is preferably 0 or 1. Ac represents an acetyl group. X represents a halogen atom, a carboxy group, an acyl group, a nitro group, or a cyano group, and is preferably a cyano group.

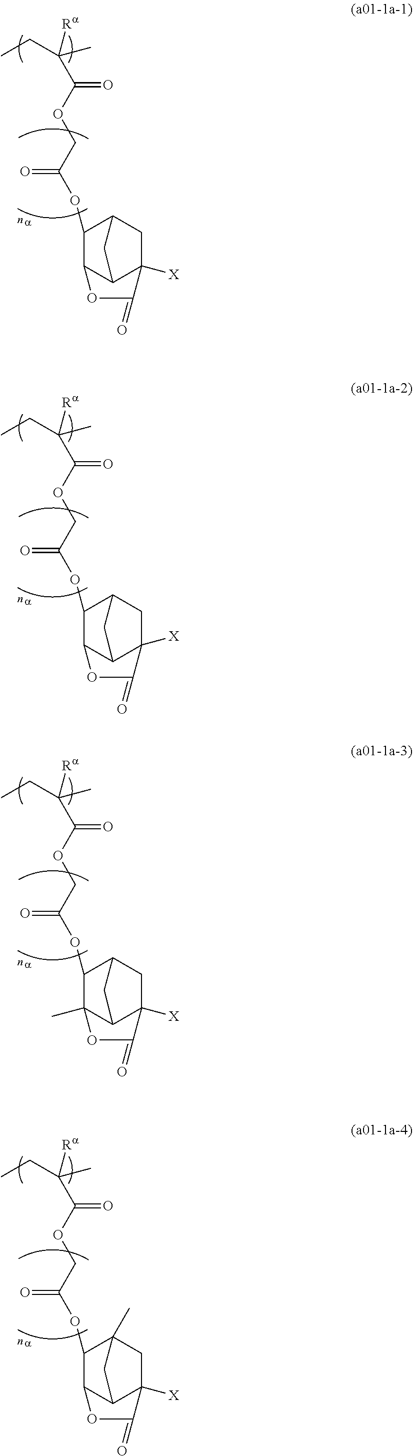

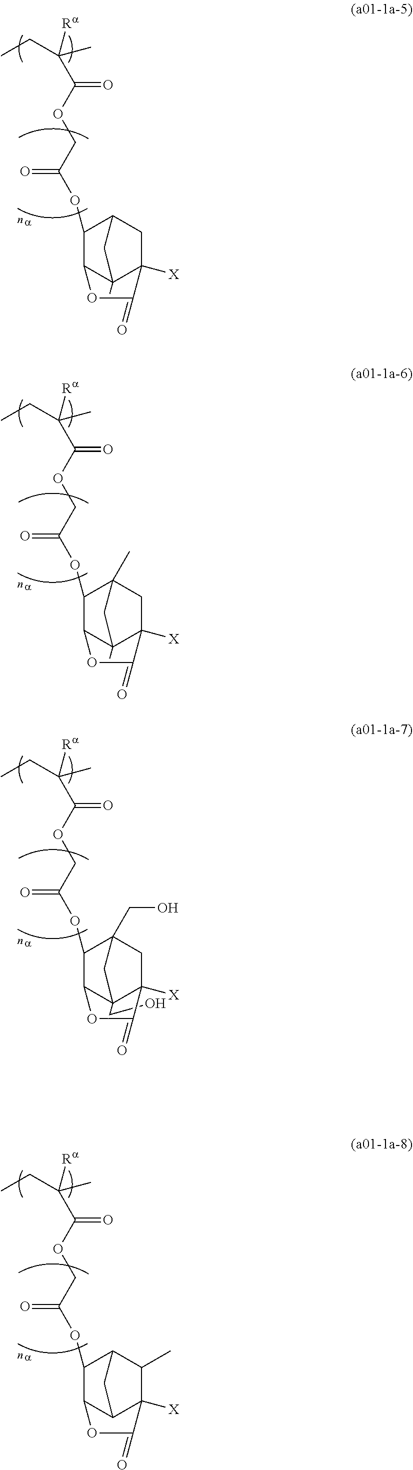

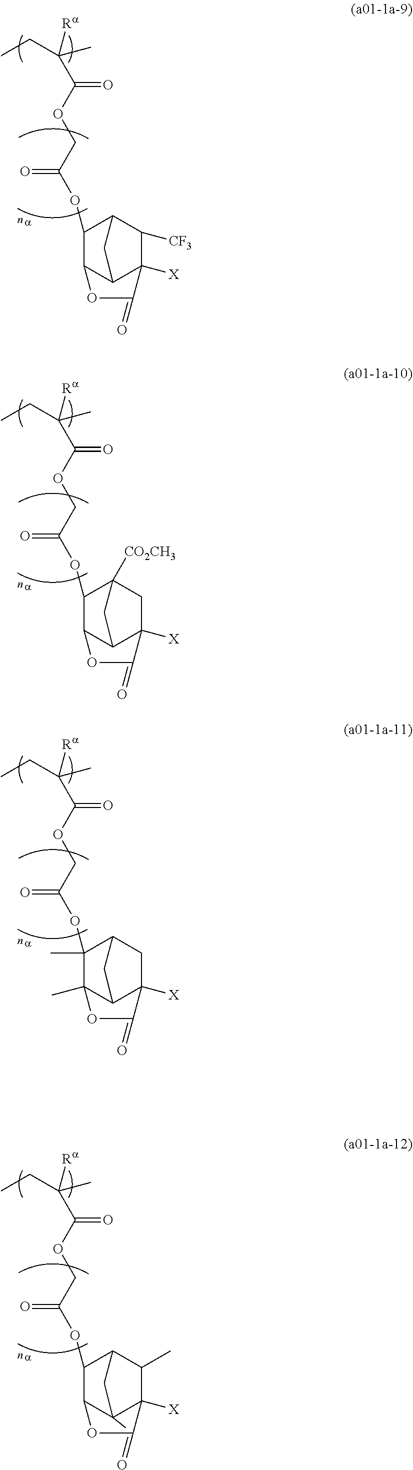

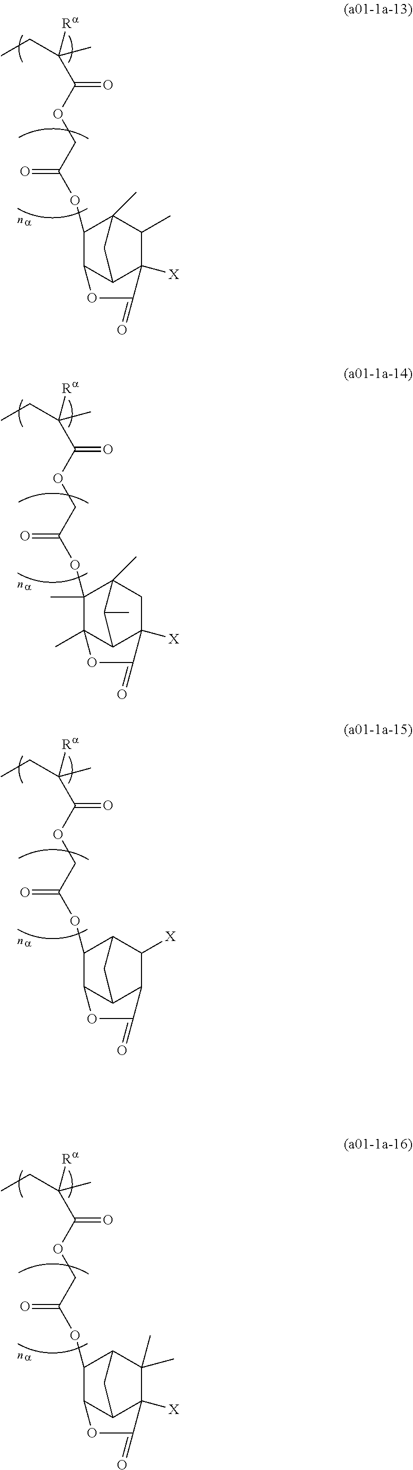

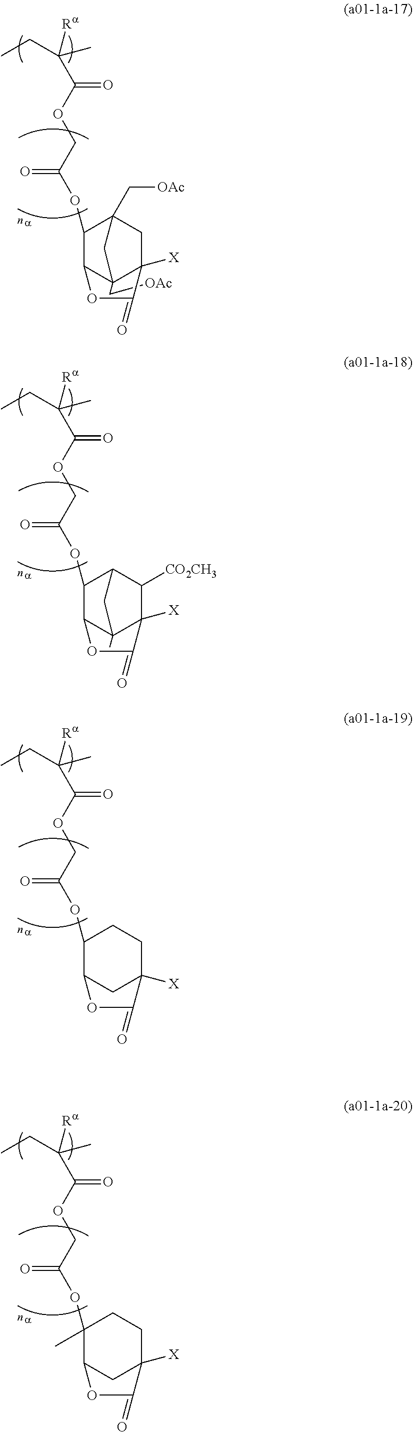

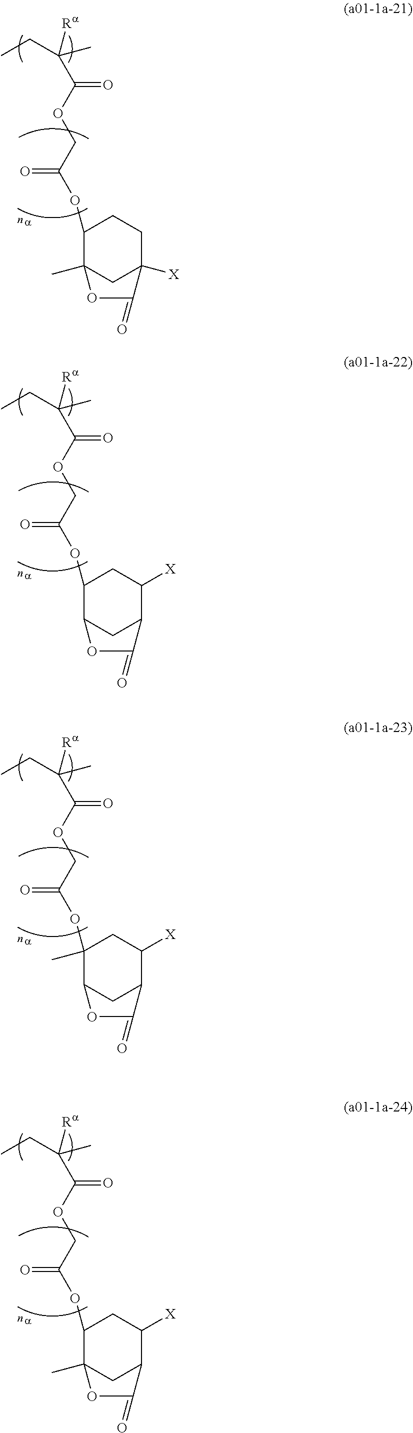

Among the above, the constitutional unit (a01) is preferably a constitutional unit represented by any one of Formulae (a01-1a-1) to (a01-1a-18) and more preferably a constitutional unit represented by General Formula (a01-1a-1).

The constitutional unit (a01) contained in the component (A1) may be one kind or may be two or more kinds.

The proportion of the constitutional unit (a01) in the component (A1) is preferably 20% by mole or more and 70% by mole or less, more preferably 30% by mole or more and 60% by mole or less, still more preferably 40% by mole or more and 60% by mole or less, and particularly preferably 45% by mole or more and 55% by mole or less, with respect to the total (100% by mole) of all constitutional units constituting the component (A1).

In a case where the proportion of the constitutional unit (a01) is set equal to or larger than the lower limit value of the preferred range described above, the roughness reduction property can be further improved by the effect of suitably adjusting the solubility at the time of development. Further, in a case where the proportion of the constitutional unit (a01) is equal to or smaller than the upper limit value of the preferred range described above, balance with other constitutional units can be easily obtained.

<<Constitutional Unit (a02)>>

The constitutional unit (a02) is a constitutional unit derived from a compound represented by General Formula (a0-2).

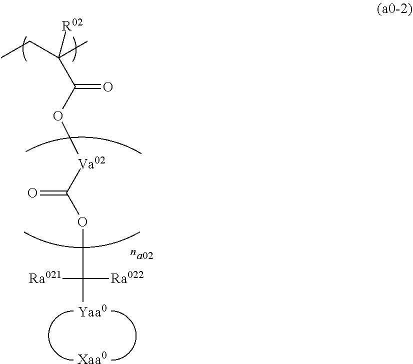

[In General Formula (a0-2), R⁰² represents a hydrogen atom, an alkyl group having 1 to 5 carbon atoms, or a halogenated alkyl group having 1 to 5 carbon atoms. Va⁰² represents a divalent linking group. nₐ₀₂ represents an integer in a range of 0 to 2. Ra⁰²¹ and Ra⁰²² each independently represent a chain alkyl group. Yaa⁰ represents a carbon atom. Xaa⁰ represents a group that forms a monocyclic alicyclic hydrocarbon group together with Yaa⁰. Part or all hydrogen atoms contained in this monocyclic alicyclic hydrocarbon group may be substituted.]

In General Formula (a0-2), R⁰² represents a hydrogen atom, an alkyl group having 1 to 5 carbon atoms, or a halogenated alkyl group having 1 to 5 carbon atoms, and examples thereof include the same one as R⁰¹ in General Formula (a0-1).

In General Formula (a0-2), Va⁰² represents a divalent linking group, and examples thereof include the same one as Va⁰¹ in General Formula (a0-1) described above.

In General Formula (a0-2), nₐ₀₂ represents an integer in a range of 0 to 2, preferably 0 or 1, and more preferably 0.

In General Formula (a0-2), Ra⁰²¹ and Ra⁰²² each independently represent a chain alkyl group. The chain alkyl group is preferably a linear or branched alkyl group having 1 to 5 carbon atoms, and specifically, suitable examples thereof include a methyl group, an ethyl group, a propyl group, an isopropyl group, an n-butyl group, an isobutyl group, a tert-butyl group, a pentyl group, an isopentyl group, and a neopentyl group.

In General Formula (a0-2), the total number of carbon atoms of the chain alkyl group as Ra⁰²¹ and Ra⁰²² is preferably 2 to 8, more preferably 2 to 6, and still more preferably 2 to 4.

In General Formula (a0-2), Ra⁰²¹ and Ra⁰²² are preferably a methyl group or an ethyl group.

In General Formula (a0-2), Xaa⁰ is a group that forms a monocyclic alicyclic hydrocarbon group together with Yaa⁰.

The monocyclic alicyclic hydrocarbon group is preferably a group obtained by removing one or more hydrogen atoms from a monocycloalkane.

The monocycloalkane preferably has 3 to 12 carbon atoms, more preferably 4 to 8 carbon atoms, still more preferably 5 or 6 carbon atoms, and particularly preferably 6 carbon atoms. Specifically, the monocycloalkane is preferably cyclopentane or cyclohexane and more preferably cyclohexane.

The monocyclic alicyclic hydrocarbon group formed by Xaa⁰ together with Yaa⁰ may have a substituent. Examples of this substituent include a methyl group, an ethyl group, propyl group, a hydroxy group, a hydroxyalkyl group, a carboxy group, a halogen atom (a fluorine atom, a chlorine atom, a bromine atom, and the like), an alkoxy group (a methoxy group, an ethoxy group, a propoxy group, a butoxy group, and the like), an acyl group, an alkyloxycarbonyl group, and an alkylcarbonyloxy group.

Suitable specific examples of the constitutional unit (a02) are as follows.

In each of the formulae shown below, R^{α} represents a hydrogen atom, a methyl group, or a trifluoromethyl group.

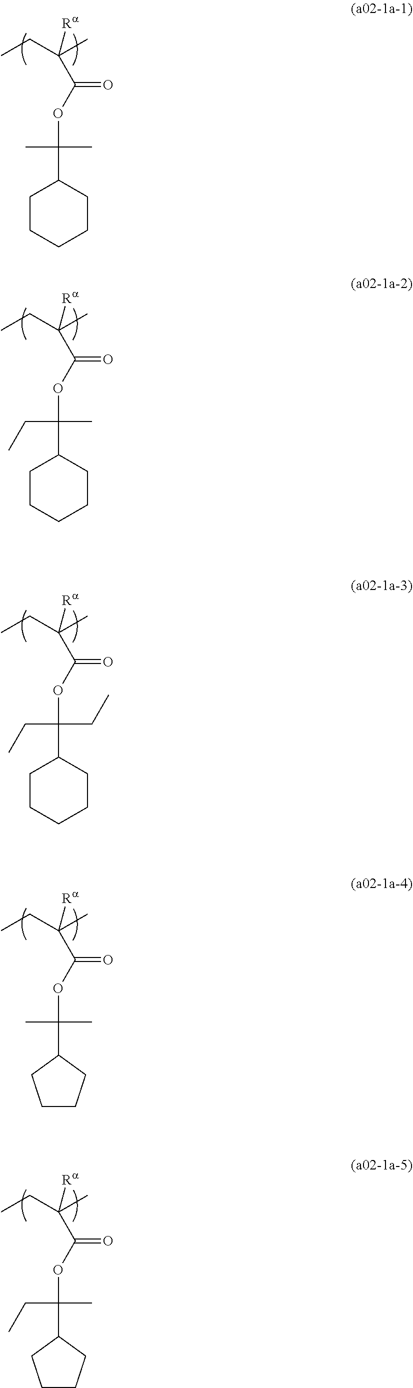

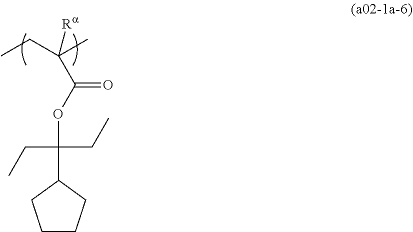

Among the above, the constitutional unit (a02) is preferably a constitutional unit represented by any one of General Formulae (a02-1a-1) to (a02-1a-3).

The constitutional unit (a02) contained in the component (A1) may be one kind or may be two or more kinds.

The proportion of the constitutional unit (a02) in the component (A1) is preferably 10% by mole or more and 60% by mole or less, more preferably 20% by mole or more and 60% by mole or less, still more preferably 20% by mole or more and 50% by mole or less, and particularly preferably 35% by mole or more and 45% by mole or less, with respect to the total (100% by mole) of all constitutional units constituting the component (A1).

In a case where the proportion of the constitutional unit (a02) is set to be equal to or larger than the lower limit value of the preferred range described above, the dissolution of unexposed portions of the resist film due to development can be further suppressed. In addition, lithography characteristics such as roughness reduction property are improved. Further, in a case where the proportion of the constitutional unit (a02) is equal to or smaller than the upper limit value of the preferred range described above, balance with other constitutional units can be easily obtained.

<<Constitutional Unit (a03)>>

The constitutional unit (a03) is a constitutional unit derived from a compound represented by General Formula (a0-3).

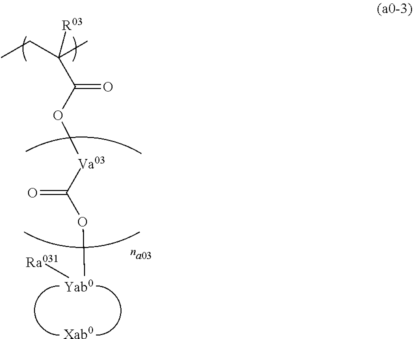

[In General Formula (a0-3), R⁰³ represents a hydrogen atom, an alkyl group having 1 to 5 carbon atoms, or a halogenated alkyl group having 1 to 5 carbon atoms. Va⁰³ represents a divalent linking group. nₐ₀₃ represents an integer in a range of 0 to 2. Ra⁰³¹ represents a chain alkyl group. Yab⁰ represents a carbon atom. Xab⁰ represents a group that forms a monocyclic alicyclic hydrocarbon group together with Yab⁰. Part or all hydrogen atoms contained in this monocyclic alicyclic hydrocarbon group may be substituted.]

In General Formula (a0-3), R⁰³ represents a hydrogen atom, an alkyl group having 1 to 5 carbon atoms, or a halogenated alkyl group having 1 to 5 carbon atoms, and examples thereof include the same one as R⁰¹ in General Formula (a0-1).

In General Formula (a0-3), Va⁰³ represents a divalent linking group, and examples thereof include the same one as Va⁰¹ in General Formula (a0-1) described above.

In General Formula (a0-3), nₐ₀₃ represents an integer in a range of 0 to 2, preferably 0 or 1, and more preferably 0.

In General Formula (a0-3), Ra⁰³¹ represents a chain alkyl group. The chain alkyl group is preferably a linear or branched alkyl group having 1 to 5 carbon atoms, and specifically, suitable examples thereof include a methyl group, an ethyl group, a propyl group, an isopropyl group, an n-butyl group, an isobutyl group, a tert-butyl group, a pentyl group, an isopentyl group, and a neopentyl group.

In General Formula (a0-3), Ra⁰³¹ is, among the above, preferably a methyl group or an ethyl group from the viewpoints of the roughness reduction property and the improvement of collapse margin and more preferably an isopropyl group from the viewpoint of high sensitivity.

In General Formula (a0-3), Xab⁰ is a group that forms a monocyclic alicyclic hydrocarbon group together with Yab⁰.

The monocyclic alicyclic hydrocarbon group is preferably a group obtained by removing two or more hydrogen atoms from a monocycloalkane.

The monocycloalkane preferably has 3 to 12 carbon atoms, more preferably 4 to 8 carbon atoms, still more preferably 5 or 6 carbon atoms, and particularly preferably 5 carbon atoms. Specifically, the monocycloalkane is preferably cyclopentane or cyclohexane and more preferably cyclopentane.

The monocyclic alicyclic hydrocarbon group formed by Xab⁰ together with Yab⁰ may have a substituent. Examples of this substituent include a methyl group, an ethyl group, propyl group, a hydroxy group, a hydroxyalkyl group, a carboxy group, a halogen atom (a fluorine atom, a chlorine atom, a bromine atom, and the like), an alkoxy group (a methoxy group, an ethoxy group, a propoxy group, a butoxy group, and the like), an acyl group, an alkyloxycarbonyl group, and an alkylcarbonyloxy group.

Suitable specific examples of the constitutional unit (a03) are as follows.

In each of the formulae shown below, R^{α} represents a hydrogen atom, a methyl group, or a trifluoromethyl group.

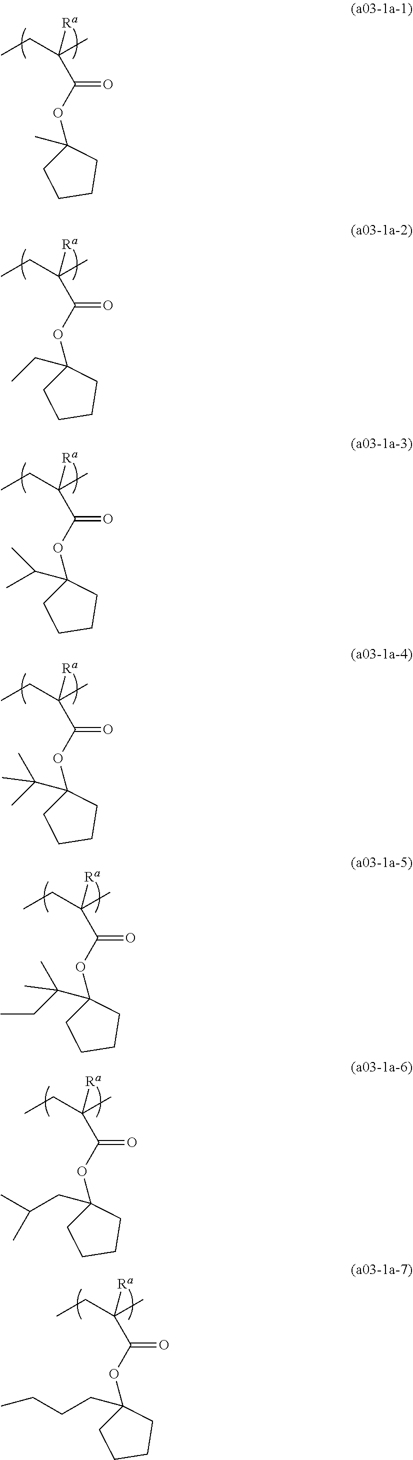

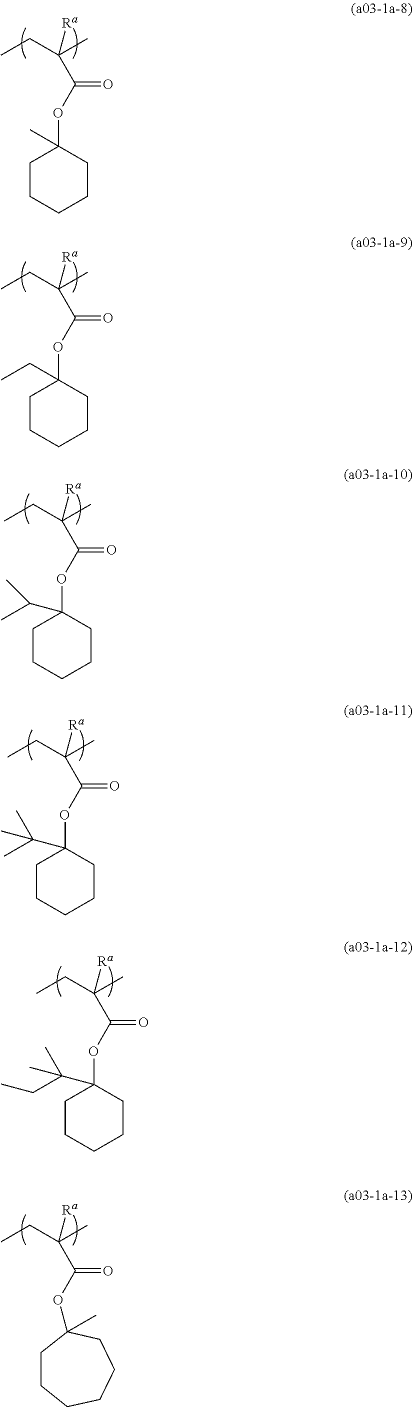

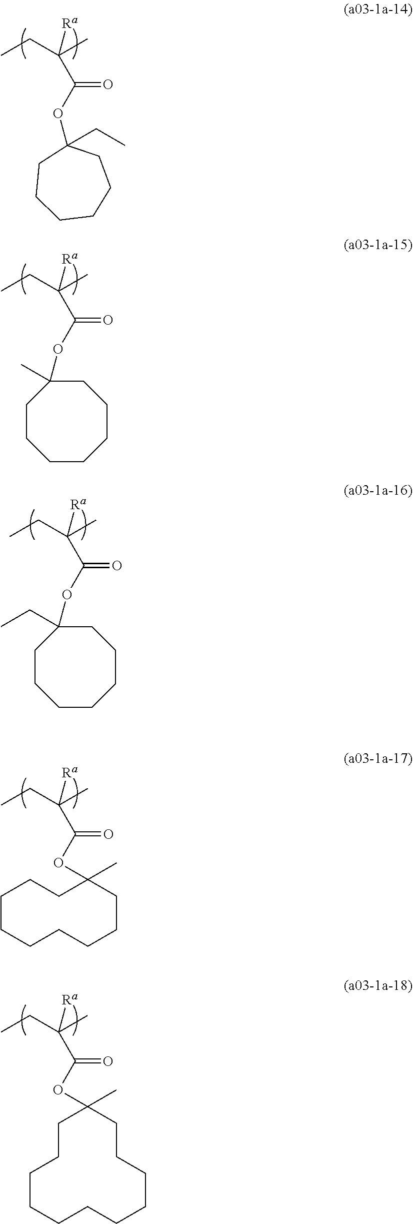

Among the above, the constitutional unit (a03) is preferably a constitutional unit represented by any one of General Formulae (a03-1a-1) to (a03-1a-7) and more preferably a constitutional unit represented by any one of General Formula (a03-1a-1) to (a03-1a-3).

The constitutional unit (a03) contained in the component (A1) may be one kind or may be two or more kinds.

The proportion of the constitutional unit (a03) in the component (A1) is preferably 1% by mole or more and 50% by mole or less, more preferably 5% by mole or more and 30% by mole or less, still more preferably 5% by mole or more and 20% by mole or less, and particularly preferably 5% by mole or more and 15% by mole or less, with respect to the total (100% by mole) of all constitutional units constituting the component (A1).

In a case where the proportion of the constitutional unit (a03) is set to be equal to or larger than the lower limit value of the preferred range described above, deprotection reactivity can be improved. Further, in a case where the proportion of the constitutional unit (a03) is equal to or smaller than the upper limit value of the preferred range described above, balance with other constitutional units can be easily obtained.

<Other Constitutional Units>

The component (A1) may have other constitutional units as necessary in addition to the constitutional unit (a01), the constitutional unit (a02), and the constitutional unit (a03).

Examples of the other constitutional units include a constitutional unit (a1) containing an acid decomposable group having a polarity that is increased under action of acid (provided that a constitutional unit corresponding to the constitutional unit (a01), the constitutional unit (a02), or the constitutional unit (a03) is excluded); a constitutional unit (a2) containing a lactone-containing cyclic group, a —SO₂-containing cyclic group, or a carbonate-containing cyclic group (provided that a constitutional unit corresponding to the constitutional unit (a01), the constitutional unit (a02), the constitutional unit (a03), or the constitutional unit (a1) is excluded); a constitutional unit (a3) containing a polar group-containing aliphatic hydrocarbon group (provided that a constitutional unit corresponding to the constitutional unit (a01), the constitutional unit (a02), the constitutional unit (a03), the constitutional unit (a1), or the constitutional unit (a2) is excluded); a constitutional unit (a4) containing an acid non-dissociable aliphatic cyclic group; a constitutional unit (st) derived from styrene or a styrene derivative; and a constitutional unit derived from a hydroxystyrene or a hydroxystyrene derivative.

<<Constitutional Unit (a1)>>

The constitutional unit (a1) is a constitutional unit that contains an acid decomposable group having a polarity that is increased under action of acid. However, a constitutional unit corresponding to the constitutional unit (a01), the constitutional unit (a02), or the constitutional unit (a03) is excluded.

Examples of the acid dissociable group are the same as those which have been proposed so far as acid dissociable groups for the base resin for a chemically amplified resist composition.

Specific examples of acid dissociable groups of the base resin proposed for a chemically amplified resist composition contains an “acetal-type acid dissociable group”, a “tertiary alkyl ester-type acid dissociable group”, and a “tertiary alkyloxycarbonyl acid dissociable group” described below.

Acetal-Type Acid Dissociable Group:

Examples of the acid dissociable group for protecting a carboxy group or a hydroxyl group as a polar group include acid dissociable groups represented by General Formula (a1-r-1) (hereinafter, also referred to as then “acetal-type acid dissociable group”).

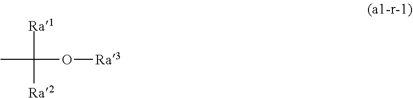

[In the formula, Ra′¹ and Ra′² represent a hydrogen atom or an alkyl group. Ra′³ represents a hydrocarbon group, and Ra′³ may be bonded to any one of Ra′¹ or Ra′² to form a ring.]

In General Formula (a1-r-1), it is preferable that at least one of Ra′¹ and Ra′² represents a hydrogen atom and more preferable that both Ra′¹ and Ra′² represent a hydrogen atom.

In a case where Ra′¹ or Ra′² represents an alkyl group, examples of the alkyl group include the same one as the alkyl group described as the substituent which may be bonded to the carbon atom at the α-position in the description on the α-substituted acrylic acid ester, and the alkyl group preferably has 1 to 5 carbon atoms. Specific preferred examples thereof include linear or branched alkyl groups. Specific examples of the alkyl group include a methyl group, an ethyl group, a propyl group, an isopropyl group, an n-butyl group, an isobutyl group, a tert-butyl group, a pentyl group, an isopentyl group, and a neopentyl group. Among these, a methyl group or an ethyl group is more preferable, and a methyl group is particularly preferable.

In General Formula (a1-r-1), examples of the hydrocarbon group as Ra′³ include a linear or branched alkyl group and a cyclic hydrocarbon group.

The linear alkyl group has preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group has preferably 3 to 10 carbon atoms and more preferably 3 to 5 carbon atoms. Specific examples thereof include an isopropyl group, an isobutyl group, a tert-butyl group, an isopentyl group, a neopentyl group a 1,1-diethylpropyl group, and a 2,2-dimethylbutyl group.

Among these, an isopropyl group is preferable.

In a case where Ra′³ represents a cyclic hydrocarbon group, the hydrocarbon group may be an aliphatic hydrocarbon group or an aromatic hydrocarbon group and may be a polycyclic group or a monocyclic group.

The aliphatic hydrocarbon group which is a monocyclic group is preferably a group obtained by removing one hydrogen atom from a monocycloalkane. The monocycloalkane has preferably 3 to 6 carbon atoms, and specific examples thereof include cyclopentane and cyclohexane.

The aliphatic hydrocarbon group which is a polycyclic group is preferably a group obtained by removing one hydrogen atom from a polycycloalkane. The polycycloalkane is preferably a group having 7 to 12 carbon atoms, and specific examples of thereof include adamantane, norbornane, isobornane, tricyclodecane, and tetracyclododecane.

In a case where the cyclic hydrocarbon group as Ra′³ is an aromatic hydrocarbon group, the aromatic hydrocarbon group is a hydrocarbon group having at least one aromatic ring.

The aromatic ring is not particularly limited as long as it is a cyclic conjugated system having (4n+2) π electrons, and may be monocyclic or polycyclic. The aromatic ring has preferably 5 to 30 carbon atoms, more preferably 5 to 20 carbon atoms, still more preferably 6 to 15 carbon atoms, and particularly preferably 6 to 12 carbon atoms.

Specific examples of the aromatic ring include: aromatic hydrocarbon rings such as benzene, naphthalene, anthracene, and phenanthrene; and aromatic heterocyclic rings in which part of carbon atoms constituting the above-described aromatic hydrocarbon rings have been substituted with hetero atoms. Examples of the hetero atom in the aromatic heterocyclic rings include an oxygen atom, a sulfur atom, and a nitrogen atom. Specific examples of the aromatic heterocyclic ring include a pyridine ring and a thiophene ring.

Specific examples of the aromatic hydrocarbon group as Ra′³ include: a group obtained by removing one hydrogen atom from the above-described aromatic hydrocarbon ring or aromatic heterocyclic ring (an aryl group or a heteroaryl group); a group obtained by removing one hydrogen atom from an aromatic compound having two or more aromatic rings (biphenyl, fluorene or the like); and a group obtained by substituting one hydrogen atom of the above-described aromatic hydrocarbon ring or aromatic heterocyclic ring with an alkylene group (for example, arylalkyl groups such as a benzyl group, a phenethyl group, a 1-naphthylmethyl group, a 2-naphthylmethyl group, a 1-naphthylethyl group, and a 2-naphthylethyl group). The alkylene group bonded to the aromatic hydrocarbon ring or aromatic heterocyclic ring has preferably 1 to 4 carbon atoms, more preferably 1 or 2 carbon atoms, and particularly preferably 1 carbon atom.

The cyclic hydrocarbon group as Ra′³ may have a substituent. Examples of the substituent include, —R^{P1}, —R^{P2}—O—R^{P1}, —R^{P2}—CO—R^{P1}, —R^{P2}—CO—OR^{P1}, —R^{P2}—O—CO—R^{P1}, —R^{P2}—OH, —R^{P2}—CN, and —R^{P2}—COOH (hereinafter, these substituents are also collectively referred to as “Ra^{x5}”).

Here, R^{P1} represents a monovalent chain-like saturated hydrocarbon group having 1 to 10 carbon atoms, a monovalent aliphatic cyclic saturated hydrocarbon group having 3 to 20 carbon atoms, or a monovalent aromatic hydrocarbon group having 6 to 30 carbon atoms. In addition, R^{P2} represents a single bond, a divalent chain-like saturated hydrocarbon group having 1 to 10 carbon atoms, a divalent aliphatic cyclic saturated hydrocarbon group having 3 to 20 carbon atoms, or a divalent aromatic hydrocarbon group having 6 to 30 carbon atoms. However, part or all hydrogen atoms contained in the chain-like saturated hydrocarbon group, the aliphatic cyclic saturated hydrocarbon group, and the aromatic hydrocarbon group of R^{P1} and R^{P2} may be substituted with a fluorine atom. In the aliphatic cyclic hydrocarbon group, one or more of the above-described substituents may be included as a single kind, or one or more of the above-described substituents may be included as a plurality of kinds.

Examples of the monovalent chain-like saturated hydrocarbon group having 1 to 10 carbon atoms include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms include: monocyclic aliphatic saturated hydrocarbon groups such as a cyclopropyl group, a cyclobutyl group, a cyclopentyl group, a cyclohexyl group, a cycloheptyl group, a cyclooctyl group, a cyclodecyl group, and cyclododecyl group; and polycyclic aliphatic saturated hydrocarbon groups such as a bicyclo[2.2.2]octanyl group, a tricyclo[5.2.1.02,6]decanyl group, a tricyclo [3.3.1.13,7]decanyl group, a tetracyclo[6.2.1.13,6.02,7] dodecanyl group, and an adamantyl group.

Examples of the monovalent aromatic hydrocarbon group having 6 to 30 carbon atoms include a group obtained by removing one hydrogen atom from aromatic hydrocarbon rings such as benzene, biphenyl, fluorene, naphthalene, anthracene, and phenanthrene.

In a case where Ra′³ is bonded to any one of Ra′¹ or Ra′² to form a ring, the cyclic group is preferably a 4-membered to 7-membered ring, and more preferably a 4-membered to 6-membered ring. Specific examples of the cyclic group include a tetrahydropyranyl group and a tetrahydrofuranyl group.

Tertiary alkyl ester-type acid dissociable group:

Among the above polar groups, examples of the acid dissociable group for protecting the carboxy group include the acid dissociable group represented by General Formula (a1-r-2) shown below.

Among the acid dissociable groups represented by General Formula (a1-r-2), for convenience, a group which is constituted of alkyl groups is referred to as a “tertiary alkyl ester-type acid dissociable group”.

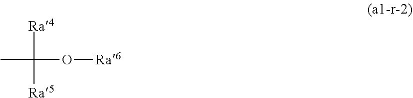

[In the formula, Ra′⁴ to Ra′⁶ each represent a hydrocarbon group, and Ra′⁵ and Ra′⁶ may be bonded to each other to form a ring.]

Examples of the hydrocarbon group as Ra′⁴ include a linear or branched alkyl group, a chain-like or cyclic alkenyl group, and a cyclic hydrocarbon group.

Examples of the linear or branched alkyl group and the cyclic hydrocarbon group (the aliphatic hydrocarbon group which is a monocyclic group, the aliphatic hydrocarbon group which is a polycyclic group, or the aromatic hydrocarbon group) as Ra′⁴ include the same one as Ra′³ described above.

The chain-like or cyclic alkenyl group as Ra′⁴ is preferably an alkenyl group having 2 to 10 carbon atoms.

Examples of the hydrocarbon group as Ra′⁵ and Ra′⁶ include the same one as Ra′³.

In a case where Ra′⁵ to Ra′⁶ are bonded to each other to form a ring, suitable examples thereof include groups represented by General Formula (a1-r2-1), General Formula (a1-r2-2), and General Formula (a1-r2-3) can be suitably mentioned.

On the other hand, in a case where Ra′⁴ to Ra′⁶ are not bonded to each other and represent an independent hydrocarbon group, suitable examples thereof include a group represented by General Formula (a1-r2-4).

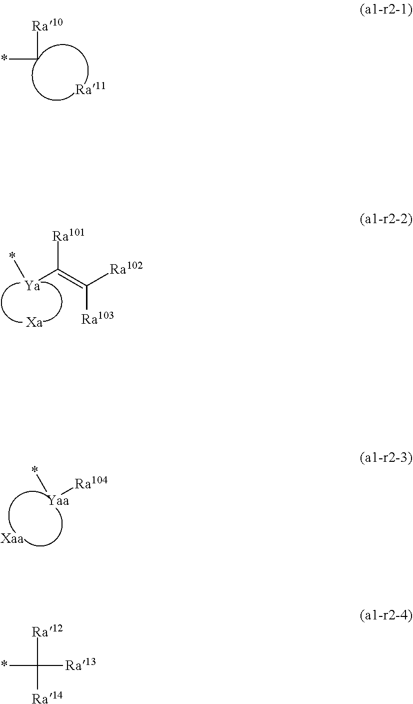

[In General Formula (a1-r2-1), Ra′¹⁰ represents a linear or branched alkyl group having 1 to 12 carbon atoms, a part of which may be substituted with a halogen atom or a hetero atom-containing group. Ra′¹¹ represents a group that forms an aliphatic cyclic group together with a carbon atom to which Ra′¹⁰ is bonded. In General Formula (a1-r2-2), Ya represents a carbon atom. Xa is a group that forms a cyclic hydrocarbon group together with Ya. Part or all hydrogen atoms contained in the cyclic hydrocarbon group may be substituted. Ra¹⁰¹ to Ra¹⁰³ each independently represent a hydrogen atom, a monovalent chain-like saturated hydrocarbon group having 1 to 10 carbon atoms, or a monovalent aliphatic cyclic saturated hydrocarbon group having 3 to 20 carbon atoms. Part or all hydrogen atoms contained in the chain-like saturated hydrocarbon group and the aliphatic cyclic saturated hydrocarbon group have may be substituted. Two or more of Ra¹⁰¹ to Ra¹⁰³ may be bonded to each other to form a cyclic structure. In General Formula (a1-r2-3), Yaa represents a carbon atom. Xaa is a group that forms an aliphatic cyclic group together with Yaa. Ra¹⁰⁴ represents an aromatic hydrocarbon group which may have a substituent. In General Formula (a1-r2-4), Ra′¹² and Ra′¹³ each independently represent a monovalent chain-like saturated hydrocarbon group having 1 to 10 carbon atoms or a hydrogen atom. Part or all hydrogen atoms contained in the chain-like saturated hydrocarbon group may be substituted. Ra′¹⁴ represents a hydrocarbon group which may have a substituent. * represents a bonding site.]

In General Formula (a1-r2-1) described above, Ra′¹⁰ represents a linear or branched alkyl group having 1 to 12 carbon atoms, a part of which may be substituted with a halogen atom or a hetero atom-containing group.

The linear alkyl group as Ra′¹⁰ has 1 to 12 carbon atoms, and preferably has 1 to 10 carbon atoms and particularly preferably 1 to 5 carbon atoms.

Examples of the branched alkyl group as Ra′¹⁰ include the same one as Ra′³.

A part of the alkyl group as Ra′¹⁰ may be substituted with a halogen atom or a hetero atom-containing group. For example, part of hydrogen atoms constituting an alkyl group may be substituted with a halogen atom or a hetero atom-containing group. Further, part of carbon atoms (a methylene group and the like) constituting the alkyl group may be substituted with a hetero atom-containing group.

Examples of the hetero atom mentioned here include an oxygen atom, a sulfur atom, and a nitrogen atom. Examples of the hetero atom-containing group include (—O—), —C(═O)—O—, —O—C(═O)—, —C(═O)—, —O—C(═O)—O—, —C(═O)—NH—, —NH—, —S—, —S(═O)₂—, and —S(═O)₂—O—.

In General Formula (a1-r2-1), Ra′¹¹ (a group that forms an aliphatic cyclic group together with a carbon atom to which Ra′10 is bonded) is preferably the group mentioned as the aliphatic hydrocarbon group (the alicyclic hydrocarbon group) which is a monocyclic group or a polycyclic group as Ra′³ in General Formula (a1-r-1). Among them, a monocyclic alicyclic hydrocarbon group is preferable, and specifically, a cyclopentyl group and a cyclohexyl group are more preferable, and a cyclopentyl group is still more preferable.

In General Formula (a1-r2-2), examples of the cyclic hydrocarbon group formed by Xa together with Ya include a group obtained by further removing one or more hydrogen atoms from a cyclic monovalent hydrocarbon group (an aliphatic hydrocarbon group) as Ra′³ in General Formula (a1-r-1).

The cyclic hydrocarbon group that is formed by Xa together with Ya may have a substituent. Examples of this substituent include the same one as the substituent which may be contained in the cyclic hydrocarbon group as Ra′³.

In General Formula (a1-r2-2), examples of the monovalent chain-like saturated hydrocarbon group having 1 to 10 carbon atoms, as Ra¹⁰¹ to Ra¹⁰³, include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms, as Ra¹⁰¹ to Ra¹⁰³, include monocyclic aliphatic saturated hydrocarbon groups such as a cyclopropyl group, a cyclobutyl group, a cyclopentyl group, a cyclohexyl group, a cycloheptyl group, a cyclooctyl group, a cyclodecyl group, and cyclododecyl group; and polycyclic aliphatic saturated hydrocarbon groups such as a bicyclo[2.2.2]octanyl group, a tricyclo[5.2.1.02,6]decanyl group, a tricyclo [3.3.1.13,7]decanyl group, a tetracyclo[6.2.1.13,6.02,7] dodecanyl group, and an adamantyl group.

Among the above, Ra¹⁰¹ to Ra¹⁰³ are preferably a hydrogen atom or a monovalent chain-like saturated hydrocarbon group having 1 to 10 carbon atoms, and among them, a hydrogen atom, a methyl group, and an ethyl group are more preferable, and a hydrogen atom is particularly preferable from the viewpoint of easy synthesis.

Examples of the substituent contained in the chain-like saturated hydrocarbon group represented by Ra¹⁰¹ to Ra¹⁰³ or the aliphatic cyclic saturated hydrocarbon group include the same group as Ra^{x5} described above.

Examples of the group containing a carbon-carbon double bond generated by forming a cyclic structure, which is obtained by bonding two or more of Ra¹⁰¹ to Ra¹⁰³ to each other, include a cyclopentenyl group, a cyclohexenyl group, a methylcyclopentenyl group, a methylcyclohexenyl group, a cyclopentylideneethenyl group, and a cyclohexylideneethenyl group. Among these, a cyclopentenyl group, a cyclohexenyl group, and a cyclopentylideneethenyl group are preferable from the viewpoint of easy synthesis.

In General Formula (a1-r2-3), an aliphatic cyclic group that is formed by Xaa together with Yaa is preferably the group mentioned as the aliphatic hydrocarbon group which is a monocyclic group or a polycyclic group as Ra′³ in General Formula (a1-r-1).

In General Formula (a1-r2-3), Examples of the aromatic hydrocarbon group as Ra¹⁰⁴ include a group obtained by removing one or more hydrogen atoms from an aromatic hydrocarbon ring having 5 to 30 carbon atoms. Among them, Ra¹⁰⁴ is preferably a group obtained by removing one or more hydrogen atoms from an aromatic hydrocarbon ring having 6 to 15 carbon atoms, more preferably a group obtained by removing one or more hydrogen atoms from benzene, naphthalene, anthracene, or phenanthrene, still more preferably a group obtained by removing one or more hydrogen atoms from benzene, naphthalene, or anthracene, particularly preferably a group obtained by removing one or more hydrogen atoms from benzene or naphthalene, and most preferably a group obtained by removing one or more hydrogen atoms from benzene.

Examples of the substituent which may be contained in Ra¹⁰⁴ in General Formula (a1-r2-3) include a methyl group, an ethyl group, propyl group, a hydroxy group, a carboxy group, a halogen atom, an alkoxy group (a methoxy group, an ethoxy group, a propoxy group, a butoxy group, and the like), and an alkyloxycarbonyl group.

In General Formula (a1-r2-4), Ra′¹² and Ra′¹³ each independently represent a monovalent chain-like saturated hydrocarbon group having 1 to 10 carbon atoms or a hydrogen atom. Examples of the monovalent chain-like saturated hydrocarbon group having 1 to 10 carbon atoms, as Ra′¹² and Ra′¹³, include the same ones as those having 1 to 10 carbon atoms, as Ra¹⁰¹ to Ra¹⁰³ as described above. Part or all hydrogen atoms contained in the chain-like saturated hydrocarbon group may be substituted.

Among the above, Ra′¹² and Ra′¹³ are preferably a hydrogen atom or an alkyl group having 1 to 5 carbon atoms, more preferably an alkyl group having 1 to 5 carbon atoms, still more preferably a methyl group or an ethyl group, and particularly preferably a methyl group.

In a case where the chain-like saturated hydrocarbon groups represented by Ra′¹² and Ra′¹³ are substituted, examples of the substituent include the same group as Ra^{x5} described above.

In General Formula (a1-r2-4), Ra′¹⁴ represents a hydrocarbon group which may have a substituent. Examples of the hydrocarbon group as Ra′¹⁴ include a linear or branched alkyl group and a cyclic hydrocarbon group.

The linear alkyl group as Ra′¹⁴ has preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group as Ra′¹⁴ preferably has 3 to 10 carbon atoms and more preferably 3 to 5 carbon atoms. Specific examples thereof include an isopropyl group, an isobutyl group, a tert-butyl group, an isopentyl group, a neopentyl group a 1,1-diethylpropyl group, and a 2,2-dimethylbutyl group.

Among these, an isopropyl group is preferable.

In a case where Ra′¹⁴ represents a cyclic hydrocarbon group, the hydrocarbon group may be an aliphatic hydrocarbon group or an aromatic hydrocarbon group and may be a polycyclic group or a monocyclic group.

The aliphatic hydrocarbon group which is a monocyclic group is preferably a group obtained by removing one hydrogen atom from a monocycloalkane. The monocycloalkane has preferably 3 to 6 carbon atoms, and specific examples thereof include cyclopentane and cyclohexane.

The aliphatic hydrocarbon group which is a polycyclic group is preferably a group obtained by removing one hydrogen atom from a polycycloalkane. The polycycloalkane is preferably a group having 7 to 12 carbon atoms, and specific examples of thereof include adamantane, norbornane, isobornane, tricyclodecane, and tetracyclododecane.

Examples of the aromatic hydrocarbon group as Ra′¹⁴ include the same one as the aromatic hydrocarbon group as Ra¹⁰⁴. Among them, Ra′¹⁴ is preferably a group obtained by removing one or more hydrogen atoms from an aromatic hydrocarbon ring having 6 to 15 carbon atoms, more preferably a group obtained by removing one or more hydrogen atoms from benzene, naphthalene, anthracene, or phenanthrene, still more preferably a group obtained by removing one or more hydrogen atoms from benzene, naphthalene, or anthracene, particularly preferably a group obtained by removing one or more hydrogen atoms from naphthalene or anthracene, and most preferably a group obtained by removing one or more hydrogen atoms from naphthalene.

Examples of the substituent which may be contained in Ra′¹⁴ include the same one as the substituent which may be contained in Ra¹⁰⁴.

In a case where Ra′¹⁴ in General Formula (a1-r2-4) is a naphthyl group, the position at which the tertiary carbon atom in General Formula (a1-r2-4) is bonded may be any of the 1-position and the 2-position of the naphthyl group.

In a case where Ra′¹⁴ in General Formula (a1-r2-4) is an anthryl group, the position at which the tertiary carbon atom in General Formula (a1-r2-4) is bonded may be any of the 1-position, the 2-position, and 9-position of the anthryl group.

Specific examples of the group represented by General Formula (a1-r2-1) are as follows.

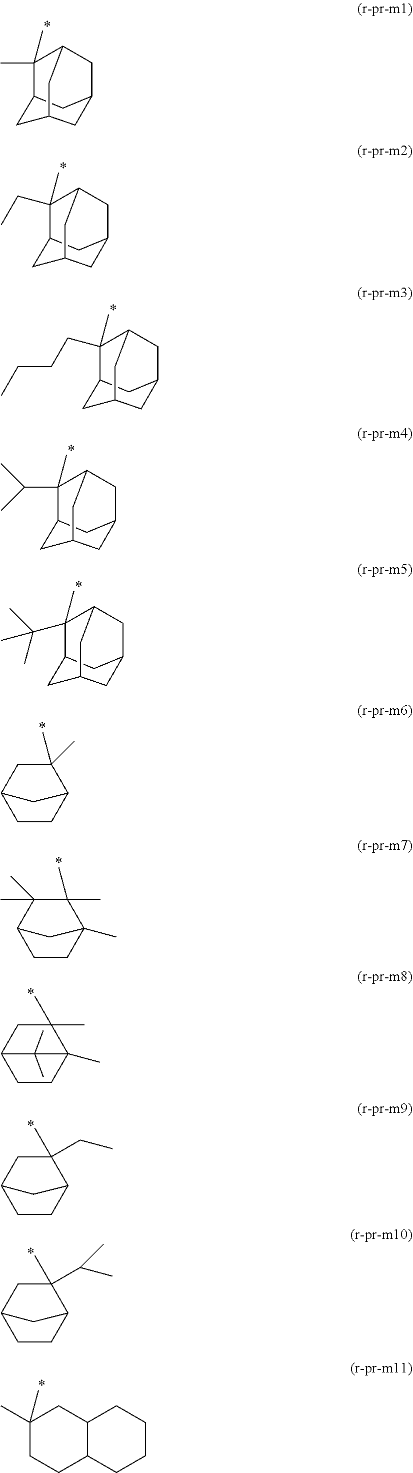

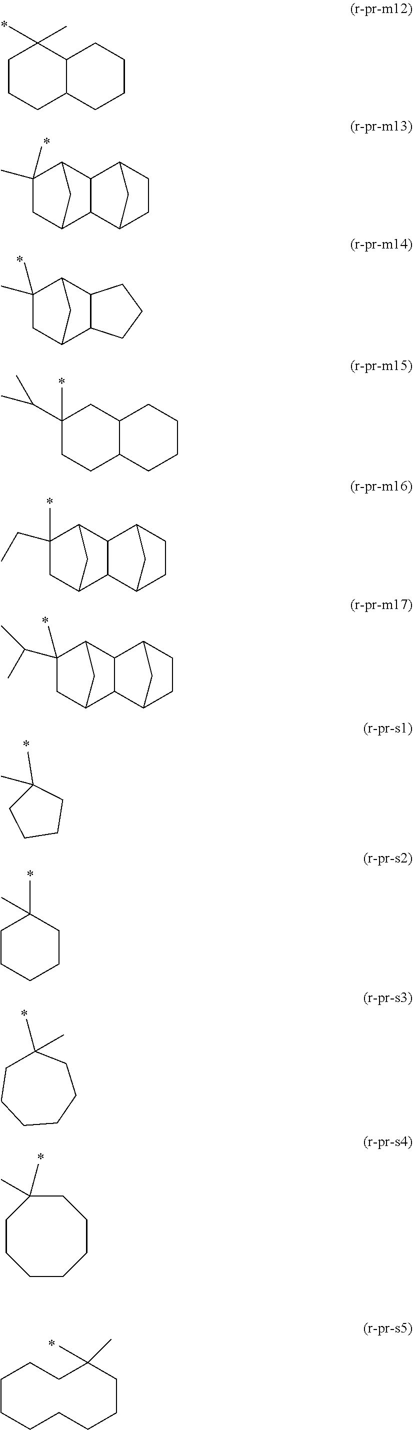

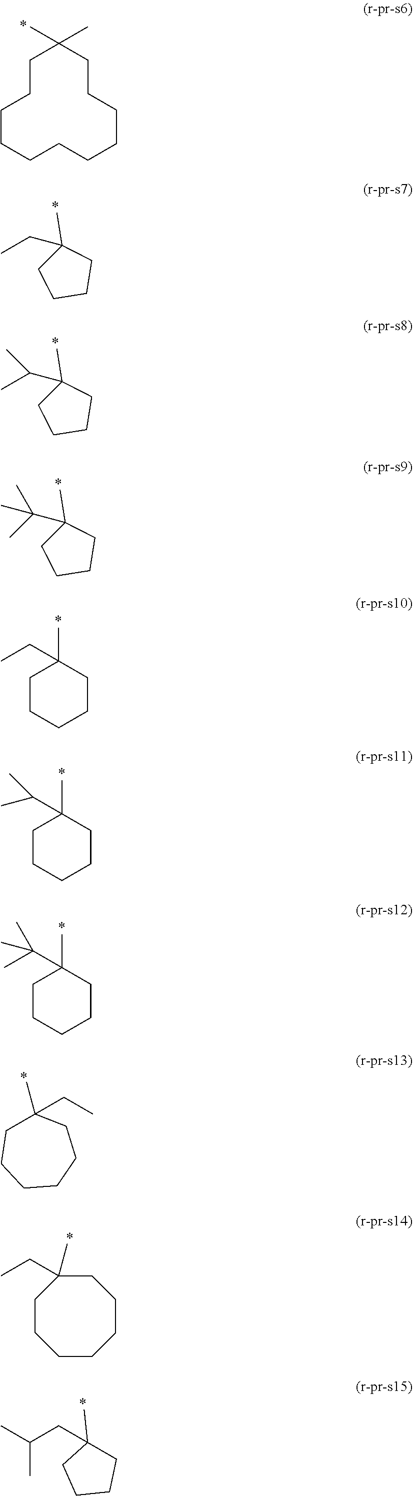

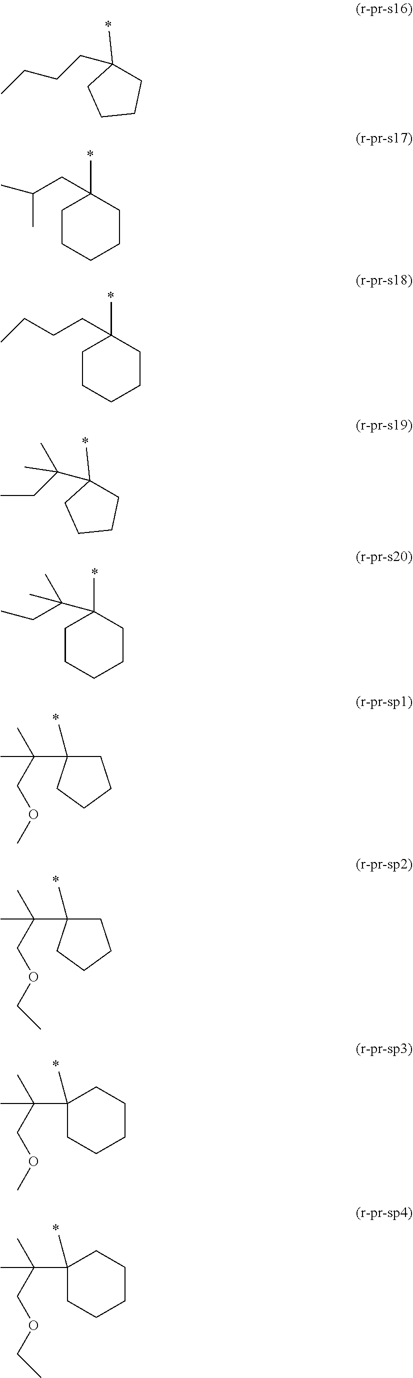

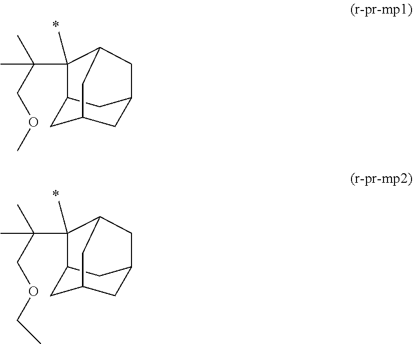

Specific examples of the group represented by General Formula (a1-r2-2) are as follows.

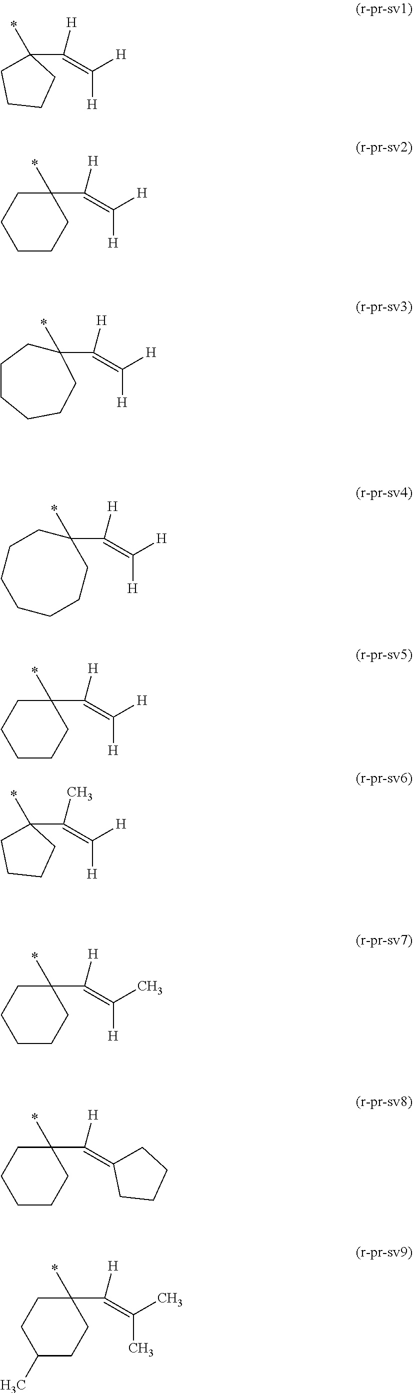

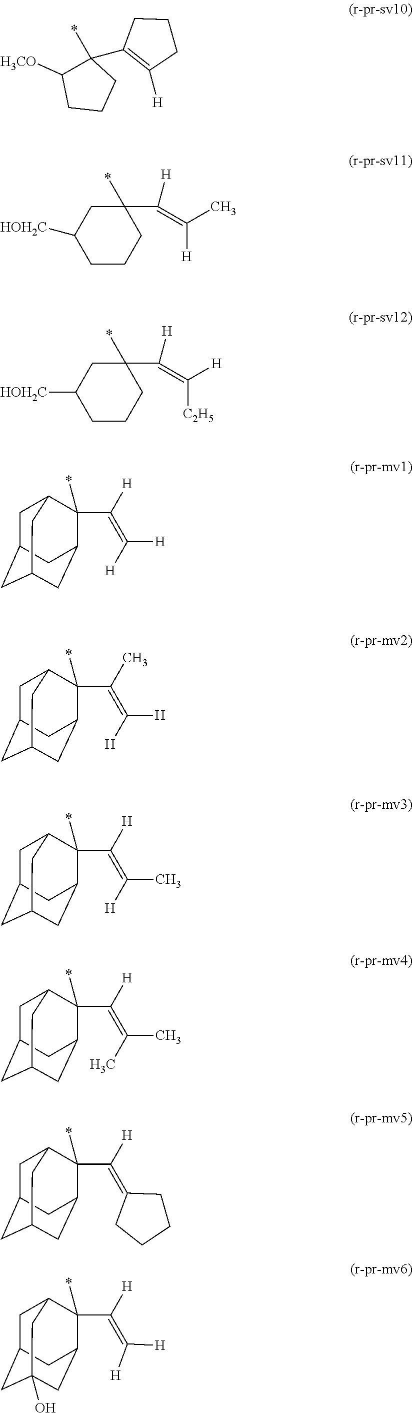

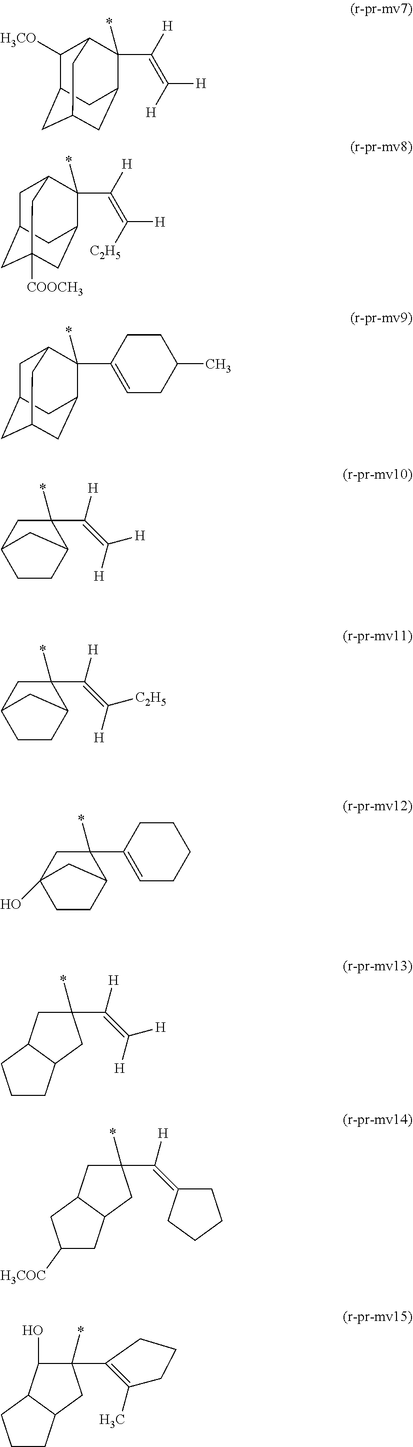

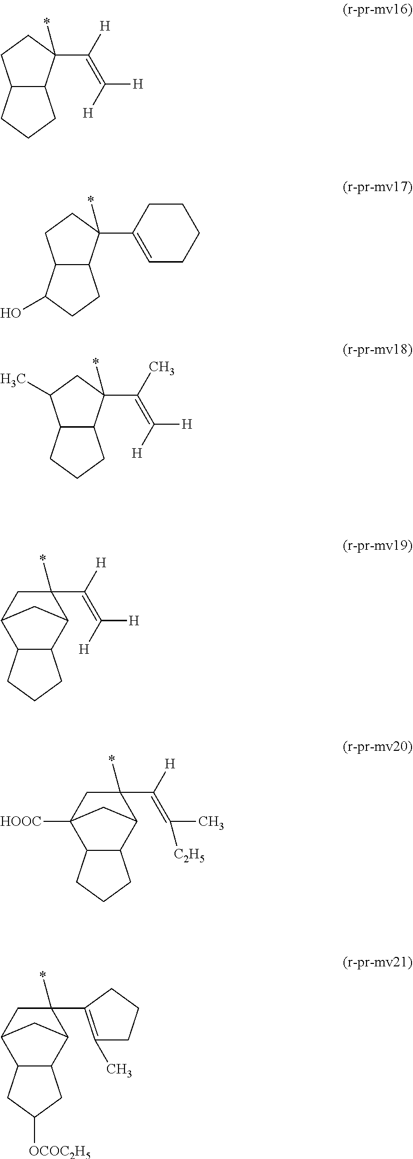

Specific examples of the group represented by General Formula (a1-r2-3) are as follows.

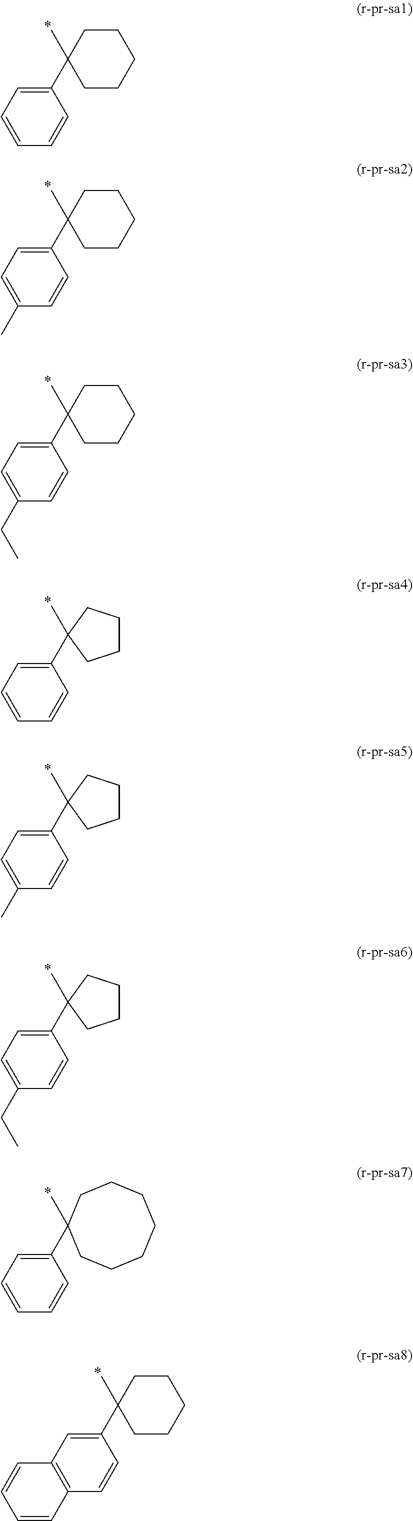

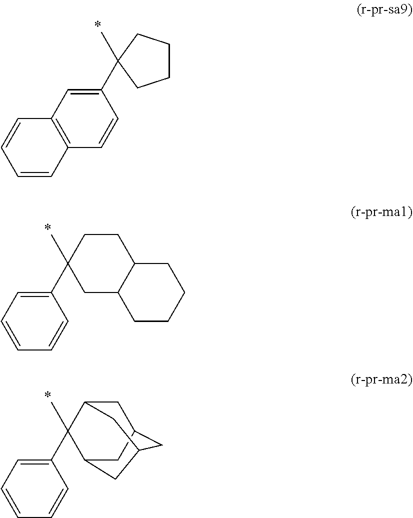

Specific examples of the group represented by General Formula (a1-r2-4) are as follows.

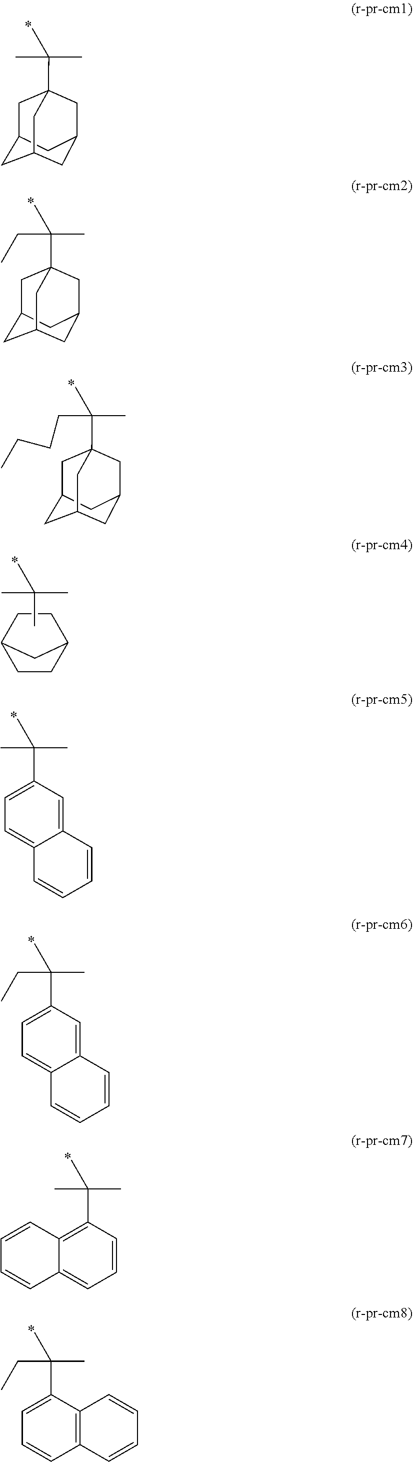

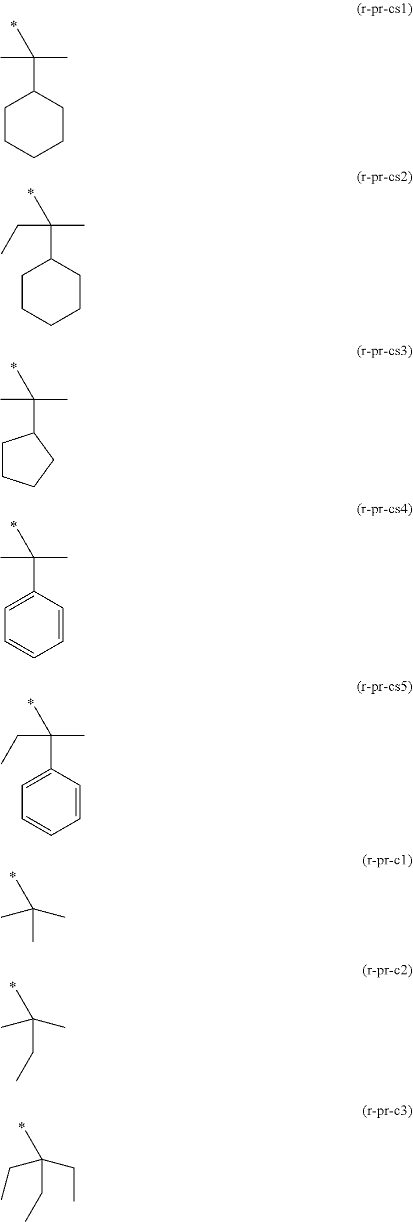

Tertiary alkyloxycarbonyl-type acid dissociable group:

Examples of the acid dissociable group for protecting a hydroxyl group as a polar group include acid dissociable groups (hereinafter, for convenience, also referred to as “tertiary alkyloxycarbonyl-type acid dissociable group”) represented by General Formula (a1-r-3).

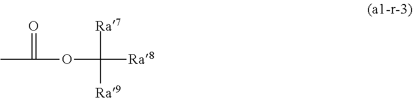

[In the formula, Ra′⁷ to Ra′⁹ each represent an alkyl group.]

In General Formula (a1-r-3), Ra′⁷ to Ra′⁹ are each preferably an alkyl group having 1 to 5 carbon atoms and more preferably an alkyl group having 1 to 3 carbon atoms.

Further, the total number of carbon atoms in each alkyl group is preferably 3 to 7, more preferably 3 to 5, and most preferably 3 or 4.

Examples of the constitutional unit (a1) include a constitutional unit derived from acrylic acid ester in which the hydrogen atom bonded to the carbon atom at the α-position may be substituted with a substituent; a constitutional unit derived from acrylamide; a constitutional unit in which at least part of hydrogen atoms in a hydroxyl group of a constitutional unit derived from hydroxystyrene or a hydroxystyrene derivative are protected by a substituent including an acid decomposable group; and a constitutional unit in which at least part of hydrogen atoms in —C(═O)—OH of a constitutional unit derived from vinylbenzoic acid or a vinylbenzoic acid derivative are protected by the substituent including an acid decomposable group.

Specific examples of the constitutional unit (a1) are shown below. In each of the formulae shown below, R^{α} represents a hydrogen atom, a methyl group, or a trifluoromethyl group.

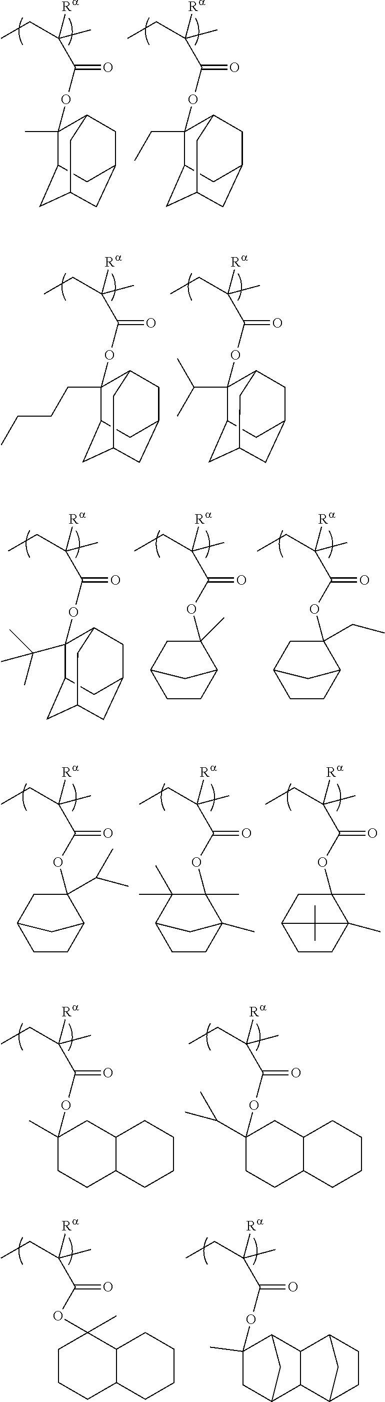

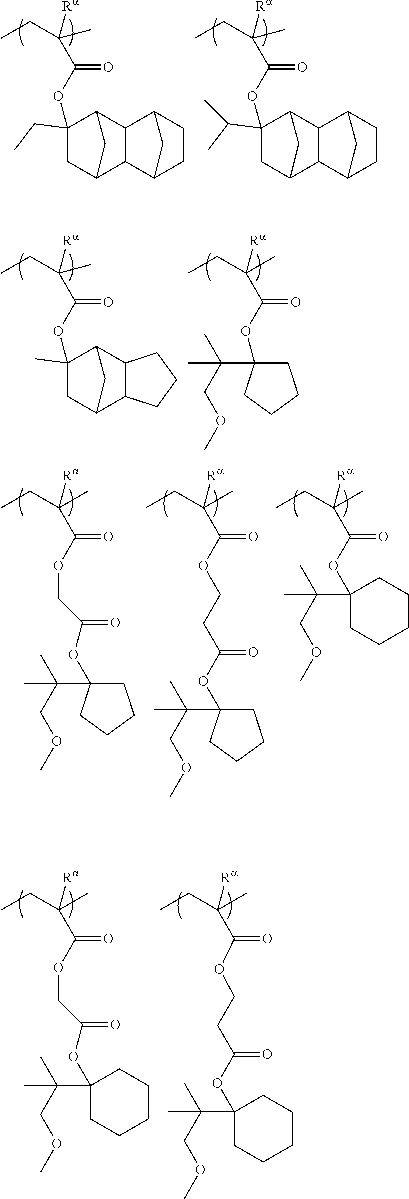

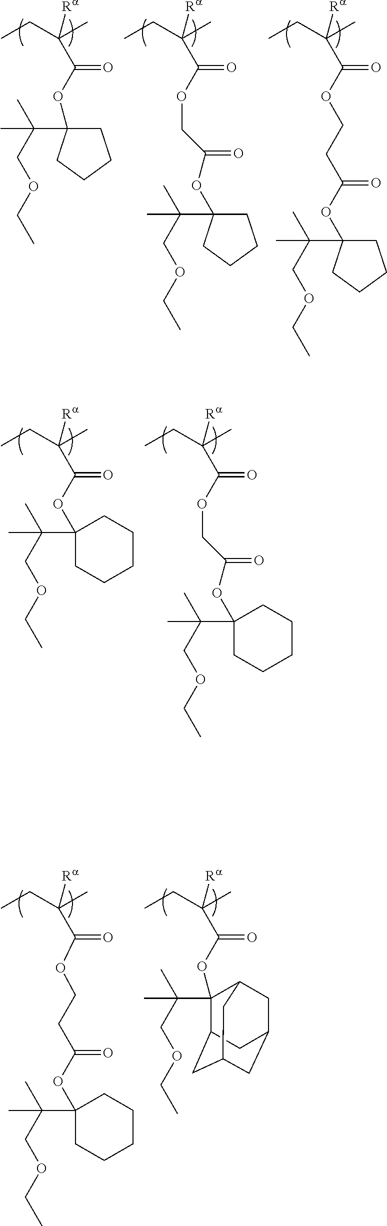

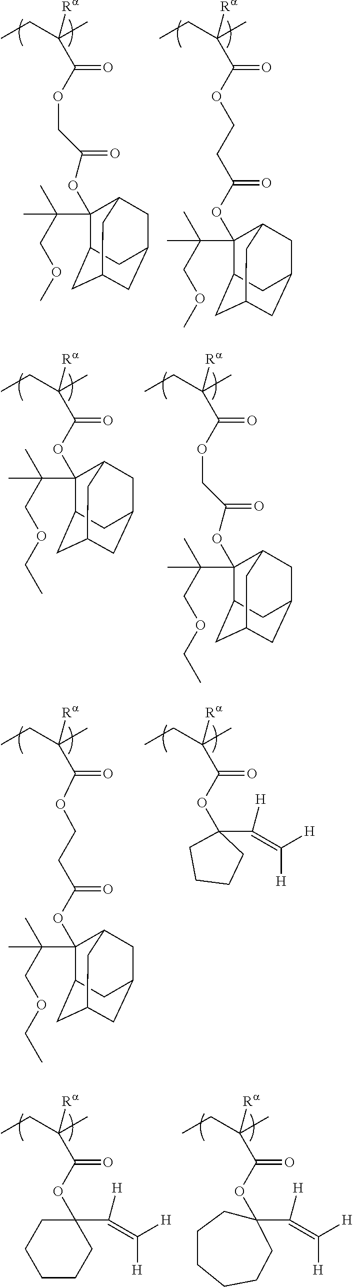

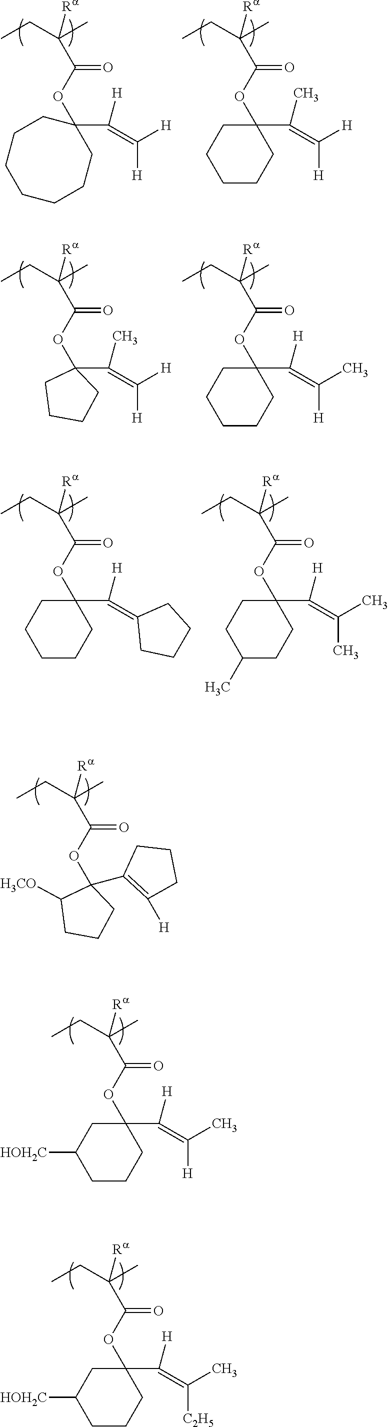

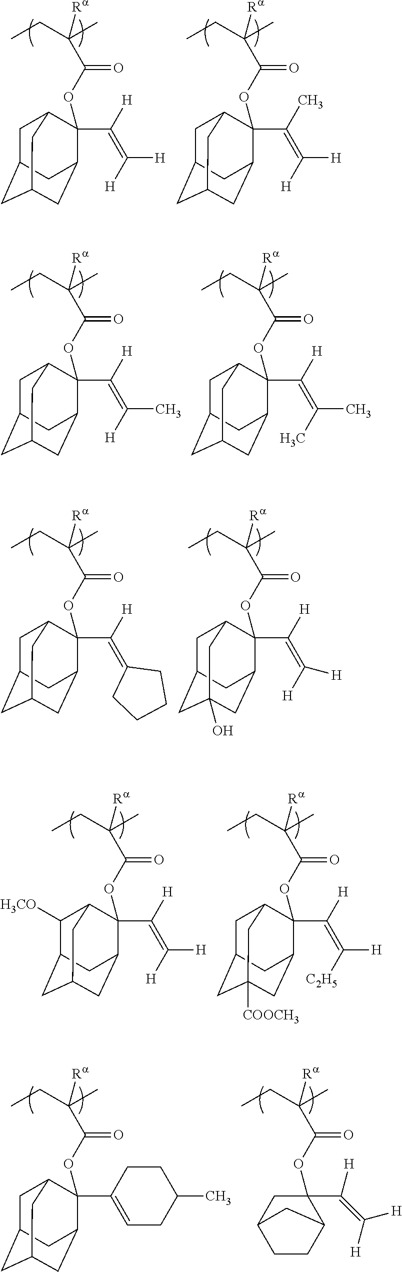

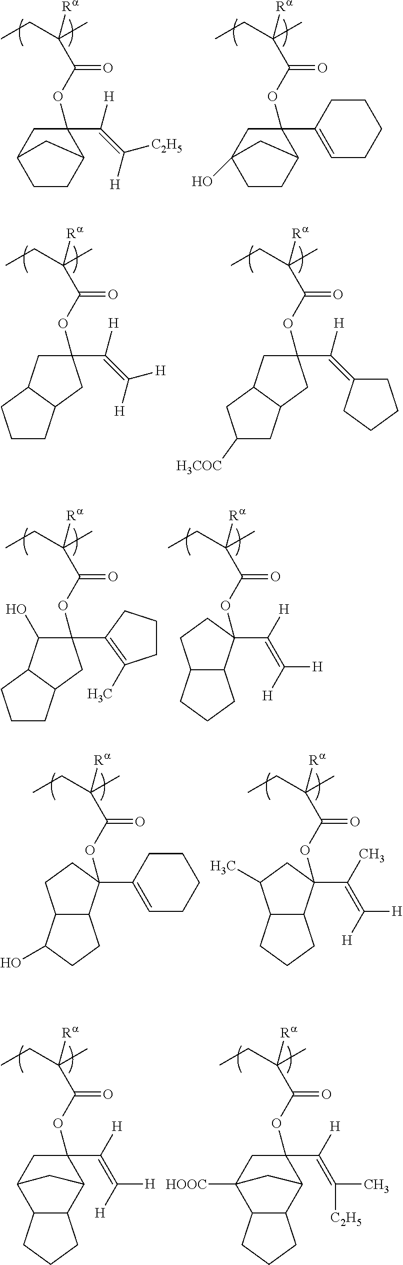

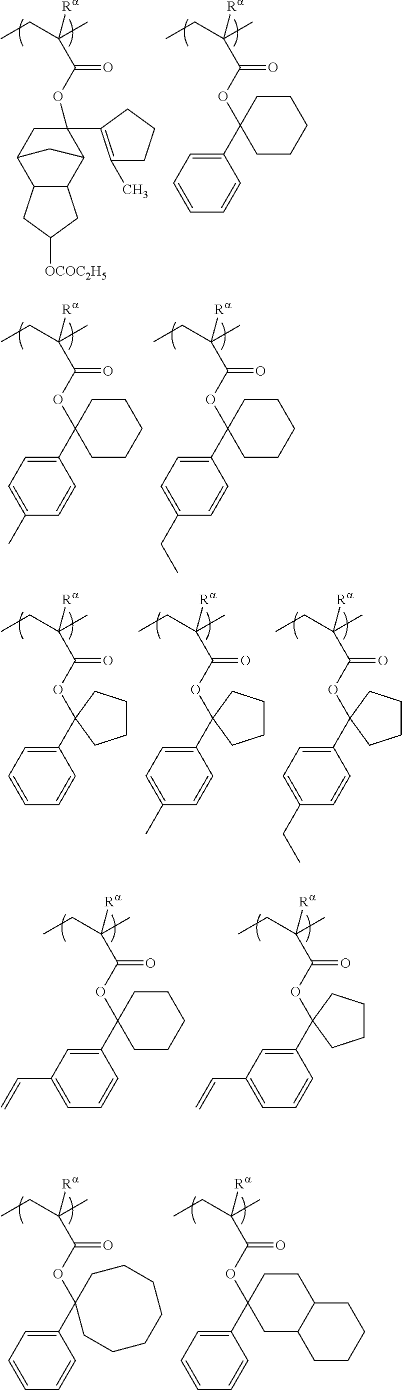

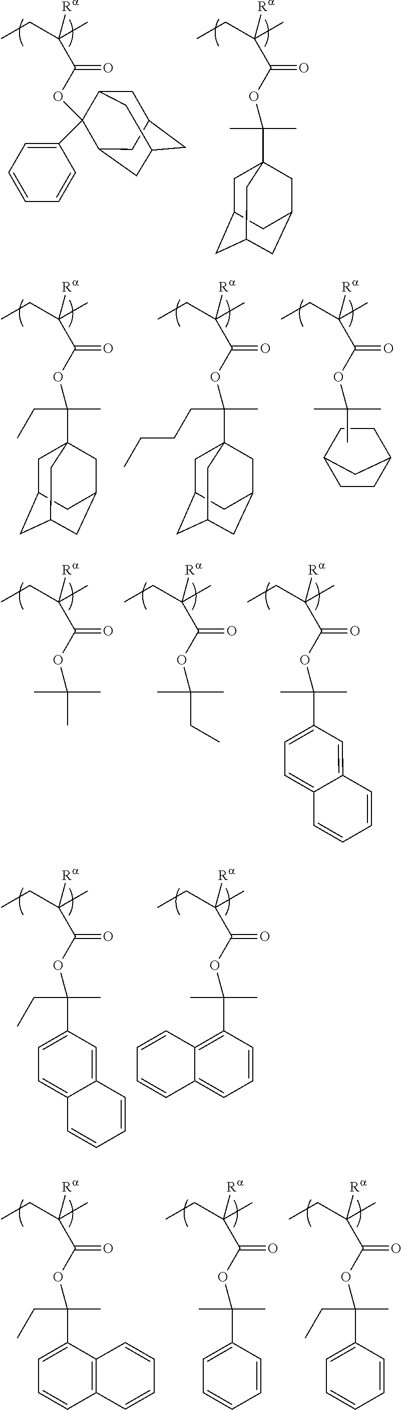

The constitutional unit (a1) contained in the component (A1) may be one kind or may be two or more kinds.

In a case where the component (A1) contains the constitutional unit (a1), the proportion of the constitutional unit (a1) in the component (A1) is preferably in a range of 1% to 50% by mole and more preferably in a range of 1% to 40% by mole with respect to the total (100% by mole) of all constitutional units constituting the component (A1).

In regard to constitutional unit (a2).

The component (A1) may further have a constitutional unit (a2) (however, a constitutional unit corresponding to the constitutional unit (a01), the constitutional unit (a02), the constitutional unit (a03), or the constitutional unit (a1) is excluded) containing a lactone-containing cyclic group, a —SO₂-containing cyclic group, or a carbonate-containing cyclic group.

In a case where the component (A1) is used for forming a resist film, the lactone-containing cyclic group, the —SO₂-containing cyclic group, or the carbonate-containing cyclic group in the constitutional unit (a2) is effective for improving the adhesiveness of the resist film to the substrate. Further, due to having the constitutional unit (a2), lithography characteristics can be improved, for example, by the effects obtained by appropriately adjusting the acid diffusion length, increasing the adhesiveness of the resist film to the substrate, and appropriately adjusting the solubility at the time of development.

The lactone-containing cyclic group for the constitutional unit (a2) is not particularly limited, and any constitutional unit may be used. Specific examples thereof include groups each represented by General Formulae (a2-r-1) to (a2-r-7).

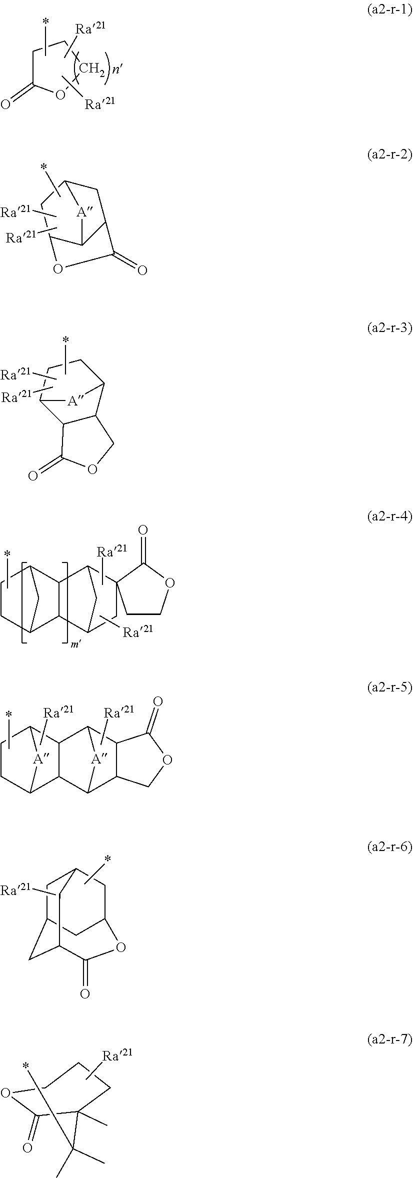

[In the formulae, each Ra′²¹ independently represent a hydrogen atom, an alkyl group, an alkoxy group, a halogen atom, a halogenated alkyl group, a hydroxyl group, —COOR″, —OC(═O)R″, a hydroxyalkyl group, or a cyano group; R″ represents a hydrogen atom, an alkyl group, a lactone-containing cyclic group, a carbonate-containing cyclic group, or a —SO₂-containing cyclic group; A″ represents an oxygen atom, a sulfur atom, or an alkylene group having 1 to 5 carbon atoms, which may contain an oxygen atom (—O—) or a sulfur atom (—S—); and n′ represents an integer in a range of 0 to 2, and m′ is 0 or 1.]

In General Formulae (a2-r-1) to (a2-r-7), the alkyl group as Ra′²¹ is preferably an alkyl group having 1 to 6 carbon atoms. The alkyl group is preferably a linear alkyl group or a branched alkyl group. Specific examples thereof include a methyl group, an ethyl group, a propyl group, an isopropyl group, an n-butyl group, an isobutyl group, a tert-butyl group, a pentyl group, an isopentyl group, a neopentyl group, and a hexyl group. Among these, a methyl group or ethyl group is preferable, and a methyl group is particularly preferable.

The alkoxy group as Ra′²¹ is preferably an alkoxy group having 1 to 6 carbon atoms. Further, the alkoxy group is preferably a linear or branched alkoxy group. Specific examples thereof include a group formed by linking the alkyl group mentioned as the alkyl group as Ra′²¹ to an oxygen atom (—O—).

The halogen atom as Ra′²¹ is preferably a fluorine atom.

Examples of the halogenated alkyl group as Ra′²¹ include group obtained by substituting part or all hydrogen atoms in the above-described alkyl group as Ra′²¹ with the above-described halogen atoms. The halogenated alkyl group is preferably a fluorinated alkyl group and particularly preferably a perfluoroalkyl group.

In —COOR″ and —OC(═O)R″ as Ra′²¹, R″ represents a hydrogen atom, an alkyl group, a lactone-containing cyclic group, a carbonate-containing cyclic group, or a —SO₂-containing cyclic group.

The alkyl group as R″ may be linear, branched, or cyclic, and preferably has 1 to 15 carbon atoms.

In a case where R″ represents a linear or branched alkyl group, it is preferably an alkyl group having 1 to 10 carbon atoms, more preferably an alkyl group having 1 to 5 carbon atoms, and particularly preferably a methyl group or an ethyl group.

In a case where R″ represents a cyclic alkyl group, the number of carbon atoms thereof is preferably 3 to 15, more preferably 4 to 12, and most preferably 5 to 10. Specific examples thereof include: a group obtained by removing one or more hydrogen atoms from a monocycloalkane which may or may not be substituted with a fluorine atom or a fluorinated alkyl group; and a group obtained by removing one or more hydrogen atoms from polycycloalkanes such as a bicycloalkane, a tricycloalkane, and a tetracycloalkane. More specific examples thereof include: a group obtained by removing one or more hydrogen atoms from monocycloalkanes such as cyclopentane and cyclohexane; and a group obtained by removing one or more hydrogen atoms from polycycloalkanes such as adamantane, norbornane, isobornane, tricyclodecane, and tetracyclododecane.

Examples of the lactone-containing cyclic group as R″ include the same ones as those each represented by General Formulae (a2-r-1) to (a2-r-7).

The carbonate-containing cyclic group as R″ has the same definition as that for the carbonate-containing cyclic group described below.

Specific examples of the carbonate-containing cyclic group include groups each represented by General Formulae (ax3-r-1) to (ax3-r-3).

The —SO₂-containing cyclic group as R″ is the same as —SO₂-containing cyclic group described below. Specific examples thereof include groups each represented by General Formulae (a5-r-1) to (a5-r-4).

The hydroxyalkyl group as Ra′²¹ preferably has 1 to 6 carbon atoms, and specific examples thereof include a group obtained by substituting at least one hydrogen atom in the alkyl group as Ra′²¹ with a hydroxyl group.

In General Formulae (a2-r-2), (a2-r-3), and (a2-r-5), as the alkylene group having 1 to 5 carbon atoms as A″, a linear or branched alkylene group is preferable, and examples thereof include a methylene group, an ethylene group, an n-propylene group, and an isopropylene group. Specific examples of the alkylene groups that contain an oxygen atom or a sulfur atom include a group obtained by interposing —O— or —S— in the terminal of the alkylene group or between the carbon atoms of the alkylene group, and examples thereof include —O—CH2-, —CH2O—CH₂—, —S—CH₂—, and —CH₂—S—CH₂—. A″ is preferably an alkylene group having 1 to 5 carbon atoms or —O—, more preferably an alkylene group having 1 to 5 carbon atoms, and most preferably a methylene group.

Specific examples of the groups each represented by General Formulae (a2-r-1) to (a2-r-7) are as follows.

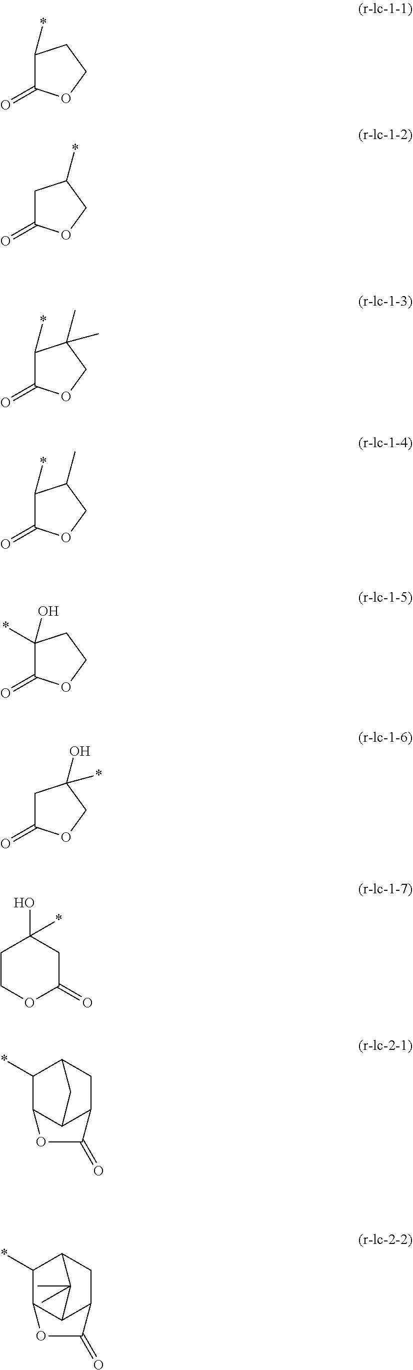

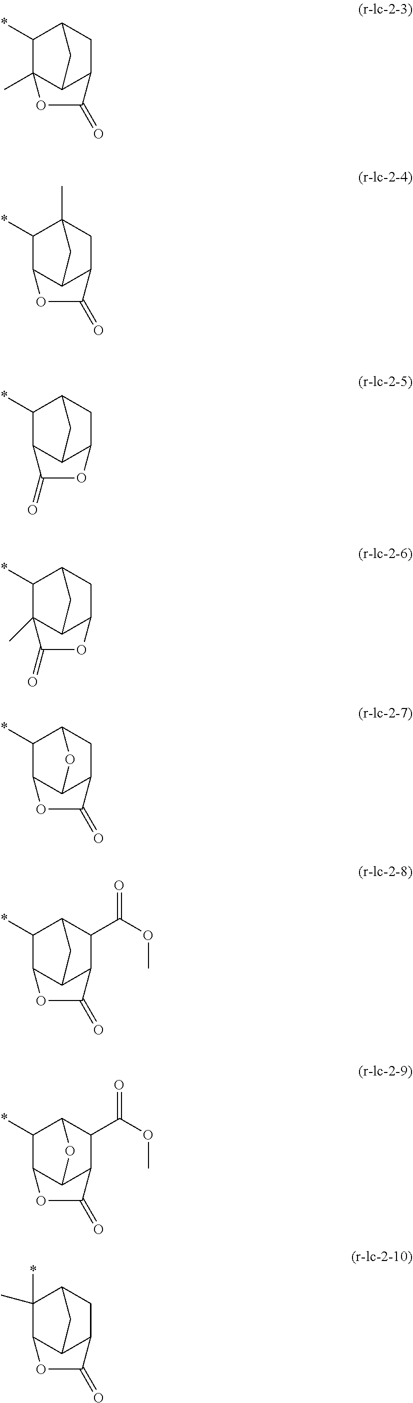

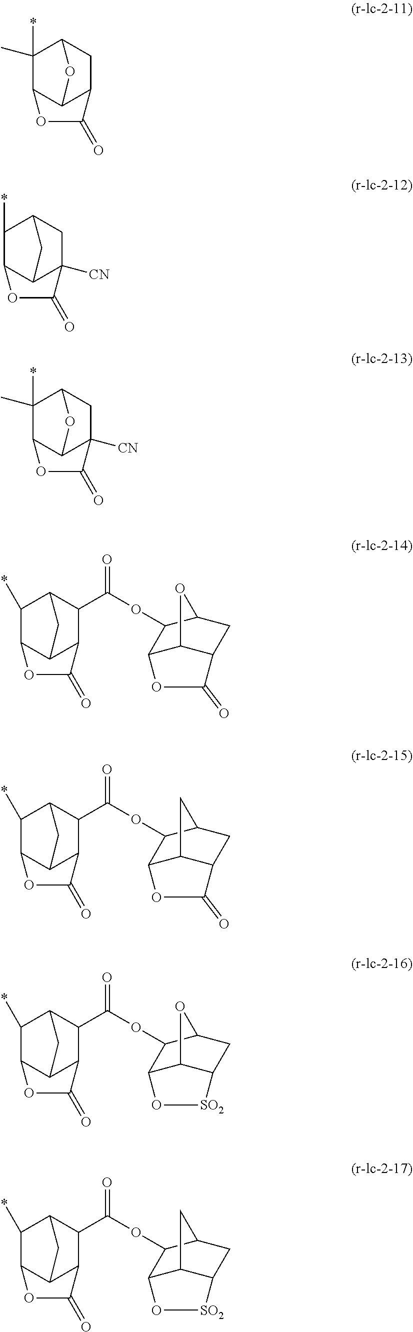

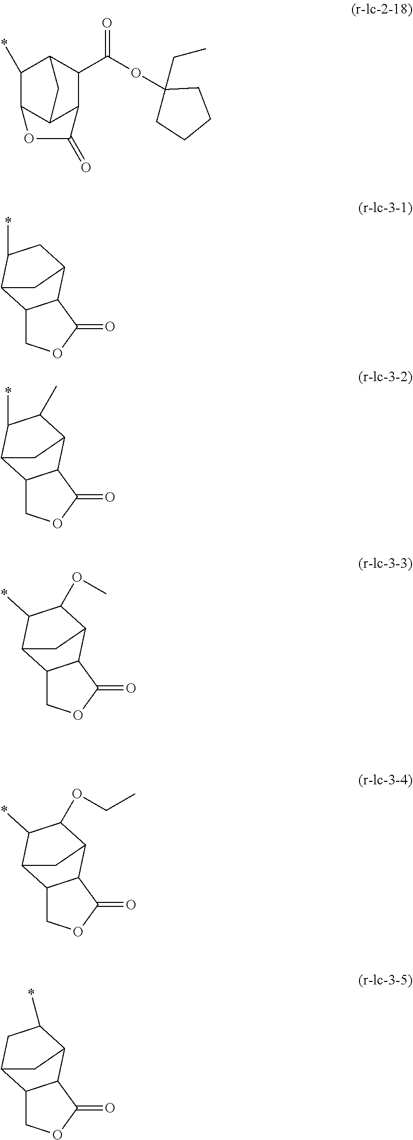

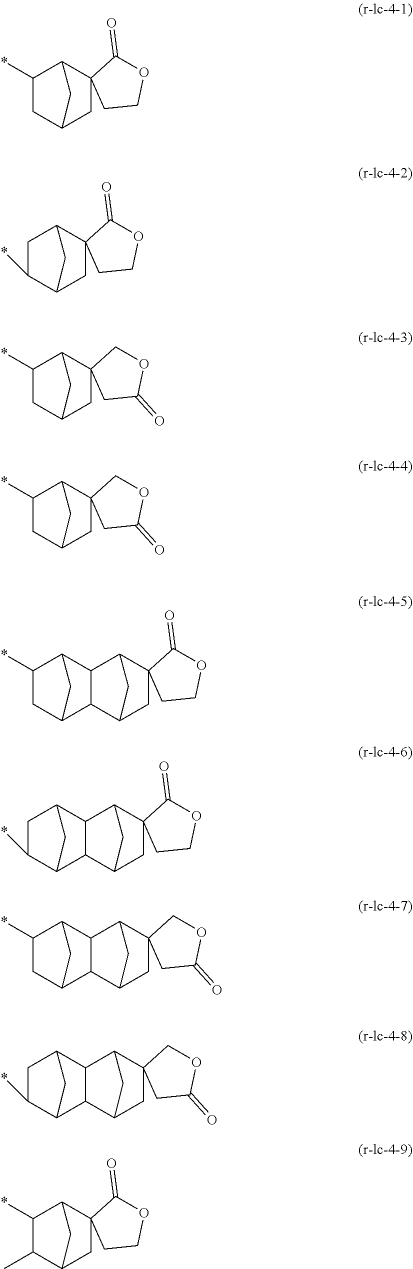

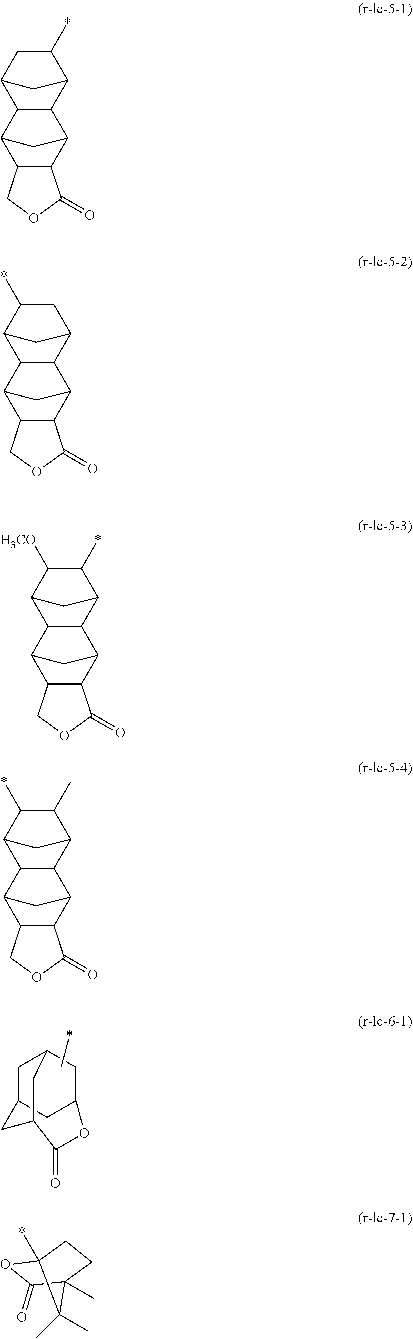

The “—SO₂-containing cyclic group” indicates a cyclic group having a ring containing —SO₂— in the ring skeleton thereof. Specifically, the —SO₂-containing cyclic group is a cyclic group in which the sulfur atom (S) in —SO₂— forms a part of the ring skeleton of the cyclic group. In a case where the ring containing —SO₂— in the ring skeleton thereof is counted as the first ring and the group contains only the ring, the group is referred to as a monocyclic group. In a case where the group further has other ring structures, the group is referred to as a polycyclic group regardless of the structures. The —SO₂-containing cyclic group may be a monocyclic group or a polycyclic group.

The —SO₂-containing cyclic group is particularly preferably a cyclic group containing —O—SO₂— in the ring skeleton thereof, in other words, a cyclic group containing a sultone ring in which —O—S— in the —O—SO₂— group forms a part of the ring skeleton thereof.

More specific examples of the —SO₂-containing cyclic group include groups each represented by General Formulae (a5-r-1) to (a5-r-4) shown below.

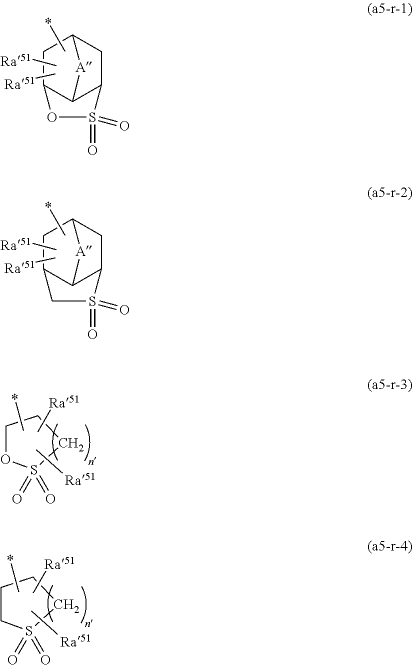

[In the formulae, each Ra′⁵¹ independently represent a hydrogen atom, an alkyl group, an alkoxy group, a halogen atom, a halogenated alkyl group, a hydroxyl group, —COOR″, —OC(═O)R″, a hydroxyalkyl group, or a cyano group; R″ represents a hydrogen atom, an alkyl group, a lactone-containing cyclic group, a carbonate-containing cyclic group, or a —SO₂-containing cyclic group; A″ represents an oxygen atom, a sulfur atom, or an alkylene group having 1 to 5 carbon atoms, which may contain an oxygen atom or a sulfur atom; and n′ represents an integer in a range of 0 to 2.]

In General Formulae (a5-r-1) and (a5-r-2), A″ is the same as A″ in General Formulae (a2-r-2), (a2-r-3) and (a2-r-5).

Examples of the alkyl group, the alkoxy group, the halogen atom, the halogenated alkyl group, —COOR″, —OC(═O)R″, and the hydroxyalkyl group as Ra′⁵¹ each include the same ones as those mentioned in the explanation of Ra′²¹ in General Formulae (a2-r-1) to (a2-r-7).

Specific examples of the groups each represented by General Formulae (a5-r-1) to (a5-r-4) are as follows. The “Ac” in the formula represents an acetyl group.

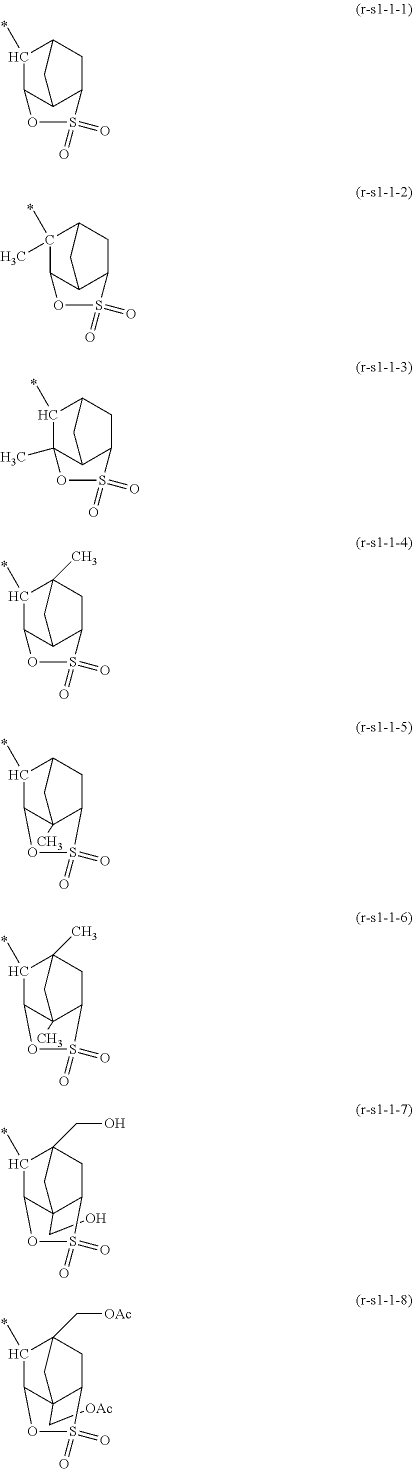

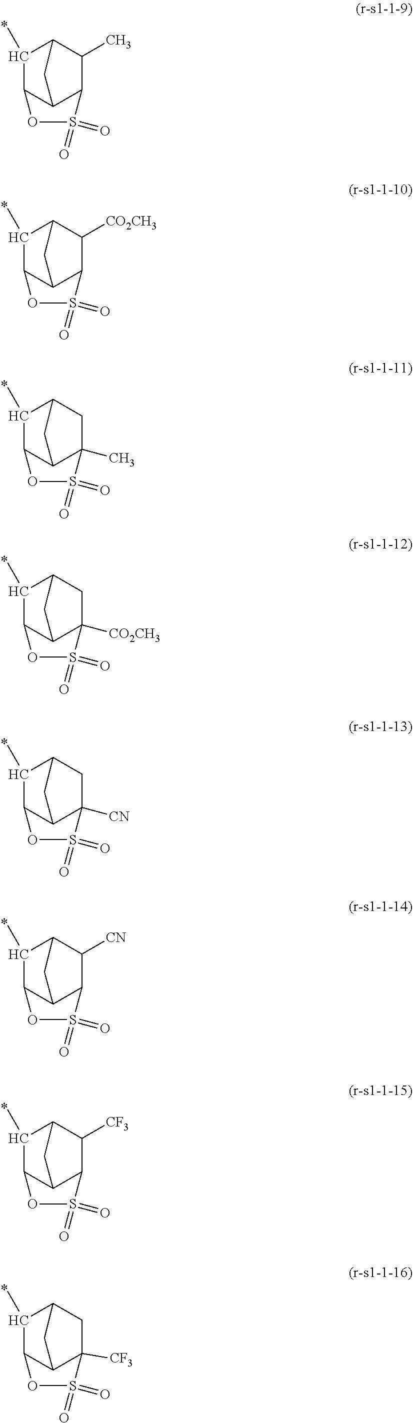

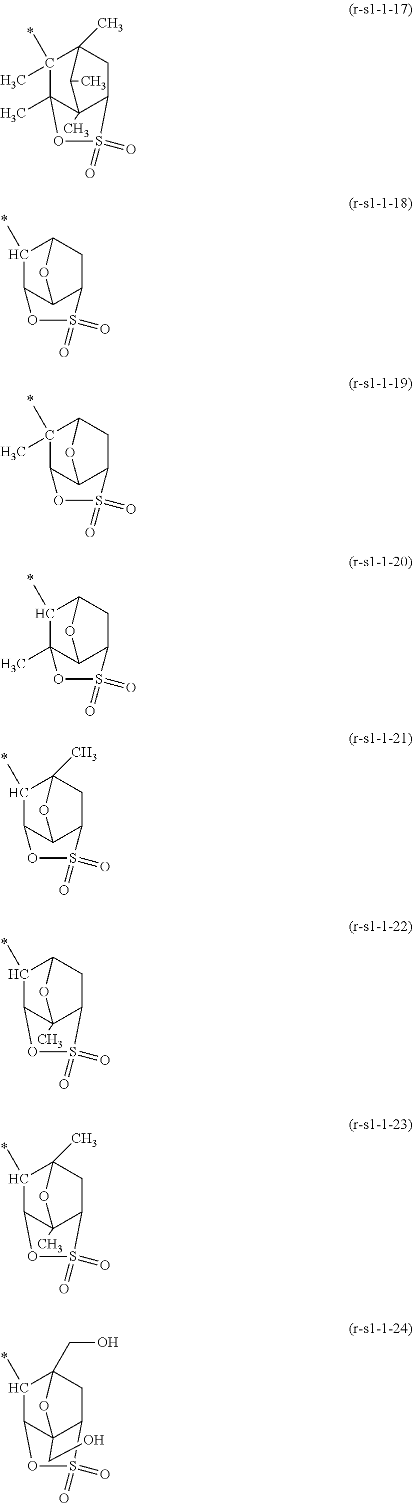

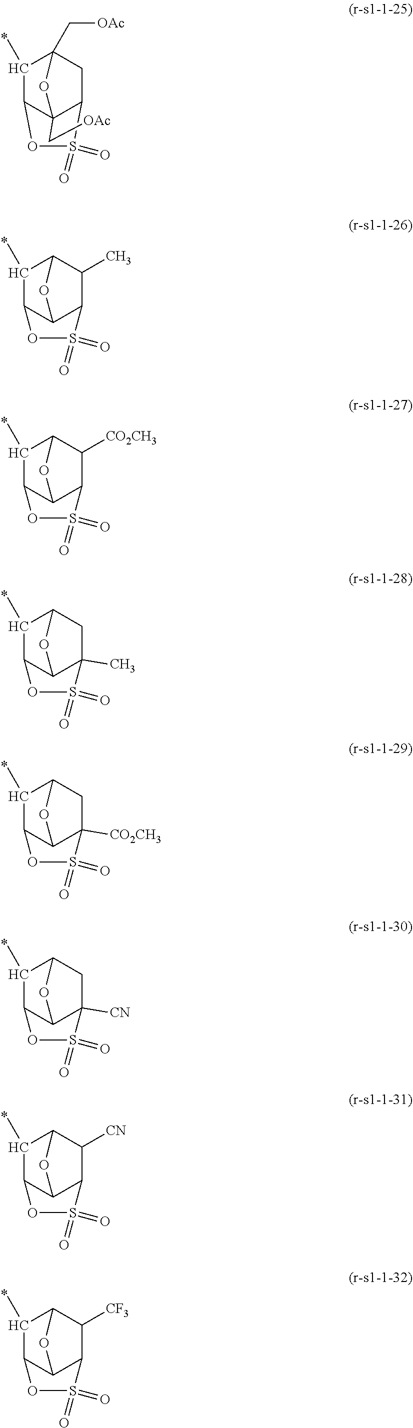

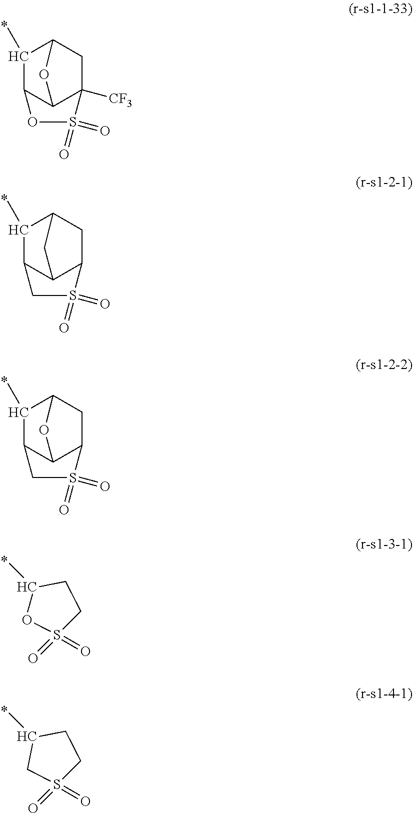

The “carbonate-containing cyclic group” indicates a cyclic group having a ring (a carbonate ring) containing —O—C(═O)—O— in the ring skeleton thereof. In a case where the carbonate ring is counted as the first ring and the group contains only the carbonate ring, the group is referred to as the monocyclic group.

Further, in a case where the group has other ring structures, the group is referred to as the polycyclic group regardless of the structures. The carbonate-containing cyclic group may be a monocyclic group or a polycyclic group.

The carbonate ring-containing cyclic group is not particularly limited, and any group may be used. Specific examples thereof include groups each represented by General Formulae (ax3-r-1) to (ax3-r-3).

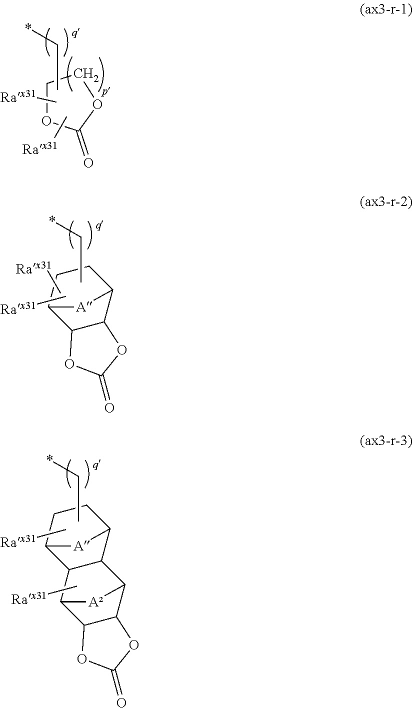

[In the formulae, Ra′^{x31}s independently represent a hydrogen atom, an alkyl group, an alkoxy group, a halogen atom, a halogenated alkyl group, a hydroxyl group, —COOR″, —OC(═O)R″, a hydroxyalkyl group, or a cyano group; R″ represents a hydrogen atom, an alkyl group, a lactone-containing cyclic group, a carbonate-containing cyclic group, or a —SO₂-containing cyclic group; A″ represents an oxygen atom, a sulfur atom, or an alkylene group having 1 to 5 carbon atoms, which may contain an oxygen atom or a sulfur atom; and p′ represents an integer in a range of 0 to 3, and q′ is 0 or 1.]

In General Formulae (ax3-r-2) and (ax3-r-3), A″ is the same as A″ in General Formulae (a2-r-2), (a2-r-3) and (a2-r-5).

Examples of the alkyl group, the alkoxy group, the halogen atom, the halogenated alkyl group, —COOR″, —OC(═O)R″, and the hydroxyalkyl group as Ra′³¹ each include the same ones as those mentioned in the explanation of Ra′²¹ in General Formulae (a2-r-1) to (a2-r-7).

Specific examples of the groups each represented by General Formulae (ax3-r-1) to (ax3-r-3) are as follows.

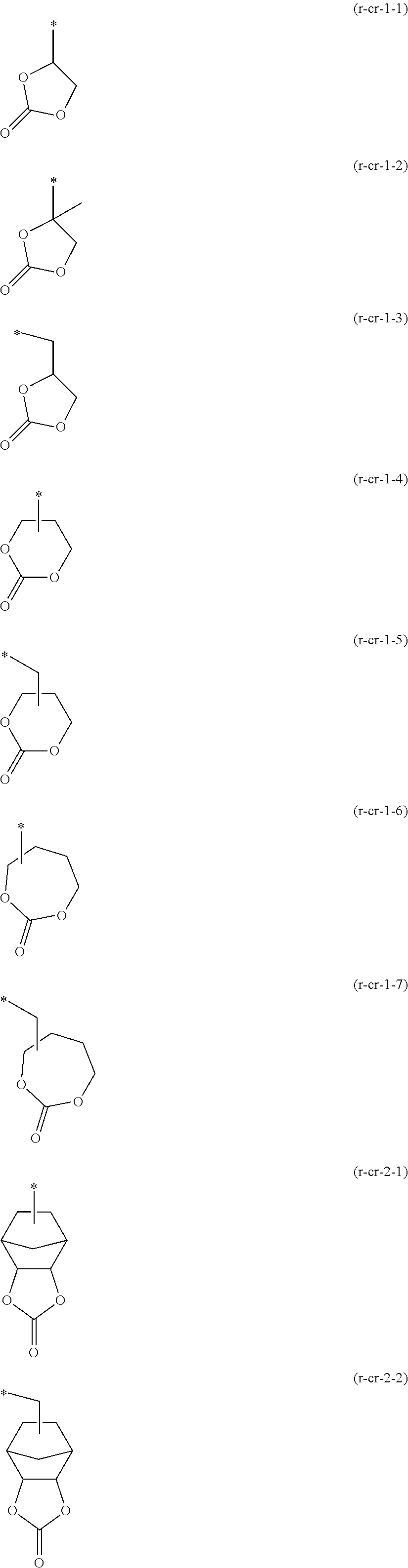

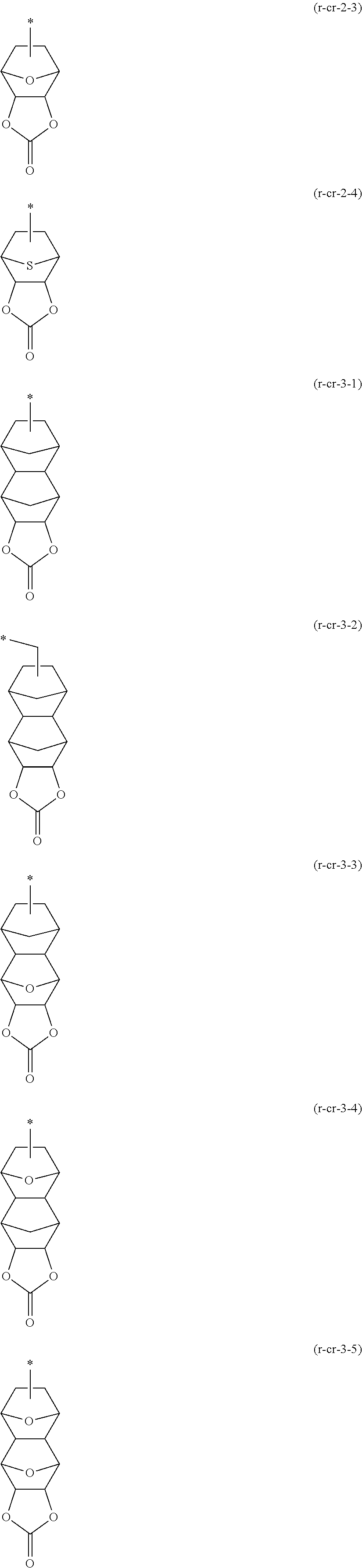

The constitutional unit (a2) contained in the component (A1) may be one kind or may be two or more kinds.

In a case where the component (A1) contains the constitutional unit (a2), the proportion of the constitutional unit (a2) is preferably in a range of 1% to 50% by mole and more preferably in a range of 1% to 40% by mole with respect to the total (100% by mole) of all constitutional units constituting the component (A1).

In regard to constitutional unit (a3):

The component (A1) may further have a constitutional unit (a3) (however, a constitutional unit corresponding to the constitutional unit (a01), the constitutional unit (a02), the constitutional unit (a03), the constitutional unit (a1), or the constitutional unit (a2) is excluded) containing a polar group-containing aliphatic hydrocarbon group. In a case where the component (A1) has the constitutional unit (a3), the hydrophilicity of the component (A) is increased, which contributes to an improvement in resolution. Further, the acid diffusion length can be appropriately adjusted.

Examples of the polar group include a hydroxyl group, a cyano group, a carboxy group, or a hydroxyalkyl group obtained by substituting part of hydrogen atoms of an alkyl group with fluorine atoms, and a hydroxyl group is particularly preferable.

Examples of the aliphatic hydrocarbon group include a linear or branched hydrocarbon group (preferably alkylene group) having 1 to 10 carbon atoms, and a cyclic aliphatic hydrocarbon group (cyclic group). The cyclic group may be a monocyclic group or a polycyclic group. For example, these cyclic groups can be appropriately selected from a large number of groups that have been proposed for a resin for a resist composition for an ArF excimer laser.

In a case where the cyclic group is a monocyclic group, the monocyclic group more preferably has 3 to 10 carbon atoms. Among them, constitutional units derived from the acrylic acid ester that includes an aliphatic monocyclic group containing a hydroxyl group, cyano group, carboxy group, or a hydroxyalkyl group obtained by substituting part of hydrogen atoms of an alkyl group with fluorine atoms are more preferable. Examples of the monocyclic group include a group obtained by removing two or more hydrogen atoms from a monocycloalkane. Specific examples of the monocyclic group include a group obtained by removing two or more hydrogen atoms from monocycloalkanes such as cyclopentane, cyclohexane, and cyclooctane. Among these monocyclic groups, a group obtained by removing two or more hydrogen atoms from cyclopentane or a group obtained by removing two or more hydrogen atoms from cyclohexane are industrially preferable.

In a case where the cyclic group is a polycyclic group, the polycyclic group more preferably has 7 to 30 carbon atoms. Among them, constitutional units derived from the acrylic acid ester that includes an aliphatic polycyclic group containing a hydroxyl group, cyano group, carboxy group, or a hydroxyalkyl group obtained by substituting part of hydrogen atoms of an alkyl group with fluorine atoms are more preferable. Examples of the polycyclic group include a group obtained by removing two or more hydrogen atoms from a bicycloalkane, a tricycloalkane, a tetracycloalkane, or the like. Specific examples thereof include a group obtained by removing two or more hydrogen atoms from polycycloalkanes such as adamantane, norbornane, isobornane, tricyclodecane, and tetracyclododecane. Among these polycyclic groups, a group obtained by removing two or more hydrogen atoms from adamantane, a group obtained by removing two or more hydrogen atoms from norbornane, and a group obtained by removing two or more hydrogen atoms from tetracyclododecane are preferred industrially.

The constitutional unit (a3) is not particularly limited, and any constitutional unit may be used as long as the constitutional unit contains a polar group-containing aliphatic hydrocarbon group.

The constitutional unit (a3) is preferably a constitutional unit containing a polar group-containing aliphatic hydrocarbon group, which is a constitutional unit derived from the acrylic acid ester in which the hydrogen atom bonded to the carbon atom at the α-position may be substituted with a substituent.

In a case where the hydrocarbon group in the polar group-containing aliphatic hydrocarbon group is a linear or branched hydrocarbon group having 1 to 10 carbon atoms, the constitutional unit (a3) is preferably a constitutional unit derived from a hydroxyethyl ester of acrylic acid.

Further, examples of the constitutional unit (a3) include, as a preferred constitutional unit: in a case where the hydrocarbon group in the polar group-containing aliphatic hydrocarbon group is a polycyclic group, a constitutional unit represented by General Formula (a3-1), a constitutional unit represented by General Formula (a3-2), and a constitutional unit represented by General Formula (a3-3); and in a case where the hydrocarbon group is a monocyclic group, a constitutional unit represented by General Formula (a3-4).

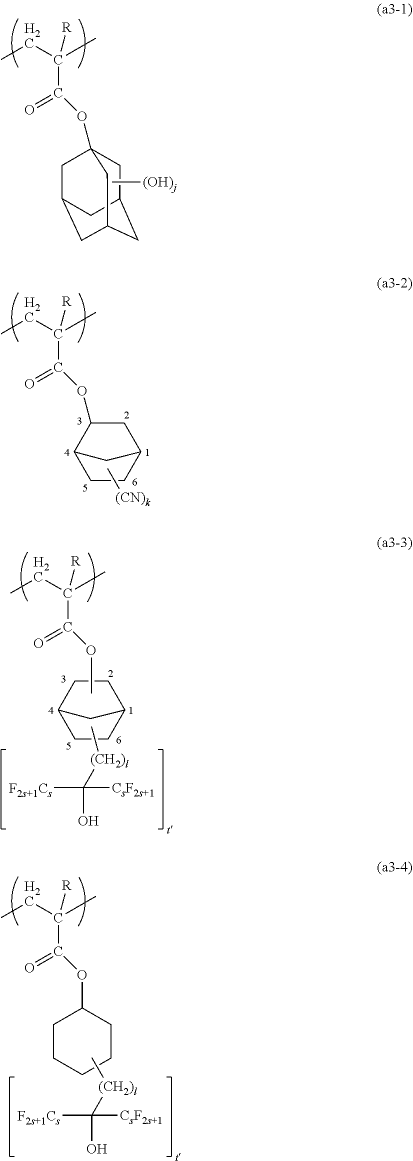

[In the formulae, R is the same as the above, j represents an integer in a range of 1 to 3, k represents an integer in a range of 1 to 3, t′ represents an integer in a range of 1 to 3, 1 represents an integer in a range of 0 to 5, and s represents an integer in a range of 1 to 3.]

In General Formula (a3-1), j represents preferably 1 or 2 and more preferably 1. In a case where j represents 2, it is preferable that the hydroxyl groups are bonded to the 3-position and the 5-position of the adamantyl group. In a case where j represents 1, it is preferable that the hydroxyl group is bonded to the 3-position of the adamantyl group.

It is preferable that j represents 1, and it is particularly preferable that the hydroxyl group is bonded to the 3-position of the adamantyl group.

In General Formula (a3-2), k represents preferably 1. The cyano group is preferably bonded to the 5- or 6-position of the norbornyl group.

In General Formula (a3-3), it is preferable that t′ represents 1. It is preferable that 1 represents 1. It is preferable that s represents 1. Further, it is preferable that a 2-norbornyl group or 3-norbornyl group is bonded to the terminal of the carboxy group of the acrylic acid. It is preferable that the fluorinated alkyl alcohol is bonded to the 5- or 6-position of the norbornyl group.

In General Formula (a3-4), it is preferable that t′ represents 1 or 2. It is preferable that 1 represents 0 or 1. It is preferable that s represents 1. It is preferable that the fluorinated alkyl alcohol is bonded to the 3- or 5-position of the cyclohexyl group.

The constitutional unit (a3) which contained in the component (A1) may be one kind or may be two or more kinds.

In a case where the component (A1) has the constitutional unit (a3), the proportion of the constitutional unit (a3) is preferably 1% to 30% by mole, more preferably 2% to 25% by mole, and still more preferably 5% to 20% by mole, with respect to the total (100% by mole) of all constitutional units constituting the component (A1).

In a case where the proportion of the constitutional unit (a3) is equal to or larger than the lower limit value of the above-described preferred range, the effect obtained by allowing the constitutional unit (a3) to be contained can be sufficiently achieved by the effect described above. In a case where the proportion of the constitutional unit (a3) is equal to or smaller than the upper limit value of the above-described preferred range, balance with other constitutional units can be obtained, and various lithography characteristics are improved.

In regard to constitutional unit (a4):

The component (A1) may further have a constitutional unit (a4) containing an acid non-dissociable aliphatic cyclic group.

In a case where the component (A1) has the constitutional unit (a4), the dry etching resistance of the formed resist pattern is improved. Further, the hydrophobicity of the component (A) is improved. The improvement in hydrophobicity contributes to the improvement in resolution, resist pattern shape, and the like, particularly in the case of a solvent developing process.

The “acid non-dissociable cyclic group” in the constitutional unit (a4) is a cyclic group that remains in the constitutional unit without being dissociated even when an acid acts in a case where the acid is generated in the resist composition by exposure (for example, in a case where an acid is generated from the constitutional unit that generates acid upon exposure or the component (B)).

The constitutional unit (a4) is preferably, for example, a constitutional unit derived from the acrylic acid ester containing an acid non-dissociable aliphatic cyclic group. As the cyclic group, a large number of cyclic groups known in the related art as the cyclic groups which are used as a resin component of a resist composition for an ArF excimer laser, a KrF excimer laser (preferably an ArF excimer laser), or the like can be used.

The cyclic group is preferably at least one selected from a tricyclodecyl group, an adamantyl group, a tetracyclododecyl group, an isobornyl group, and a norbornyl group, from the viewpoint of industrial availability. These polycyclic groups may have, as a substituent, a linear or branched alkyl group having 1 to 5 carbon atoms.

Specific examples of the constitutional unit (a4) include constitutional units each represented by General Formulae (a4-1) to (a4-7).

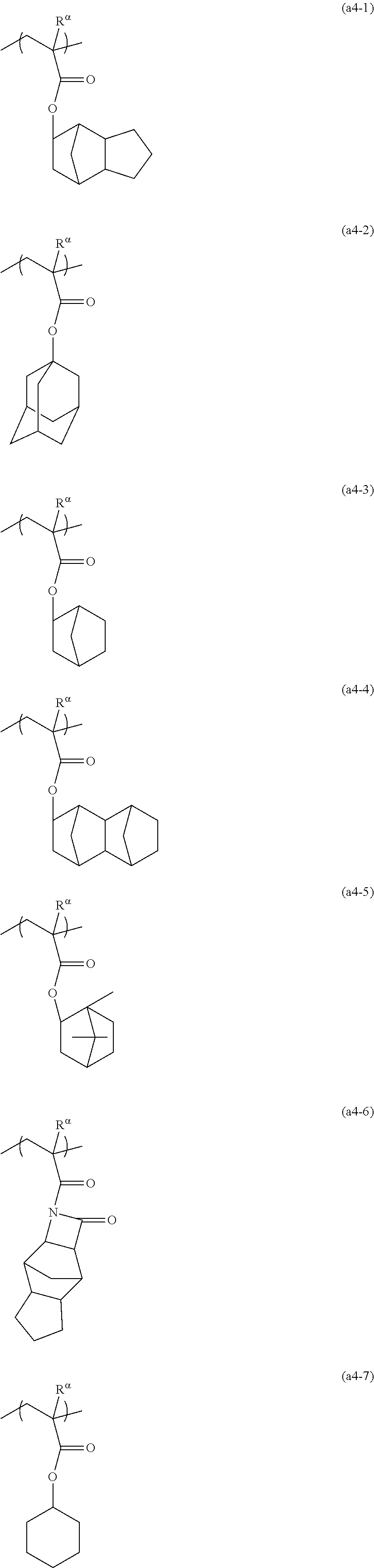

[In the formula, R^{α} is the same as above.]

The constitutional unit (a4) contained in the component (A1) may be one kind or may be two or more kinds.

In a case where the component (A1) has the constitutional unit (a4), the proportion of the constitutional unit (a4) is preferably 1% to 40% by mole and more preferably 5% to 20% by mole, with respect to the total (100% by mole) of all constitutional units constituting the component (A1).

In a case where the proportion of the constitutional unit (a4) is equal to or larger than the lower limit value of the preferred range, the effect obtained by allowing the constitutional unit (a4) to be contained can be sufficiently achieved. In a case where the proportion of the constitutional unit (a4) is equal to or smaller than the upper limit value of the preferred range, the balance with other constitutional units is obtained easily.

The component (A1) contained in the resist composition may be used alone or in a combination of two or more kinds thereof.

The component (A1) contains a polymeric compound (A01) having a repeating structure of the constitutional unit (a01), the constitutional unit (a02), and the constitutional unit (a03), and the preferred component (A1) is a polymeric compound (A011) consisting of a repeating structure of the constitutional unit (a01), the constitutional unit (a02), and the constitutional unit (a03).

The proportion of the constitutional unit (a01) in the polymeric compound (A01) is preferably 20% by mole or more and 70% by mole or less, more preferably 30% by mole or more and 60% by mole or less, still more preferably 40% by mole or more and 60% by mole or less, and particularly preferably 45% by mole or more and 55% by mole or less, with respect to the total (100% by mole) of all constitutional units constituting the component (A1).

The proportion of the constitutional unit (a02) in the polymeric compound (A01) is preferably 10% by mole or more and 60% by mole or less, more preferably 20% by mole or more and 60% by mole or less, still more preferably 20% by mole or more and 50% by mole or less, and particularly preferably 35% by mole or more and 45% by mole or less, with respect to the total (100% by mole) of all constitutional units constituting the component (A1).

The proportion of the constitutional unit (a03) in the polymeric compound (A01) is preferably 1% by mole or more and 50% by mole or less, more preferably 5% by mole or more and 30% by mole or less, still more preferably 5% by mole or more and 20% by mole or less, and particularly preferably 5% by mole or more and 15% by mole or less, with respect to the total (100% by mole) of all constitutional units constituting the component (A1).

The molar ratio of the content of the constitutional unit (a03) to the content of the constitutional unit (a02) (the constitutional unit (a02):the constitutional unit (a03)) in the polymeric compound (A01) is preferably in a range of 10:90 to 90:10, more preferably in a range of 10:90 to 60:40, still more preferably in a range of 10:90 to 50:50, and particularly preferably in a range of 10:90 to 40:60.

The molar ratio of the content of the constitutional unit (a01) to the total content of the constitutional unit (a02) and the constitutional unit (a03) (the constitutional unit (a01): the constitutional unit (a02):the constitutional unit (a03)) in the polymeric compound (A01) is preferably in a range of 80:20 to 20:80, more preferably in a range of 70:30 to 30:70, and still more preferably in a range of 60:40 to 40:60.

The component (A1) can be produced by dissolving, in a polymerization solvent, each monomer from which the constitutional unit is derived, adding thereto a radical polymerization initiator such as azobisisobutyronitrile (AIBN) or dimethyl azobisisobutyrate (for example, V-601) to carry out polymerization.

Alternatively, the component (A1) can be produced by dissolving, in a polymerization solvent, a monomer from which the constitutional unit (a01) is derived, a monomer from which the constitutional unit (a02) is derived, a monomer from which the constitutional unit (a03) is derived, and, as necessary, a monomer from which a constitutional unit other than these constitutional units is derived, adding thereto a radical polymerization initiator as described above to carry out polymerization.

Further, a —C(CF₃)₂—OH group may be introduced into the terminal of the component (A1) during the polymerization using a chain transfer agent such as HS—CH₂—CH₂—CH₂—C(CF₃)₂—OH in combination. As described above, a copolymer into which a hydroxyalkyl group, which is formed by substituting part of hydrogen atoms in an alkyl group with fluorine atoms, has been introduced is effective for reducing development defects and reducing line edge roughness (LER: uneven irregularities of a line side wall).

The weight average molecular weight (Mw) (based on the polystyrene-equivalent value determined by gel permeation chromatography (GPC)) of the component (A1), which is not particularly limited, is preferably 1,000 to 50,000, more preferably 2,000 to 30,000, and still more preferably 3,000 to 20,000.

In a case where Mw of the component (A1) is equal to or smaller than the upper limit value of this preferred range, the resist composition exhibits a solubility in a solvent for a resist, which is enough for using the resist composition as a resist composition. On the other hand, in a case where Mw of the component (A1) is equal to or larger than the lower limit value of this preferred range, dry etching resistance and the cross-sectional shape of the resist pattern become excellent.

Further, the polydispersity (Mw/Mn) of the component (A1) is not particularly limited but is preferably 1.0 to 4.0, more preferably 1.0 to 3.0, and particularly preferably 1.0 to 2.0. Mn represents the number average molecular weight.

In regard to component (A2)

In the resist composition according to the present embodiment, a base material component (hereinafter, referred to as “component (A2)”) that exhibits changed solubility in a developing solution under action of acid, which does not correspond to the component (A1), may be used in combination as the component (A).

The component (A2) is not particularly limited and may be freely selected and used from a large number of known base material components for the chemically amplified resist composition in the related art.

As the component (A2), a polymeric compound or a low molecular weight compound may be used alone or in a combination of two or more kinds thereof.

The proportion of the component (A1) in the component (A) is preferably 25% by mass or more, more preferably 50% by mass or more, and still more preferably 75% by mass or more, and may be 100% by mass, with respect to the total mass of the component (A). In a case where the proportion is 25% by mass or more, a resist pattern having various excellent lithography characteristics, such as sensitivity, resolution, and roughness amelioration can be easily formed.

The content of the component (A) in the resist composition according to the present embodiment may be adjusted depending on the resist film thickness to be formed.

<Compound (D1)>

The resist composition according to the present embodiment further contains a compound (D1) in addition to the component (A). The compound (D1) is one or more compounds selected from the group consisting of a compound represented by General Formula (d1-1) and a compound represented by General Formula (d1-2), and it acts, for example, as a quencher (an acid diffusion controlling agent) which traps the acid generated in the resist composition upon exposure.

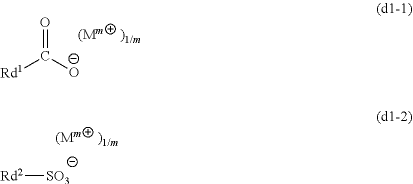

[In the formulae, Rd¹ and Rd² each independently represent a cyclic group which may have a substituent, a chain alkyl group which may have a substituent, or a chain-like alkenyl group which may have a substituent. However, the carbon atom adjacent to the S atom in Rd² in General Formula (d1-2) has no fluorine atom bonded thereto. m represents an integer of 1 or more, and each M^{m+} independently represents an m-valent organic cation.]

{Component (d1-1)}

Anion Moiety

[In General Formula (d1-1), Rd¹ represents a cyclic group which may have a substituent, a chain alkyl group which may have a substituent, or a chain-like alkenyl group which may have a substituent.

Cyclic group which may have substituent:

The cyclic group is preferably a cyclic hydrocarbon group, and the cyclic hydrocarbon group may be an aromatic hydrocarbon group or an aliphatic hydrocarbon group. The aliphatic hydrocarbon group indicates a hydrocarbon group that has no aromaticity. The aliphatic hydrocarbon group may be saturated or unsaturated.

In general, the aliphatic hydrocarbon group is preferably saturated.

The aromatic hydrocarbon group represents a hydrocarbon group having an aromatic ring. The aromatic hydrocarbon group has preferably 3 to 30 carbon atoms, more preferably 5 to 30, still more preferably 5 to 20, particularly preferably 6 to 15, and most preferably 6 to 10. However, the number of carbon atoms in a substituent is not included in the number of carbon atoms.

Specific examples of the aromatic ring contained in the aromatic hydrocarbon group include benzene, fluorene, naphthalene, anthracene, phenanthrene, biphenyl, and an aromatic heterocyclic ring obtained by substituting part of carbon atoms constituting one of these aromatic rings with a hetero atom. Examples of the hetero atom in the aromatic heterocyclic rings include an oxygen atom, a sulfur atom, and a nitrogen atom.

Specific examples of the aromatic hydrocarbon group include a group (an aryl group such as a phenyl group or a naphthyl group) obtained by removing one hydrogen atom from the above-described aromatic ring and a group (an arylalkyl group such as a benzyl group, a phenethyl group, a 1-naphthylmethyl group, a 2-naphthylmethyl group, 1-naphthylethyl group, or a 2-naphthylethyl group) obtained by substituting one hydrogen atom in the aromatic ring with an alkylene group. The alkylene group (an alkyl chain in the arylalkyl group) has preferably 1 to 4 carbon atoms, more preferably 1 or 2 carbon atoms, and particularly preferably 1 carbon atom.

Examples of the cyclic aliphatic hydrocarbon group include aliphatic hydrocarbon groups containing a ring in the structure thereof.

Examples of the aliphatic hydrocarbon group containing a ring in the structure thereof include an alicyclic hydrocarbon group (a group obtained by removing one hydrogen atom from an aliphatic hydrocarbon ring), a group obtained by bonding an alicyclic hydrocarbon group to the terminal of a linear or branched aliphatic hydrocarbon group, and a group by interposing an alicyclic hydrocarbon group in a linear or branched aliphatic hydrocarbon group.

The alicyclic hydrocarbon group has preferably 3 to 20 carbon atoms and more preferably 3 to 12 carbon atoms.

The alicyclic hydrocarbon group may be a polycyclic group or a monocyclic group. The monocyclic alicyclic hydrocarbon group is preferably a group obtained by removing one or more hydrogen atoms from a monocycloalkane. The monocycloalkane has preferably 3 to 6 carbon atoms, and specific examples thereof include cyclopentane and cyclohexane. The polycyclic alicyclic hydrocarbon group is preferably a group obtained by removing one or more hydrogen atoms from a polycycloalkane, and the number of carbon atoms of the polycycloalkane is preferably 7 to 30. Among them, the polycycloalkane is more preferably polycycloalkanes having a crosslinked ring-based polycyclic skeleton, such as adamantane, norbornane, isobornane, tricyclodecane, and tetracyclododecane, and polycycloalkanes having a condensed ring-based polycyclic skeleton, such as a cyclic group having a steroid skeleton.

The cyclic hydrocarbon group may contain a hetero atom such as a heterocyclic ring. Specific examples thereof include lactone-containing cyclic groups each represented by General Formulae (a2-r-1) to (a2-r-7), —SO₂-containing cyclic groups each represented by General Formulae (a5-r-1) to (a5-r-4), and other heterocyclic groups each represented by Chemical Formulae (r-hr-1) to (r-hr-16). * represents a bonding site.

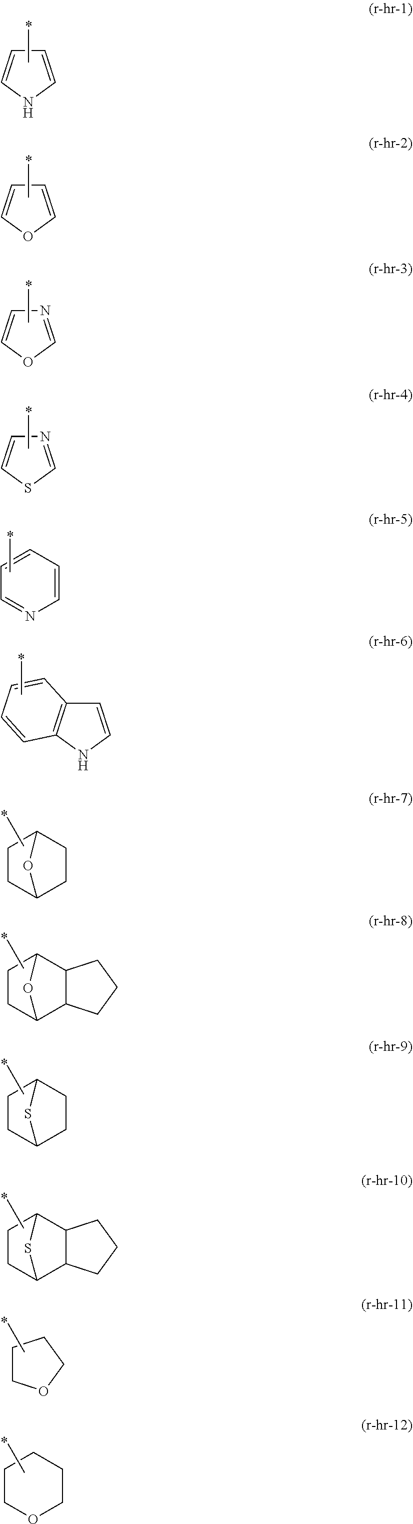

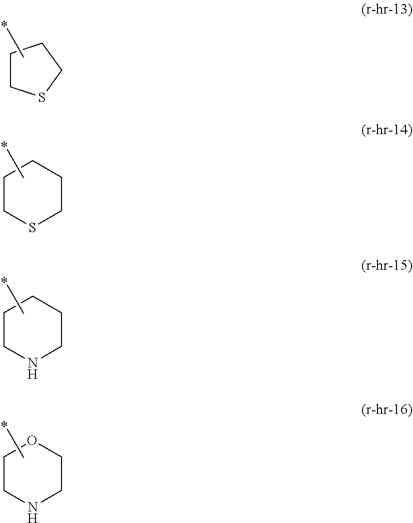

Examples of the substituent of the cyclic group as Rd¹ include an alkyl group, an alkoxy group, a halogen atom, a halogenated alkyl group, a hydroxyl group, a carbonyl group, and a nitro group.

Chain alkyl group which may have substituent:

The chain alkyl group as Rd¹ may be linear or branched.

The linear alkyl group has preferably 1 to 20 carbon atoms, more preferably 1 to 15 carbon atoms, and most preferably 1 to 10 carbon atoms.

The branched alkyl group has preferably 3 to 20 carbon atoms, more preferably 3 to 15, and most preferably 3 to 10. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-like alkenyl group which may have substituent:

A chain-like alkenyl group as Rd¹ may be linear or branched, and the chain-like alkenyl group preferably has 2 to 10 carbon atoms, more preferably 2 to 5 carbon atoms, still more preferably 2 to 4 carbon atoms, and particularly preferably 3 carbon atoms. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Among the above, the chain-like alkenyl group is preferably a linear alkenyl group, more preferably a vinyl group or a propenyl group, and particularly preferably a vinyl group.

Examples of the substituent in the chain alkyl group or alkenyl group as Rd¹ include an alkoxy group, a halogen atom, a halogenated alkyl group, a hydroxyl group, a carbonyl group, a nitro group, and an amino group.

Among these, Rd¹ is preferably an aromatic hydrocarbon group which may have a substituent, an aliphatic cyclic group which may have a substituent, or a chain alkyl group which may have a substituent. Examples of the substituent which may be contained in these groups include a hydroxyl group, an oxo group, an alkyl group, an aryl group, a fluorine atom, a fluorinated alkyl group, lactone-containing cyclic groups each represented by General Formulae (a2-r-1) to (a2-r-7), an ether bond, an ester bond, and a combination thereof. In a case where an ether bond or an ester bond is contained as the substituent, the substituent may be bonded through an alkylene group, and the substituent in this case is preferably linking groups each represented by General Formulae (y-a1-1) to (y-a1-7). In a case where linking groups each represented by General Formulae (y-a1-1) to (y-a1-7) are contained as the substituent, the one that is bonded to Rd¹ in General Formula (d1-1) is V′¹⁰¹ in General Formulae (y-a1-1) to (y-a1-7).

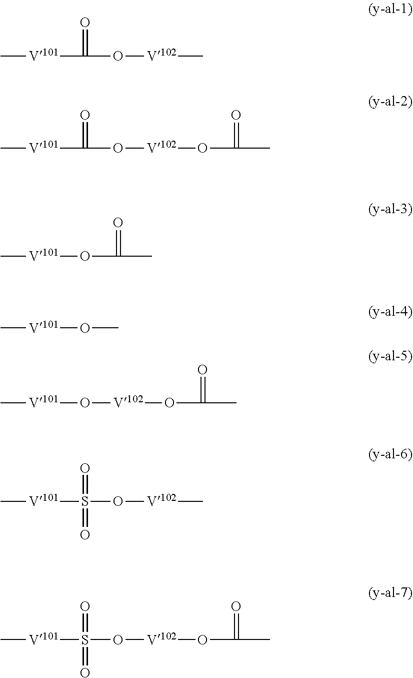

[In the formulae, V′¹⁰¹ represents a single bond or an alkylene group having 1 to 5 carbon atoms, and V′¹⁰² represents a divalent saturated hydrocarbon group having 1 to 30 carbon atoms.]

The divalent saturated hydrocarbon group as V′¹⁰² is preferably an alkylene group having 1 to 30 carbon atoms, more preferably an alkylene group having 1 to 10 carbon atoms, and still more preferably an alkylene group having 1 to 5 carbon atoms.

The alkylene group as V′¹⁰¹ and V′¹⁰² may be a linear alkylene group or a branched alkylene group, and a linear alkylene group is preferable.

Specific examples of the alkylene group as V′¹⁰¹ and V′¹⁰² include a methylene group [—CH₂—]; an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, or —C(CH₂CH₃)₂—; an ethylene group [—CH₂CH₂—]; an alkylethylene group such as —CH(CH₃)CH₂—, —CH(CH₃)CH(CH₃)—, —C(CH₃)₂CH₂—, or —CH(CH₂CH₃)CH₂—; a trimethylene group (n-propylene group) [—CH₂CH₂CH₂—]; an alkyltrimethylene group such as —CH(CH₃)CH₂CH₂— or —CH₂CH(CH₃)CH₂—; a tetramethylene group [—CH₂CH₂CH₂CH₂—]; an alkyltetramethylene group such as —CH(CH₃)CH₂CH₂CH₂—, or —CH₂CH(CH₃)CH₂CH₂—; and a pentamethylene group [—CH₂CH₂CH₂CH₂CH₂—].

Further, part of methylene groups in the alkylene group as V′¹⁰¹ and V′¹⁰² may be substituted with a divalent aliphatic cyclic group having 5 to 10 carbon atoms. The aliphatic cyclic group is preferably a divalent group obtained by removing one hydrogen atom from the cyclic aliphatic hydrocarbon group (a monocyclic aliphatic hydrocarbon group or a polycyclic aliphatic hydrocarbon group) as Ra′³ in General Formula (a1-r-1), and more preferably a cyclohexylene group, a 1,5-adamantylene group, or a 2,6-adamantylene group.

Suitable examples of the aromatic hydrocarbon group as Rd¹ include a phenyl group, a naphthyl group, and a polycyclic structure (a polycyclic structure including a bicyclooctane skeleton and a ring structure other than the bicyclooctane skeleton) including a bicyclooctane skeleton.

The aliphatic cyclic group as Rd¹ is preferably a group obtained by removing one or more hydrogen atoms from polycycloalkanes such as adamantane, norbornane, isobornane, tricyclodecane, and tetracyclododecane.

The chain alkyl group as Rd¹ preferably has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl group, or a decyl group, and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, or a 4-methylpentyl group.

In a case where the chain alkyl group is a fluorinated alkyl group having a fluorine atom or a fluorinated alkyl group as a substituent, the fluorinated alkyl group has preferably 1 to 11 carbon atoms, more preferably 1 to 8 carbon atoms, and still more preferably 1 to 4 carbon atoms. The fluorinated alkyl group may contain an atom other than a fluorine atom. Examples of the atom other than a fluorine atom include an oxygen atom, a sulfur atom, and a nitrogen atom.

Specific examples of the preferred anion moiety for the component (d1-1) are as follows.

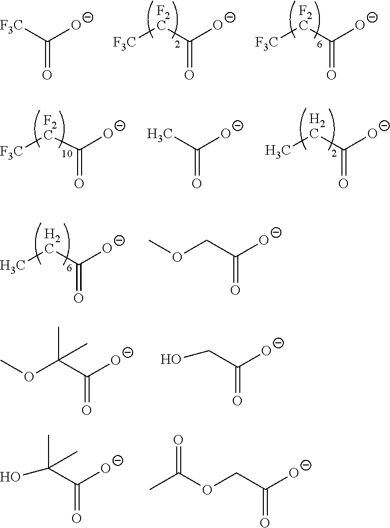

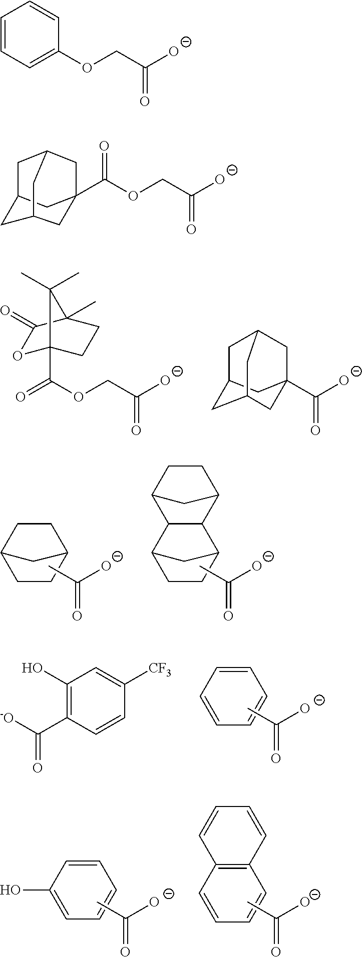

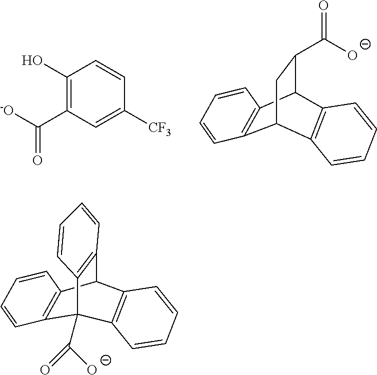

Cation Moiety

In General Formula (d1-1), M^{m+} represents an m-valent organic cation. Among these, a sulfonium cation and an iodonium cation are preferable.

m represents an integer of 1 or more.

Preferred examples of the cation moiety ((M^{m+})_{1/m}) include organic cations each represented by General Formulae (ca-1) to (ca-5).

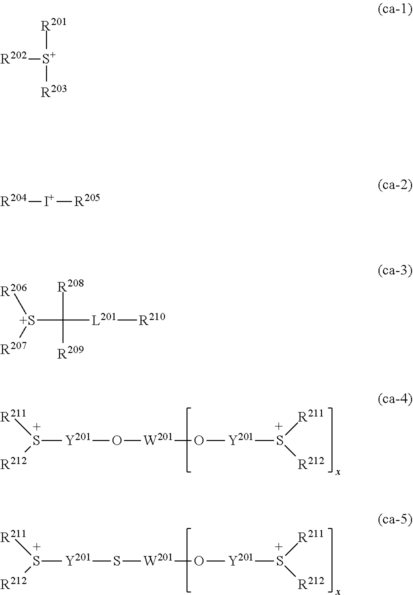

[In the formula, R²⁰¹ to R²⁰⁷, R²¹¹, and R²¹² each independently represent an aryl group, an alkyl group, or an alkenyl group, each of which may have a substituent. R²⁰¹ to R²⁰³, R²⁰⁶ and R²⁰⁷, or R²¹¹ and R²¹² may be bonded to each other to form a ring together with the sulfur atoms in the formulae. R²⁰⁸ and R²⁰⁹ each independently represent a hydrogen atom or an alkyl group having 1 to 5 carbon atoms. R²¹⁰ represents an aryl group which may have a substituent, an alkyl group which may have a substituent, an alkenyl group which may have a substituent, or a —SO₂-containing cyclic group which may have a substituent. L²⁰¹ represents —C(═O)— or —C(═O)—O—. Y²⁰¹s each independently represent an arylene group, an alkylene group, or an alkenylene group. x represents 1 or 2. W²⁰¹ represents an (x+1)-valent linking group.]

In General Formulae (ca-1) to (ca-5), examples of the aryl group as R²⁰¹ to R²⁰⁷, R²¹¹, and R²¹² include an unsubstituted aryl group having 6 to 20 carbon atoms, and a phenyl group or a naphthyl group is preferable.

The alkyl group as R²⁰¹ to R²⁰⁷, R²¹¹, and R²¹² is preferably a chain-like or cyclic alkyl group having 1 to 30 carbon atoms.

The alkenyl group as R²⁰¹ to R²⁰⁷, R²¹¹, and R²¹² preferably has 2 to 10 carbon atoms.

Examples of the substituent which may be contained in R²⁰¹ to R²⁰⁷ and R²¹⁰ to R²¹² include an alkyl group, a halogen atom, a halogenated alkyl group, a carbonyl group, a cyano group, an amino group, an aryl group, and groups each represented by General Formulae (ca-r-1) to (ca-r-7) shown below.

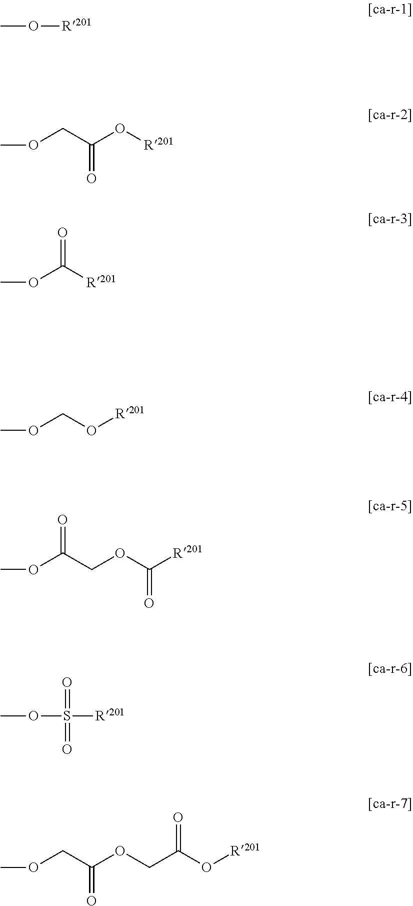

[In the formulae, each R′²⁰¹ independently represent a hydrogen atom, a cyclic group which may have a substituent, a chain alkyl group which may have a substituent, or a chain-like alkenyl group which may have a substituent.]

Examples of the cyclic group which may have a substituent, the chain alkyl group which may have a substituent, and the chain-like alkenyl group which may have a substituent, as R′²⁰¹, each include the same ones as the cyclic group which may have a substituent, the chain alkyl group which may have a substituent, and the chain-like alkenyl group which may have a substituent, as Rd¹ in General Formula (d1-1).

As the cyclic group which may have a substituent, the chain alkyl group which may have a substituent, or the chain-like alkenyl group which may have a substituent, as R′²⁰¹, the same one as the acid dissociable group represented by above-described General Formula (a1-r-2) can be mentioned as the cyclic group which may have a substituent or the chain alkyl group which may have a substituent, in addition to the groups described above.

Among them, R′²⁰¹ is preferably a cyclic group which may have a substituent and more preferably a cyclic hydrocarbon group which may have a substituent. More specific examples thereof preferably include a phenyl group; a naphthyl group; a group obtained by removing one or more hydrogen atoms from a polycycloalkane; any one of lactone-containing cyclic groups each represented by General Formulae (a2-r-1) to (a2-r-7); and any one of —SO₂-containing cyclic groups each represented by General Formulae (a5-r-1) to (a5-r-4).

In General Formulae (ca-1) to (ca-5), in a case where R²⁰¹ to R²⁰³, R²⁰⁶ and R²⁰⁷, or R²¹¹ and R²¹² are bonded to each other to form a ring with a sulfur atom in the formula, these groups may be bonded to each other via a hetero atom such as a sulfur atom, an oxygen atom or a nitrogen atom, or a functional group such as a carbonyl group, —SO—, —SO₂—, —SO₃—, —COO—, —CONH—, or —N(R_{N})-(here, R_{N} represents an alkyl group having 1 to 5 carbon atoms). As the ring to be formed, a ring containing the sulfur atom in the formula in the ring skeleton thereof is preferably a 3-membered to 10-membered ring and particularly preferably a 5-membered to 7-membered ring, including the sulfur atom. Specific examples of the ring to be formed include a thiophene ring, a thiazole ring, a thianthrene ring, a benzothiophene ring, a dibenzothiophene ring, a 9H-thioxanthene ring, a thioxanthone ring, a thianthrene ring, a phenoxathiin ring, a tetrahydrothiophenium ring, and a tetrahydrothiopyranium ring.

R²⁰⁸ and R²⁰⁹ each independently represent a hydrogen atom or an alkyl group having 1 to 5 carbon atoms and are preferably a hydrogen atom or an alkyl group having 1 to 3 carbon atoms. In a case where R²⁰⁸ and R²⁰⁹ each independently represent an alkyl group, R²⁰⁸ and R²⁰⁹ may be bonded to each other to form a ring.

R²¹⁰ represents an aryl group which may have a substituent, an alkyl group which may have a substituent, an alkenyl group which may have a substituent, or a —SO₂-containing cyclic group which may have a substituent.

Examples of the aryl group as R²¹⁰ include an unsubstituted aryl group having 6 to 20 carbon atoms, and a phenyl group or a naphthyl group is preferable.

The alkyl group as R²¹⁰, a chain-like or cyclic alkyl group having 1 to 30 carbon atoms is preferable.

The alkenyl group as R²¹⁰ preferably has 2 to 10 carbon atoms.

The —SO₂-containing cyclic group which may have a substituent, as R²¹⁰, is preferably a “—SO₂-containing polycyclic group”, and more preferably a group represented by General Formula (a5-r-1).

Each Y²⁰¹ independently represents an arylene group, an alkylene group, or an alkenylene group.

Examples of the arylene group as Y²⁰¹ include groups obtained by removing one hydrogen atom from an aryl group exemplified as the aromatic hydrocarbon group as Ya^{x0} described above.

Examples of the alkylene group and alkenylene group as Y²⁰¹ include groups obtained by removing one hydrogen atom from the chain alkyl group or the chain-like alkenyl group as R′²⁰¹ described above.

In General Formula (ca-4), x represents 1 or 2.

W²⁰¹ represents an (x+1)-valent linking group, that is, a divalent or trivalent linking group.

The divalent linking group as W²⁰¹ is preferably a divalent hydrocarbon group which may have a substituent, and as examples thereof include the same divalent hydrocarbon group, which may have a substituent, as Ya²¹ in General Formula (a2-1) described above. The divalent linking group as W²⁰¹ may be linear, branched, or cyclic and is preferably cyclic. Among them, a group obtained by combining two carbonyl groups at both terminals of an arylene group is preferable. Examples of the arylene group include a phenylene group and a naphthylene group, and a phenylene group is particularly preferable.

Examples of the trivalent linking group as W²⁰¹ include a group obtained by removing one hydrogen atom from the above-described divalent linking group as W²⁰¹ and a group obtained by bonding the divalent linking group to another divalent linking group. The trivalent linking group as W²⁰¹ is preferably a group obtained by bonding two carbonyl groups to an arylene group.

Suitable cations represented by General Formula (ca-1) are shown below.

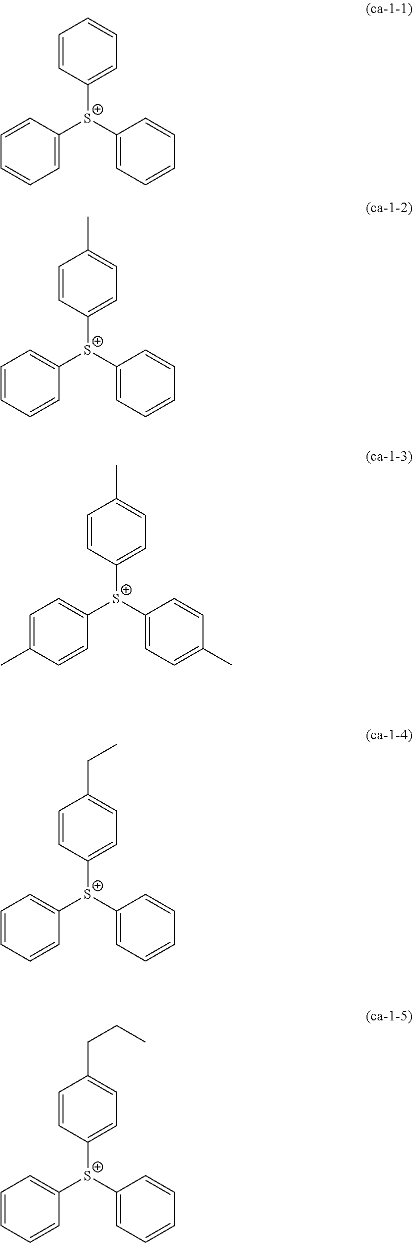

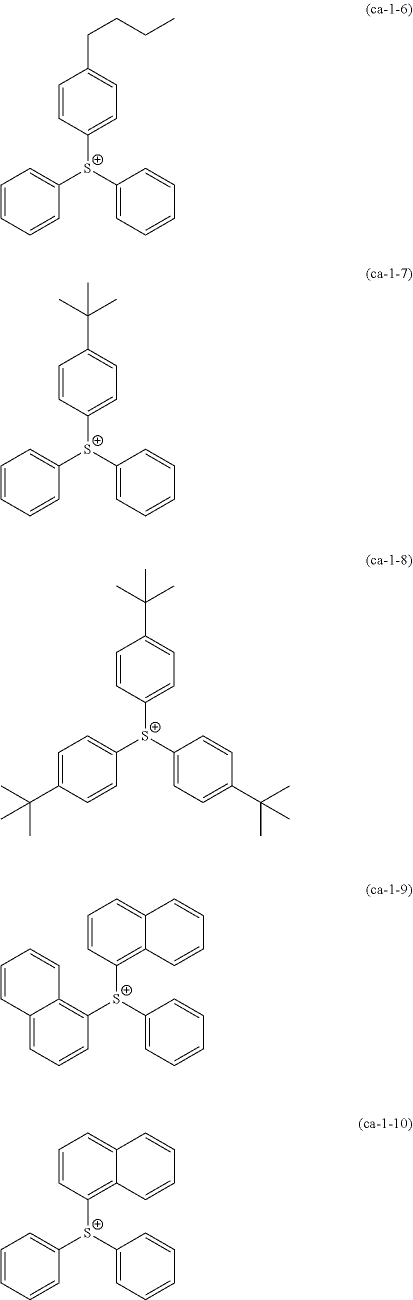

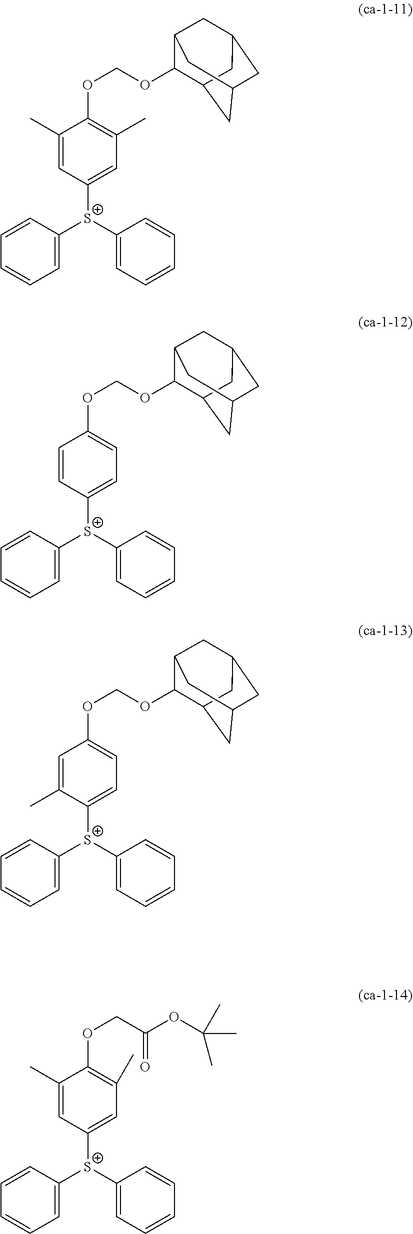

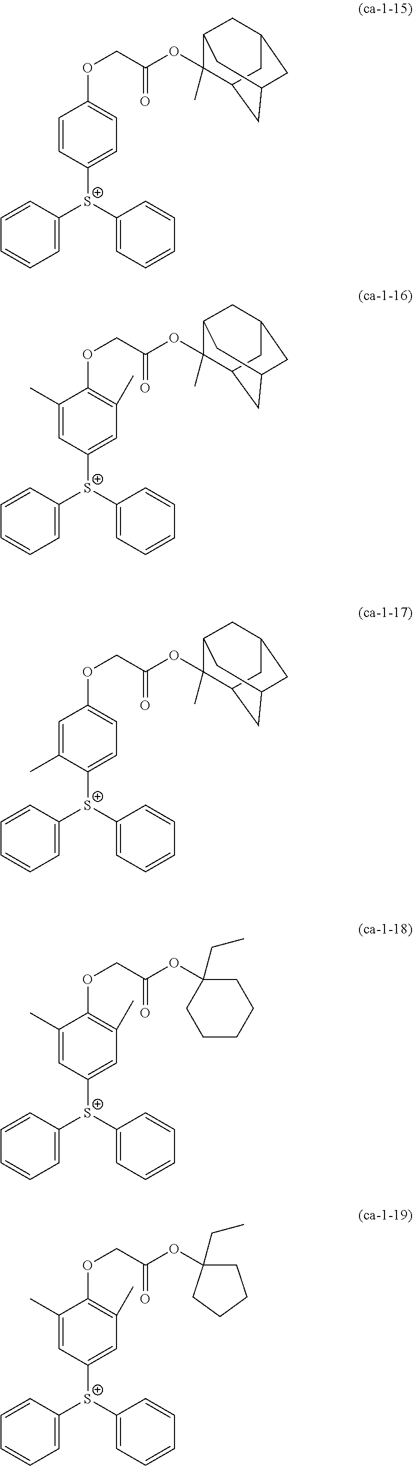

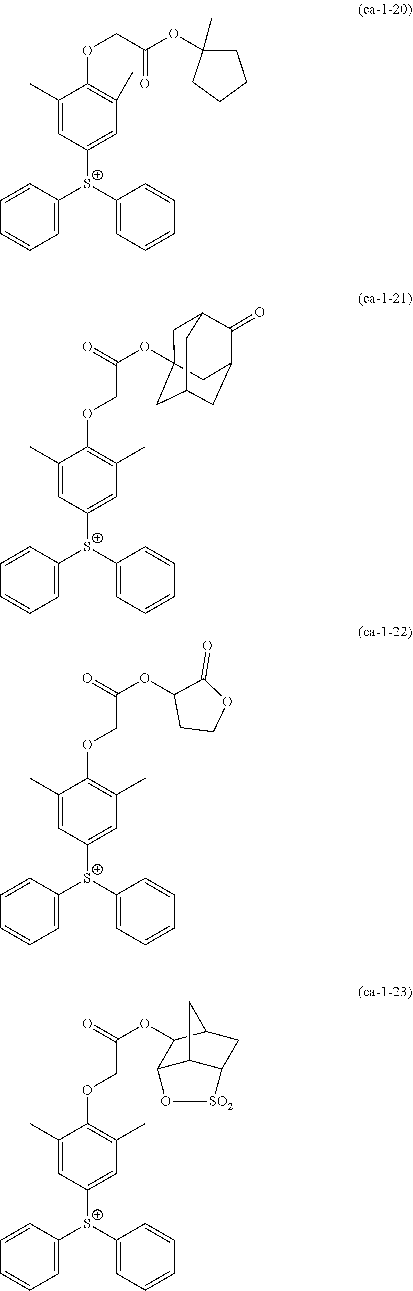

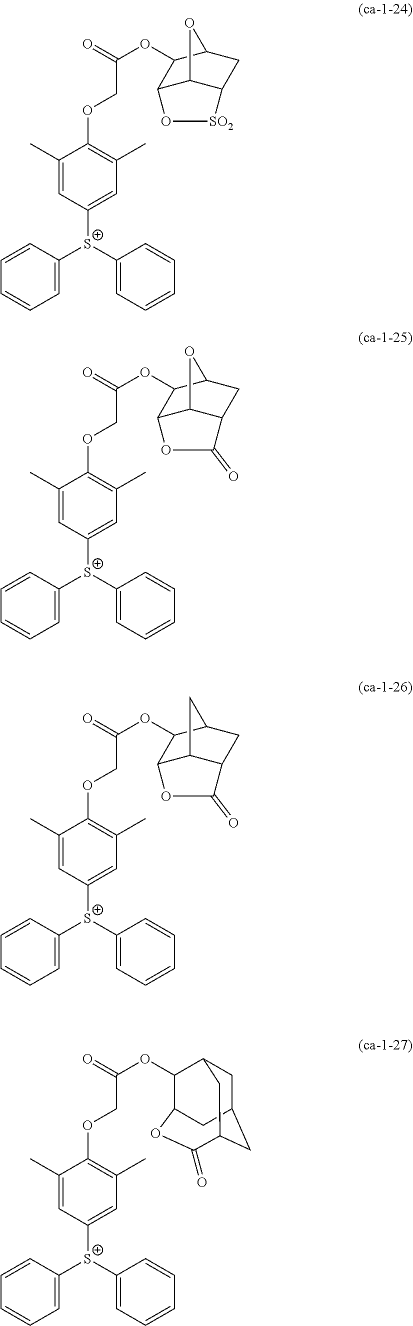

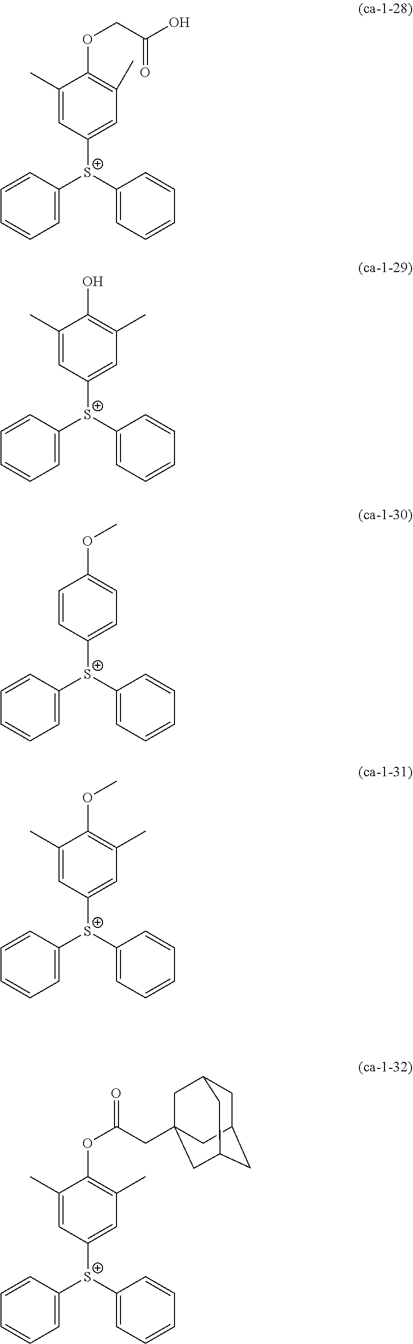

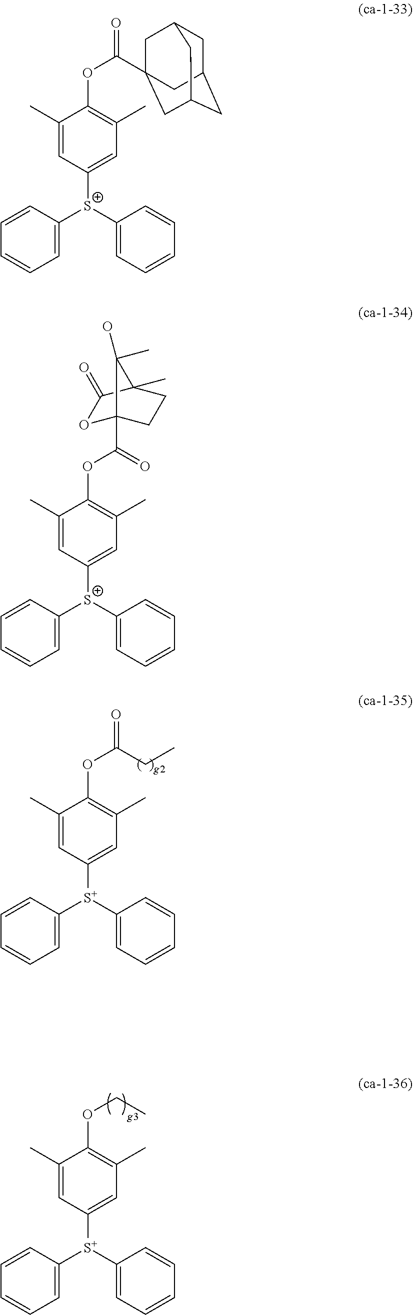

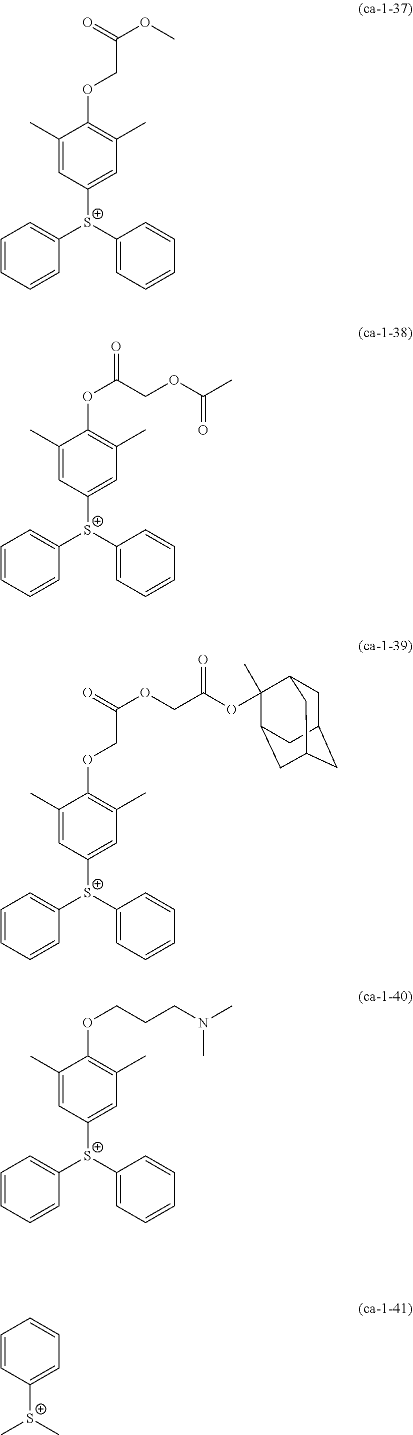

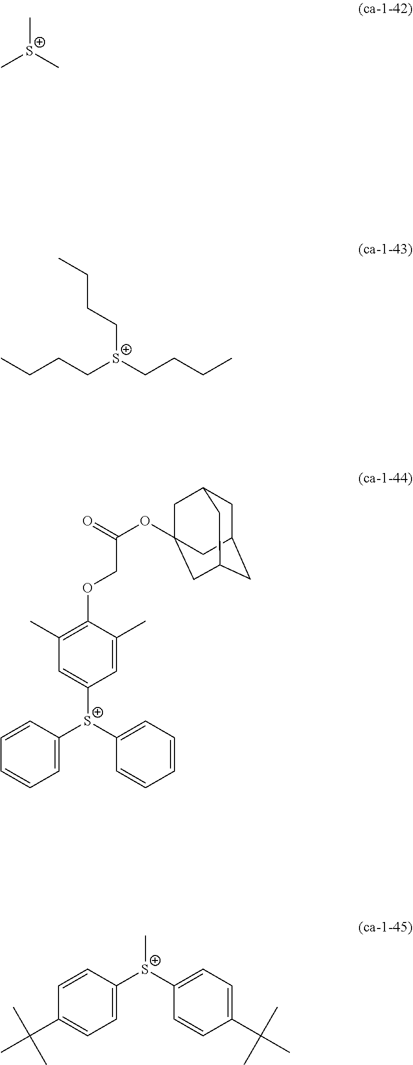

[In the formulae, g2 and g3 indicate the numbers of repetitions, g2 represents an integer in a range of 0 to 20, and g3 represents an integer in a range of 0 to 20.]

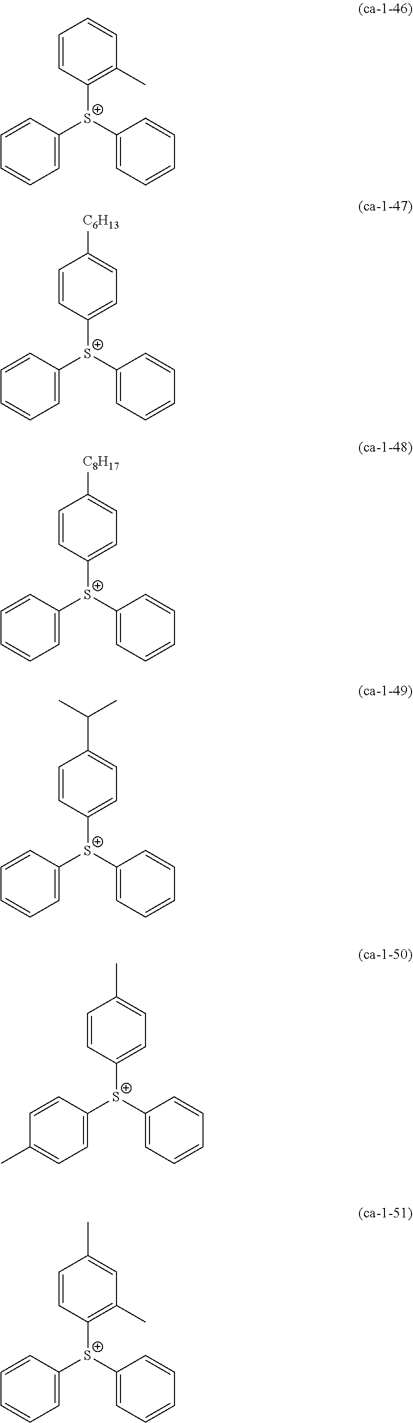

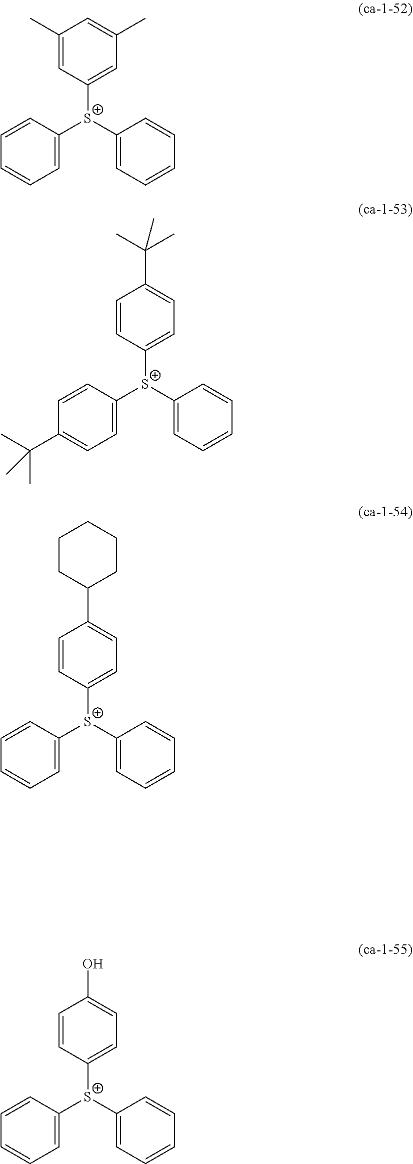 [SMILES: Cc1cc(C)cc([S+](c2ccccc2)c2ccccc2)c1 ; CC(C)(C)c1ccc([S+](c2ccccc2)c2ccc(C(C)(C)C)cc2)cc1 ; c1ccc([S+](c2ccccc2)c2ccc(C3CCCCC3)cc2)cc1 ; Oc1ccc([S+](c2ccccc2)c2ccccc2)cc1]

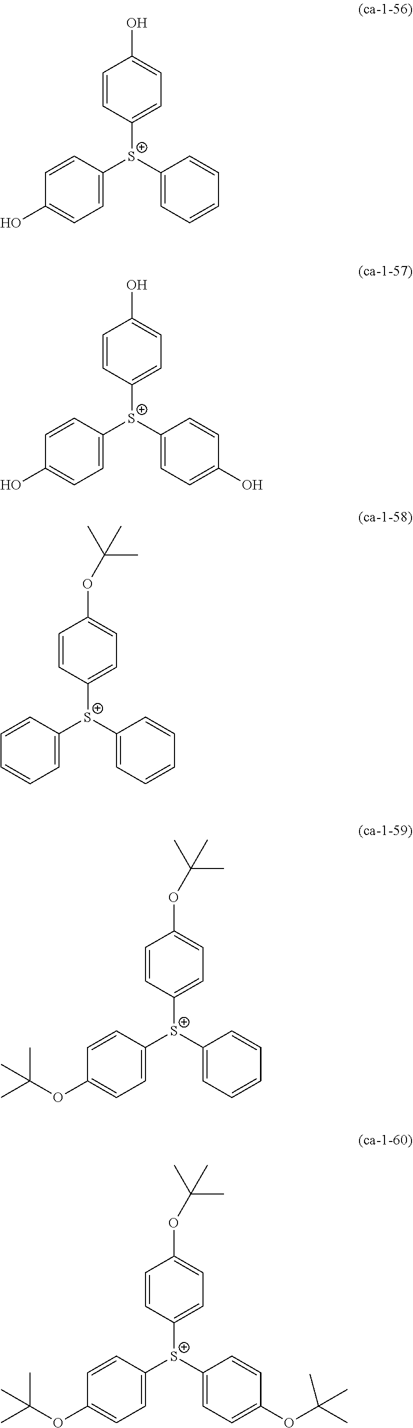 [SMILES: Oc1ccc([S+](c2ccccc2)c2ccc(O)cc2)cc1 ; Oc1ccc([S+](c2ccc(O)cc2)c2ccc(O)cc2)cc1 ; CC(C)(C)Oc1ccc([S+](c2ccccc2)c2ccccc2)cc1 ; CC(C)(C)Oc1ccc([S+](c2ccccc2)c2ccc(OC(C)(C)C)cc2)cc1 ; CC(C)(C)Oc1ccc([S+](c2ccc(OC(C)(C)C)cc2)c2ccc(OC(C)(C)C)cc2)cc1]

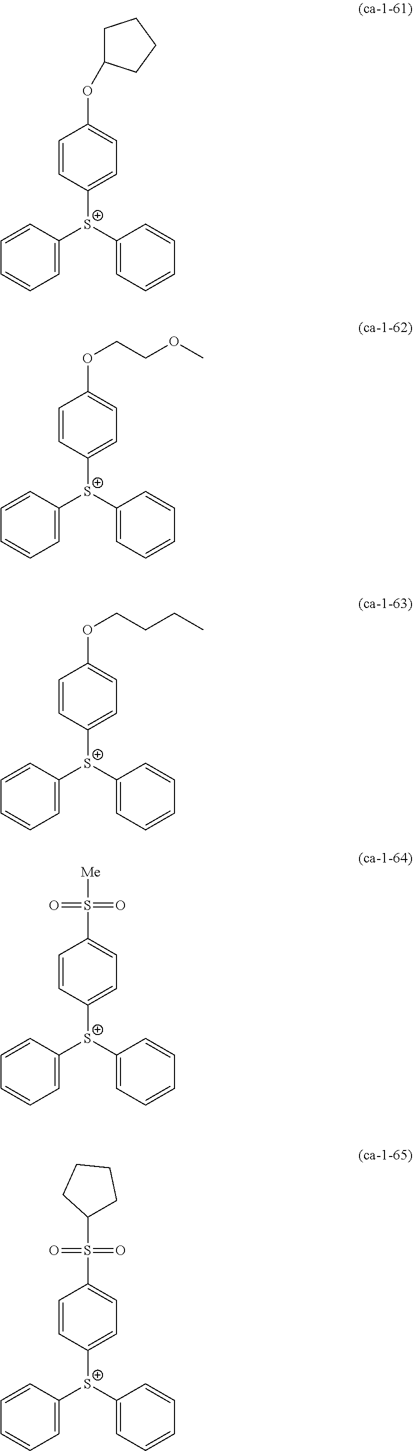 [SMILES: c1ccc([S+](c2ccccc2)c2ccc(OC3CCCC3)cc2)cc1 ; COCCOc1ccc([S+](c2ccccc2)c2ccccc2)cc1 ; CCCCOc1ccc([S+](c2ccccc2)c2ccccc2)cc1 ; CS(=O)(=O)c1ccc([S+](c2ccccc2)c2ccccc2)cc1 ; O=S(=O)(c1ccc([S+](c2ccccc2)c2ccccc2)cc1)C1CCCC1]

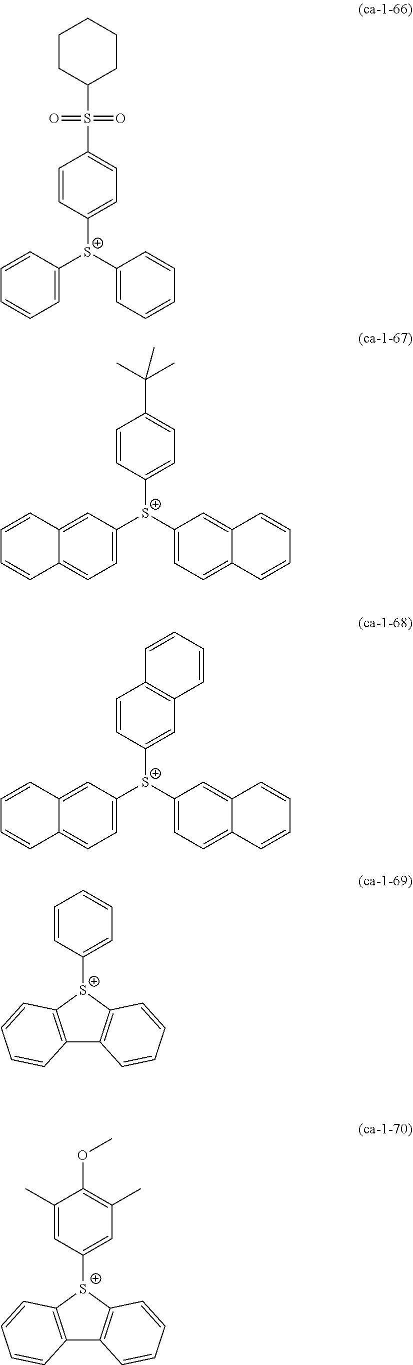 [SMILES: O=S(=O)(c1ccc([S+](c2ccccc2)c2ccccc2)cc1)C1CCCCC1 ; CC(C)(C)c1ccc([S+](c2ccc3ccccc3c2)c2ccc3ccccc3c2)cc1 ; c1ccc2cc([S+](c3ccc4ccccc4c3)c3ccc4ccccc4c3)ccc2c1 ; c1ccc(-[s+]2c3ccccc3c3ccccc32)cc1 ; COc1c(C)cc(-[s+]2c3ccccc3c3ccccc32)cc1C]

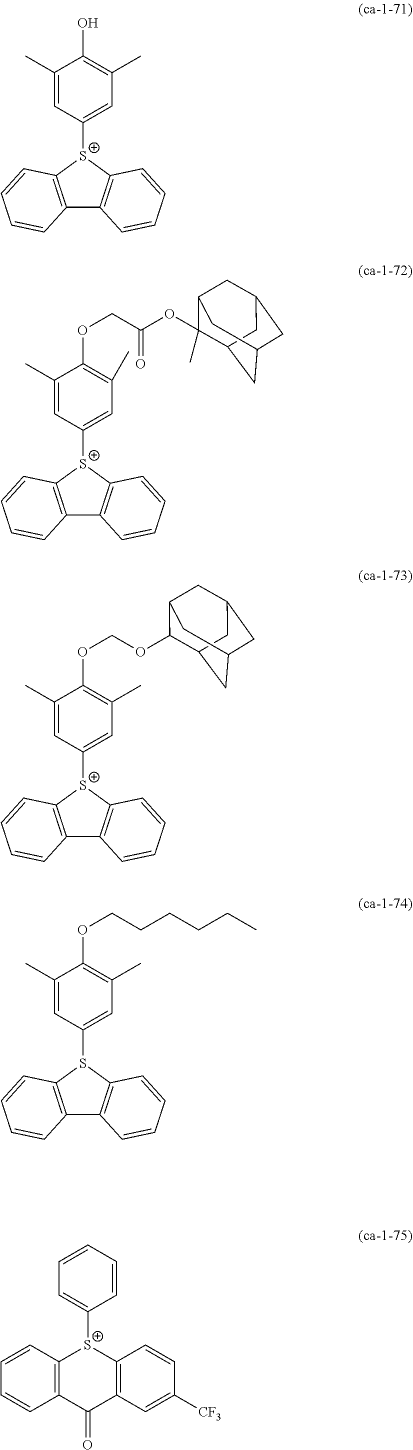

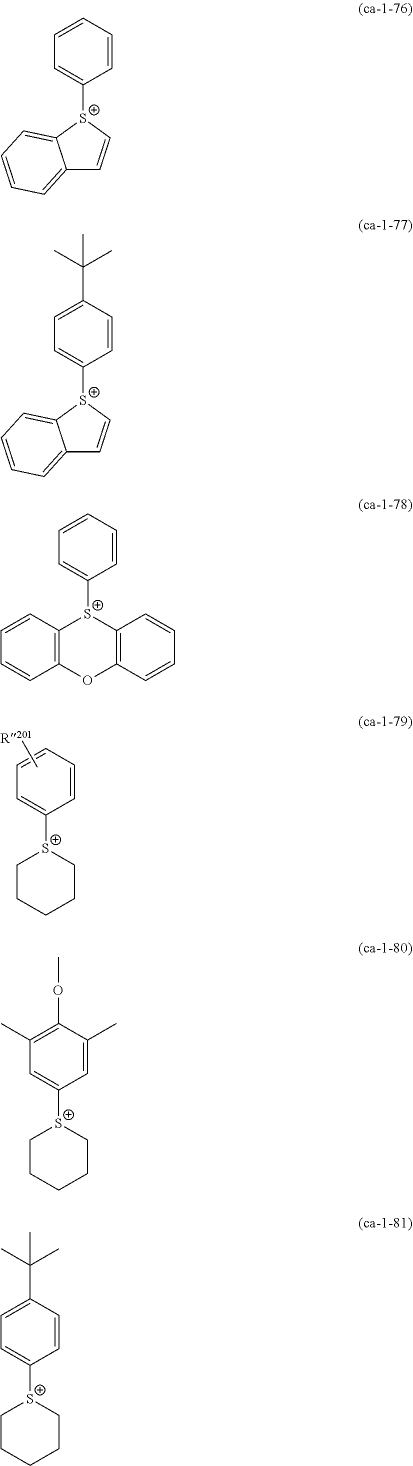

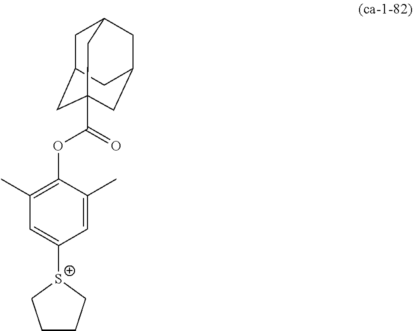 [SMILES: Cc1cc([S+]2CCCC2)cc(C)c1OC(=O)C12CC3CC(CC(C3)C1)C2]

[In the formula, R″²⁰¹ represents a hydrogen atom or a substituent, and the substituent is the same as the substituent exemplified as the substituent which may be contained in R²⁰¹ to R²⁰⁷ and R²¹⁰ to R²¹².]

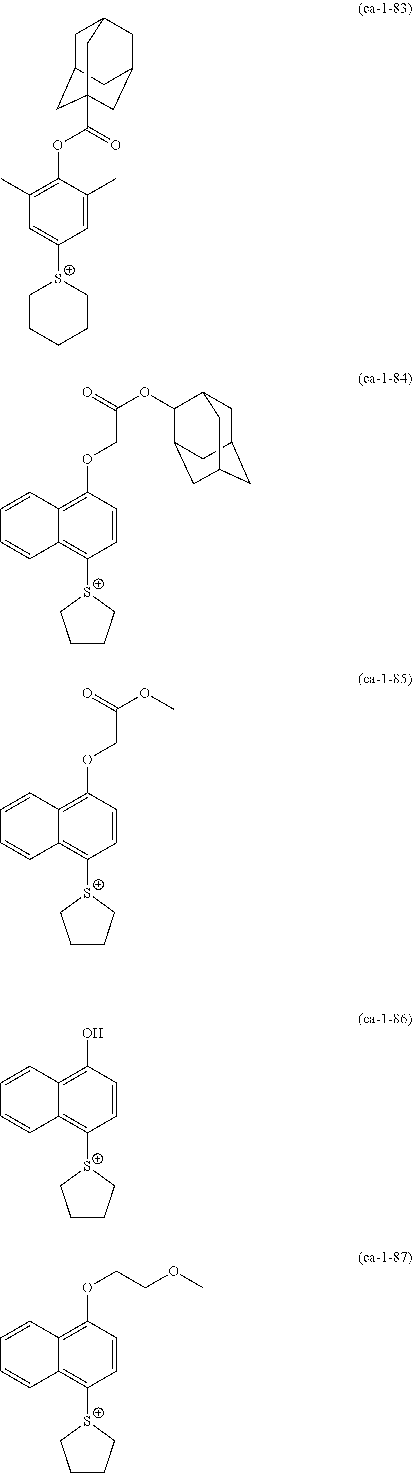 [SMILES: Cc1cc([S+]2CCCCC2)cc(C)c1OC(=O)C12CC3CC(CC(C3)C1)C2 ; O=C(COc1ccc([S+]2CCCC2)c2ccccc12)OC1C2CC3CC(C2)CC1C3 ; COC(=O)COc1ccc([S+]2CCCC2)c2ccccc12 ; Oc1ccc([S+]2CCCC2)c2ccccc12 ; COCCOc1ccc([S+]2CCCC2)c2ccccc12]

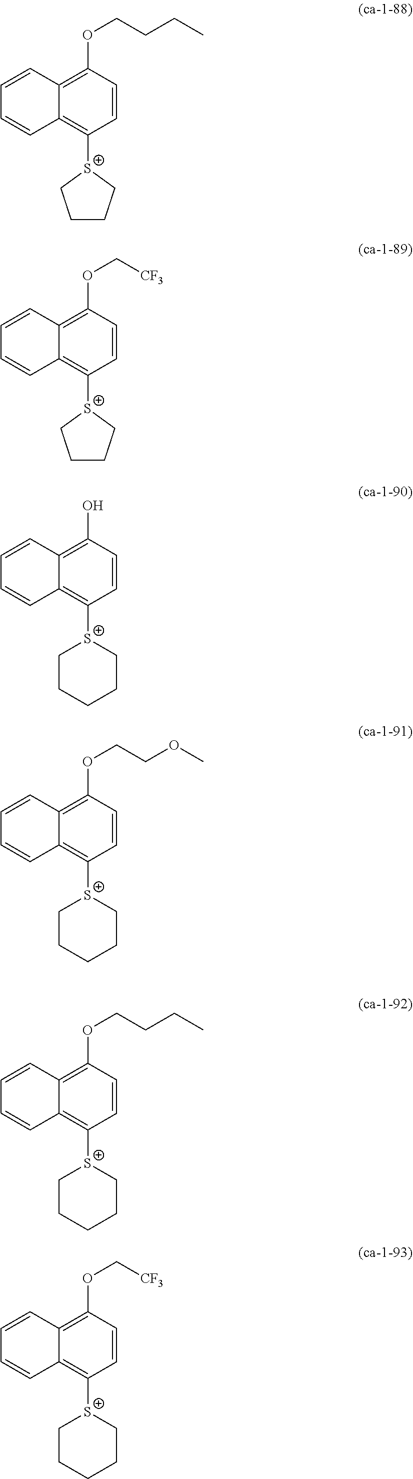 [SMILES: CCCCOc1ccc([S+]2CCCC2)c2ccccc12 ; FC(F)(F)COc1ccc([S+]2CCCC2)c2ccccc12 ; Oc1ccc([S+]2CCCCC2)c2ccccc12 ; COCCOc1ccc([S+]2CCCCC2)c2ccccc12 ; CCCCOc1ccc([S+]2CCCCC2)c2ccccc12 ; FC(F)(F)COc1ccc([S+]2CCCCC2)c2ccccc12]

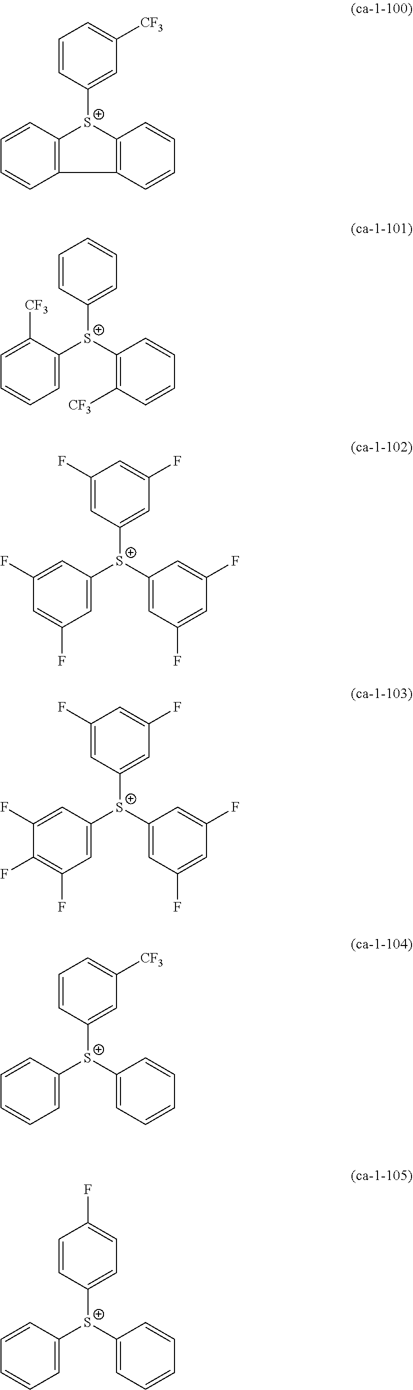 [SMILES: FC(F)(F)c1cccc(-[s+]2c3ccccc3c3ccccc32)c1 ; FC(F)(F)c1ccccc1[S+](c1ccccc1)c1ccccc1C(F)(F)F ; Fc1cc(F)cc([S+](c2cc(F)cc(F)c2)c2cc(F)cc(F)c2)c1 ; Fc1cc(F)cc([S+](c2cc(F)cc(F)c2)c2cc(F)c(F)c(F)c2)c1 ; FC(F)(F)c1cccc([S+](c2ccccc2)c2ccccc2)c1 ; Fc1ccc([S+](c2ccccc2)c2ccccc2)cc1]

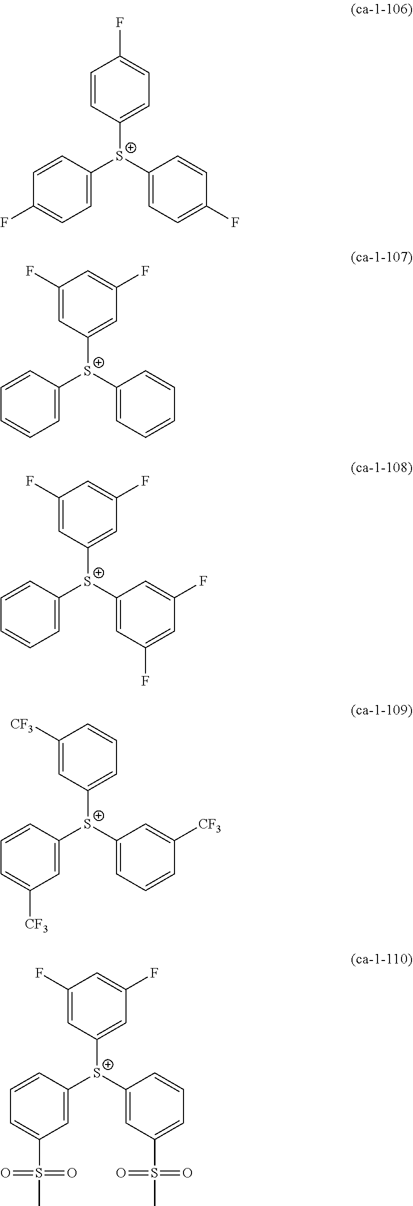 [SMILES: Fc1ccc([S+](c2ccc(F)cc2)c2ccc(F)cc2)cc1 ; Fc1cc(F)cc([S+](c2ccccc2)c2ccccc2)c1 ; Fc1cc(F)cc([S+](c2ccccc2)c2cc(F)cc(F)c2)c1 ; FC(F)(F)c1cccc([S+](c2cccc(C(F)(F)F)c2)c2cccc(C(F)(F)F)c2)c1 ; CS(=O)(=O)c1cccc([S+](c2cc(F)cc(F)c2)c2cccc(S(C)(=O)=O)c2)c1]

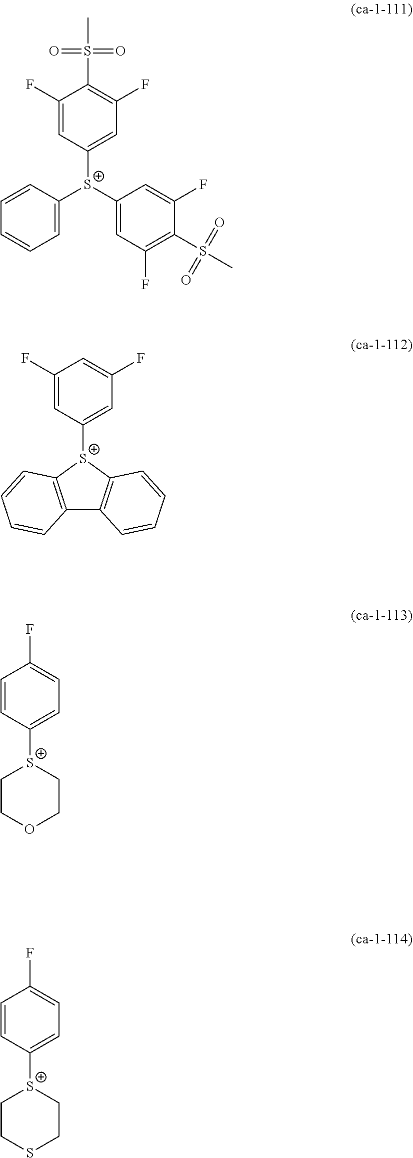 [SMILES: CS(=O)(=O)c1c(F)cc([S+](c2ccccc2)c2cc(F)c(S(C)(=O)=O)c(F)c2)cc1F ; Fc1cc(F)cc(-[s+]2c3ccccc3c3ccccc32)c1 ; Fc1ccc([S+]2CCOCC2)cc1 ; Fc1ccc([S+]2CCSCC2)cc1]

Specific examples of the suitable cation represented by General Formula (ca-2) include a diphenyliodonium cation and a bis(4-tert-butylphenyl)iodonium cation.

Specific examples of the suitable cation represented by General Formula (ca-3) include cations each represented by General Formulae (ca-3-1) to (ca-3-6).

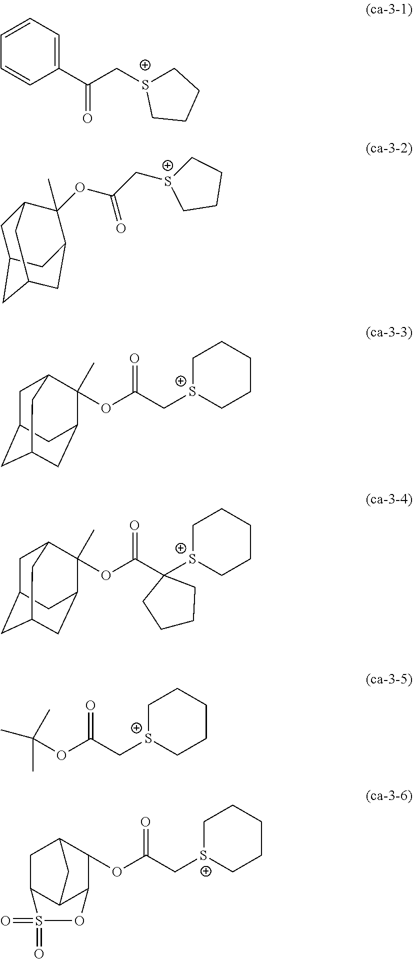

Specific examples of the suitable cation represented by General Formula (ca-4) include cations each represented by General Formulae (ca-4-1) and (ca-4-2).

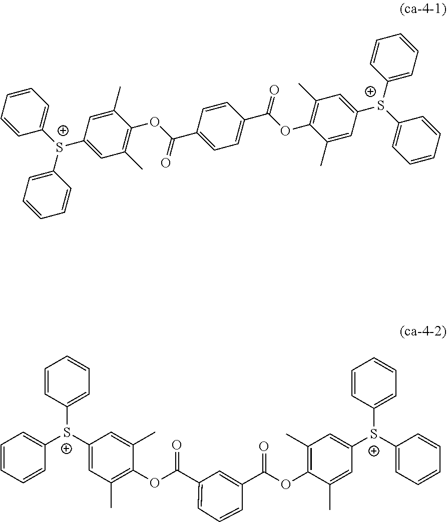

Specific examples of the suitable cation represented by General Formula (ca-5) include cations each represented by General Formulae (ca-5-1) to (ca-5-3).

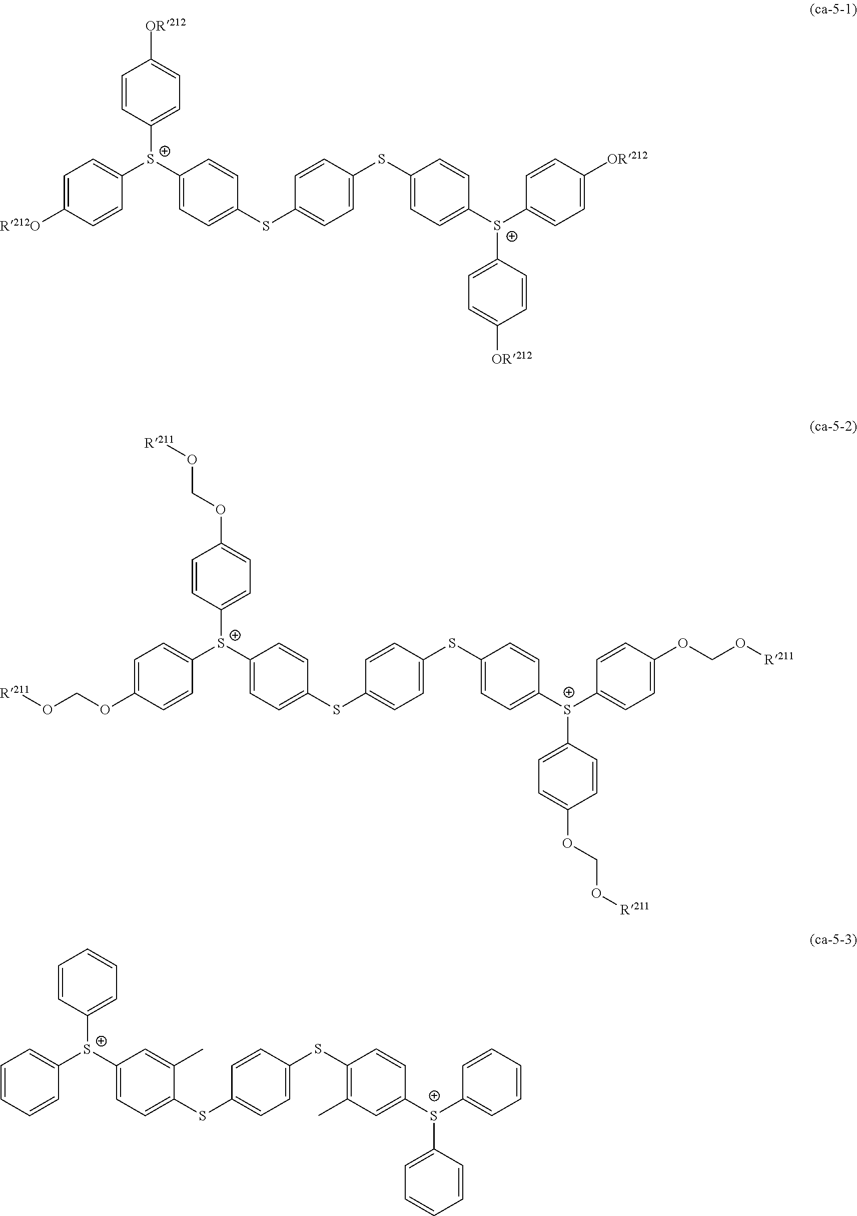

In General Formula (d1-1), M^{m+}) is, among the above, preferably a cation represented by General Formula (ca-1).

The component (d1-1) may be used alone or in a combination of two or more kinds thereof.

{Component (d1-2)}

Anion Moiety

In General Formula (d1-2), Rd² represents a cyclic group which may have a substituent, a chain alkyl group which may have a substituent, or a chain-like alkenyl group which may have a substituent, and examples thereof include the same one as R′²⁰¹.

However, the carbon atom adjacent to the S atom in Rd² has no fluorine atom bonded thereto (the carbon atom adjacent to the S atom in Rd² is not substituted with a fluorine atom). As a result, the anion of the component (d1-2) becomes an appropriately weak acid anion, thereby improving the quenching ability.

In General Formula (d1-2), Rd² is, among the above, preferably a chain alkyl group which may have a substituent or an aliphatic cyclic group which may have a substituent, and more preferably an aliphatic cyclic group which may have a substituent.

The chain alkyl group has preferably 1 to 10 carbon atoms and more preferably 3 to 10 carbon atoms.

The aliphatic cyclic group is preferably a group obtained by removing one or more hydrogen atoms from adamantane, norbornane, isobornane, tricyclodecane, or tetracyclododecane (which may have a substituent) and a group obtained by removing one or more hydrogen atoms from camphor.

The hydrocarbon group as Rd² may have a substituent. Examples of the substituent include the same one as the substituent which may be contained in the hydrocarbon group (the aromatic hydrocarbon group, the aliphatic cyclic group, or the chain alkyl group) as Rd¹ in General Formula (d1-1).

In General Formulae (y-a1-1) to (y-a1-7), in a case where linking groups each represented by General Formulae (y-a1-1) to (y-a1-7) are contained as the substituent, the one that is bonded to Rd² in General Formula (d1-1) is V′¹⁰ in General Formulae (y-a1-1) to (y-a1-7).

Among the above, the anion moiety of the component (d1-2) is preferably an anion represented by General Formula (an-d1-2).

Rd¹¹-Yd¹¹-Ld¹¹-SO₃^{⊖} (an-1-2)

[In the formula, Ld¹¹ represents an alkylene group which may have a substituent. Yd¹¹ represents a single bond or a divalent linking group containing an oxygen atom. Rd¹¹ represents an alicyclic hydrocarbon group which may have a substituent. However, Ld¹¹, Yd¹¹, and Rd¹¹ do not contain a halogen atom.]

In General Formula (an-d1-2), Ld¹¹ represents an alkylene group which may have a substituent. The alkylene group has preferably 1 to 10 carbon atoms, more preferably 1 to 5 carbon atoms, still more preferably 1 to 3 carbon atoms, and particularly preferably 1 or 2 carbon atoms. The alkylene group may be linear or branched. Specific examples of the alkylene group as Ld¹¹ include a methylene group [—CH₂—]; an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, or —C(CH₂CH₃)₂—; an ethylene group [—CH₂CH₂—]; an alkylethylene group such as —CH(CH₃)CH₂—, —CH(CH₃)CH(CH₃)—, —C(CH₃)₂CH₂—, or —CH(CH₂CH₃)CH₂—; a trimethylene group (n-propylene group) [—CH₂CH₂CH₂—]; an alkyltrimethylene group such as —CH(CH₃)CH₂CH₂— or —CH₂CH(CH₃)CH₂—; a tetramethylene group [—CH₂CH₂CH₂CH₂—]; an alkyltetramethylene group such as —CH(CH₃)CH₂CH₂CH₂—, or —CH₂CH(CH₃)CH₂CH₂—; and a pentamethylene group [—CH₂CH₂CH₂CH₂CH₂—].

The alkylene group as Ld¹¹ may have or may not have a substituent; however, it preferably does not have a substituent. Examples of the substituent which may be contained in the alkylene group as Ld¹¹ include an alkoxy group, a hydroxyl group, a carbonyl group, a nitro group, and an amino group.

The alkylene group as Ld¹¹ is preferably a linear alkylene group having 1 to 5 carbon atoms, more preferably a linear alkylene group having 1 to 3 carbon atoms, and still more preferably a methylene group or an ethylene group.

In General Formula (an-d1-2), Yd¹¹ represents a single bond or a divalent linking group containing an oxygen atom.

In a case where Yd¹¹ represents a divalent linking group containing an oxygen atom, Yd¹¹ may contain an atom other than the oxygen atom. Examples of the atom other than an oxygen atom include a carbon atom, a hydrogen atom, a sulfur atom, and a nitrogen atom.

Examples of the divalent linking group containing an oxygen atom include: non-hydrocarbon-based oxygen atom-containing linking groups such as an oxygen atom (an ether bond; —O—), an ester bond (—C(═O)—O—), an oxycarbonyl group (—O—C(═O)—), an amide bond (—C(═O)—NH—), a carbonyl group (—C(═O)—), and a carbonate bond (—O—C(═O)—O—); and a combination of the non-hydrocarbon-based oxygen atom-containing linking groups with an alkylene group. Furthermore, a sulfonyl group (—SO₂—) may be linked to the combination.

Suitable examples of the divalent linking group containing an oxygen atom, as Yd¹¹, more specifically include linking groups each represented by General Formulae (y-a1-1) to (y-a1-7). In a case where Yd¹¹ in General Formula (an-d1-2) represents linking groups each represented by General Formulae (y-a1-1) to (y-a1-7), the one that is bonded to Rd¹¹ in General Formula (an-d1-2) is V′¹⁰¹ in General Formulae (y-a1-1) to (y-a1-7).

Yd¹¹ is preferably a divalent linking group containing an ester bond, a divalent linking group containing an oxycarbonyl group, or a single bond, and more preferably a divalent linking group containing an ester bond or a divalent linking group containing an oxycarbonyl group.

Specifically, Yd¹¹ is preferably a linking group represented by General Formula (y-a1-1) or (y-a1-3).

In General Formula (an-d1-2), Rd¹¹ represents an alicyclic hydrocarbon group which may have a substituent.

Examples of the alicyclic hydrocarbon group as Rd¹¹ include the same ones as those mentioned as the alicyclic hydrocarbon group as Rd¹. Among them, the alicyclic hydrocarbon group as Rd¹¹ is preferably a polycyclic alicyclic hydrocarbon group, more preferably a group (a crosslinked ring-type alicyclic hydrocarbon group) obtained by removing one or more hydrogen atoms from a polycycloalkane having a crosslinked ring-based polycyclic skeleton or a lactone-containing cyclic group represented by General Formula (a2-r-7), and still more preferably a group obtained by removing one or more hydrogen atoms from adamantane or norbornane, or a lactone-containing cyclic group represented by General Formula (a2-r-7).

The substituent is preferably an alkyl group or a carbonyl group.

Specific examples of the anion moiety of the component (d1-2) are shown below.

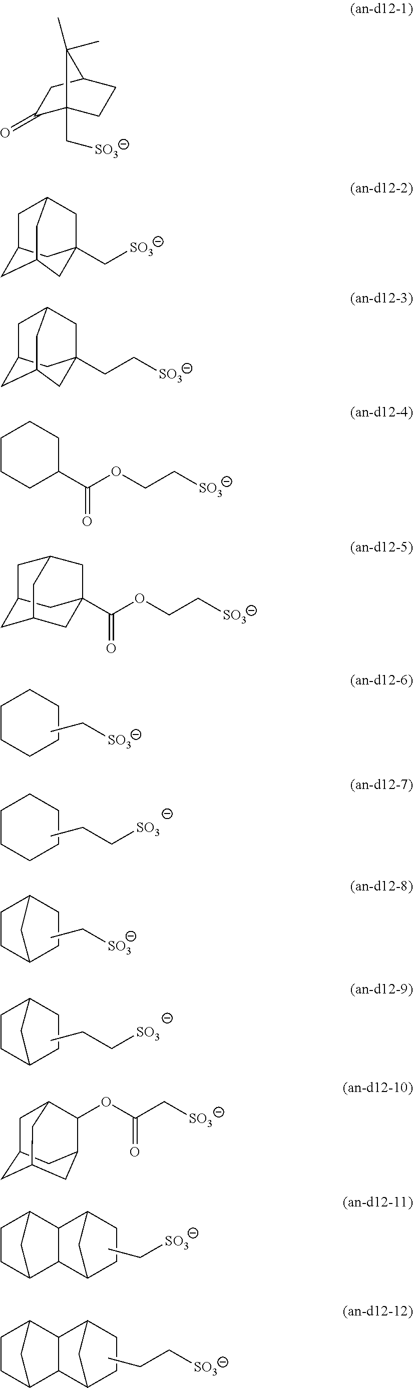

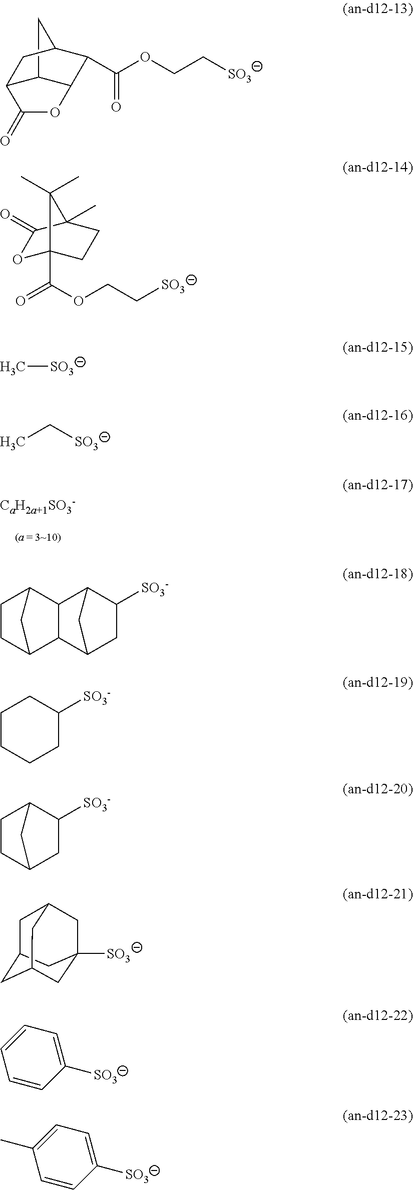

Among the above, the anion moiety of the component (d1-2) is preferably anions each represented by Chemical Formulae (an-d12-1) to (an-d12-14) and (an-d12-18) to (an-d12-21), and more preferably an anion represented by Chemical Formula (an-d12-10) or (an-d12-14) among the above.

Cation Moiety

In General Formula (d1-2), M^{m+} represents an m-valent organic cation and is the same as M^{m+} in General Formula (d1-1).

The component (d1-2) may be used alone or in a combination of two or more kinds thereof.

The component (d1-2) is preferably a compound (hereinafter, also referred to as a “component (d1-2-1)”) represented by General Formula (d1-2-1).

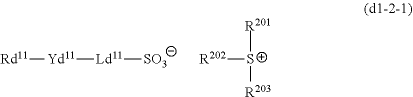

The anion moiety of the component (d1-2-1) is the same as the anion represented by General Formula (an-d1-2).

The cation moiety of the component (d1-2-1) is the same as the cation represented by General Formula (ca-1).

Among the above, the compound (D1) is preferably the compound represented by General Formula (d1-2), and more preferably the compound represented by General Formula (d1-2-1).

Suitable specific examples of the compound (D1) are shown below.

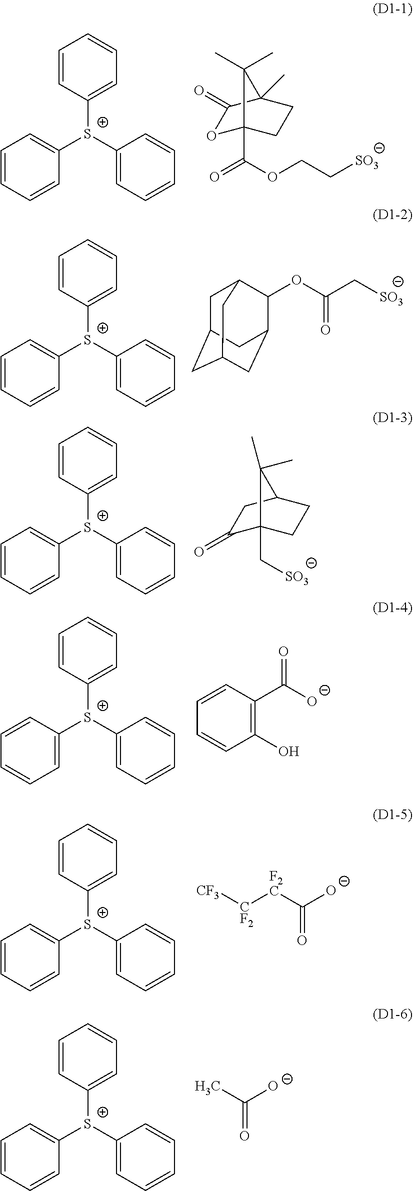

Among the above, the compound (D1) is preferably the compounds each represented by General Formulae (D1-1) to (D1-3), and more preferably the compound represented by General Formula (D1-1) or (D1-2).

The content of the compound (D1) in the resist composition according to the present embodiment is preferably in a range of 3 to 20 parts by mass and more preferably in a range of 5 to 15 parts by mass with respect to 100 parts by mass of the component (A1).

In a case where the content of the compound (D1) is equal to or larger than the above-described preferred lower limit, particularly excellent lithography characteristics and a particularly excellent resist pattern shape are easily obtained. On the other hand, in a case where it is equal to or smaller than the upper limit value described above, the sensitivity can be maintained satisfactorily.

Method of producing compound (D1):

The method of producing the components (d1-1) is not particularly limited, and the component (d1-1) can be produced by a conventionally known method. Further, the method of producing the component (d1-2) is not particularly limited, and the component (d1-2) can be produced in the same manner as disclosed in United States patent application, Publication No. 2012-0149916.

<Other Components>

The resist composition according to the present embodiment may further contain other components in addition to the component (A) and the compound (D1) described above. Examples of the other components include a component (B), a component (D) (provided that the compound (D1) is excluded), a component (E), a component (F), and a component (S), which are described below.

<<Acid Generator Component (B)>>

The resist composition according to the present embodiment may further contain an acid generator component (B) (hereinafter, referred to as “component (B)”) that generates acid upon exposure.

The component (B) is not particularly limited, and those which have been proposed as an acid generator for a chemically amplified resist composition in the related art can be used.

Examples of the acid generator are numerous and include onium salt-based acid generators such as iodonium salts and sulfonium salts; oxime sulfonate-based acid generators; diazomethane-based acid generators such as bisalkyl or bisaryl sulfonyl diazomethanes and poly(bis-sulfonyl)diazomethanes; nitrobenzylsulfonate-based acid generators; iminosulfonate-based acid generators; and disulfone-based acid generators.

Examples of the onium salt-based acid generator include a compound represented by General Formula (b-1) (hereinafter, also referred to as “component (b-1)”), a compound represented by General Formula (b-2) (hereinafter, also referred to as “component (b-2)”), and a compound represented by General Formula (b-3) (hereinafter, also referred to as “component (b-3)”).

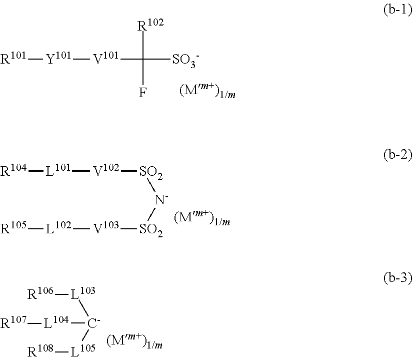

[In the formulae, R¹⁰¹ and R¹⁰⁴ to R¹⁰⁸ each independently represent a cyclic group which may have a substituent, a chain alkyl group which may have a substituent, or a chain-like alkenyl group which may have a substituent. R¹⁰⁴ and R¹⁰⁵ may be bonded to each other to form a ring structure. R¹⁰² represents a fluorinated alkyl group having 1 to 5 carbon atoms or a fluorine atom. Y¹⁰¹ represents a divalent linking group containing an oxygen atom or a single bond. V¹⁰¹ to V¹⁰³ each independently represent a single bond, an alkylene group, or a fluorinated alkylene group. L¹⁰¹ and L¹⁰² each independently represent a single bond or an oxygen atom. L¹⁰³ to L¹⁰⁵ each independently represent a single bond, —CO—, or —SO₂—. m represents an integer of 1 or more, and M′^{m+} represents an m-valent onium cation.]

{Anion Moiety}

Anion in Component (b-1)

[In General Formula (b-1), R¹⁰¹ represents a cyclic group which may have a substituent, a chain alkyl group which may have a substituent, or a chain-like alkenyl group which may have a substituent.

Cyclic group which may have substituent:

The cyclic group is preferably a cyclic hydrocarbon group, and the cyclic hydrocarbon group may be an aromatic hydrocarbon group or an aliphatic hydrocarbon group. The aliphatic hydrocarbon group indicates a hydrocarbon group that has no aromaticity. The aliphatic hydrocarbon group may be saturated or unsaturated.

In general, the aliphatic hydrocarbon group is preferably saturated.

The aromatic hydrocarbon group as R¹⁰¹ represents a hydrocarbon group having an aromatic ring. The aromatic hydrocarbon group has preferably 3 to 30 carbon atoms, more preferably 5 to 30, still more preferably 5 to 20, particularly preferably 6 to 15, and most preferably 6 to 10. However, the number of carbon atoms in a substituent is not included in the number of carbon atoms.

Specific examples of the aromatic ring contained in the aromatic hydrocarbon group as R¹⁰¹ include benzene, fluorene, naphthalene, anthracene, phenanthrene, biphenyl, and an aromatic heterocyclic ring obtained by substituting part of carbon atoms constituting one of these aromatic rings with a hetero atom. Examples of the hetero atom in the aromatic heterocyclic rings include an oxygen atom, a sulfur atom, and a nitrogen atom.

Specific examples of the aromatic hydrocarbon group as R¹⁰¹ include a group (an aryl group such as a phenyl group or a naphthyl group) obtained by removing one hydrogen atom from the above-described aromatic ring and a group (an arylalkyl group such as a benzyl group, a phenethyl group, a 1-naphthylmethyl group, a 2-naphthylmethyl group, 1-naphthylethyl group, or a 2-naphthylethyl group) obtained by substituting one hydrogen atom in the aromatic ring with an alkylene group. The alkylene group (an alkyl chain in the arylalkyl group) has preferably 1 to 4 carbon atoms, more preferably 1 or 2 carbon atoms, and particularly preferably 1 carbon atom.

Examples of the cyclic aliphatic hydrocarbon group as R¹⁰¹ include aliphatic hydrocarbon groups containing a ring in the structure thereof.

Examples of the aliphatic hydrocarbon group containing a ring in the structure thereof include an alicyclic hydrocarbon group (a group obtained by removing one hydrogen atom from an aliphatic hydrocarbon ring), a group obtained by bonding an alicyclic hydrocarbon group to the terminal of a linear or branched aliphatic hydrocarbon group, and a group by interposing an alicyclic hydrocarbon group in a linear or branched aliphatic hydrocarbon group.

The alicyclic hydrocarbon group has preferably 3 to 20 carbon atoms and more preferably 3 to 12 carbon atoms.

The alicyclic hydrocarbon group may be a polycyclic group or a monocyclic group. The monocyclic alicyclic hydrocarbon group is preferably a group obtained by removing one or more hydrogen atoms from a monocycloalkane. The monocycloalkane has preferably 3 to 6 carbon atoms, and specific examples thereof include cyclopentane and cyclohexane. The polycyclic alicyclic hydrocarbon group is preferably a group obtained by removing one or more hydrogen atoms from a polycycloalkane, and the number of carbon atoms of the polycycloalkane is preferably 7 to 30. Among them, the polycycloalkane is more preferably polycycloalkanes having a crosslinked ring-based polycyclic skeleton, such as adamantane, norbornane, isobornane, tricyclodecane, and tetracyclododecane, and polycycloalkanes having a condensed ring-based polycyclic skeleton, such as a cyclic group having a steroid skeleton.

Among them, the cyclic aliphatic hydrocarbon group as R¹⁰¹ is preferably a group obtained by removing one or more hydrogen atoms from a monocycloalkane or a polycycloalkane, more preferably a group obtained by removing one hydrogen atom from a polycycloalkane, particularly preferably an adamantyl group or a norbornyl group, and most preferably an adamantyl group.

The linear aliphatic hydrocarbon group which may be bonded to the alicyclic hydrocarbon group has preferably 1 to 10 carbon atoms, more preferably 1 to 6 carbon atoms, still more preferably 1 to 4 carbon atoms, and most preferably 1 to 3 carbon atoms. The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group which may be bonded to the alicyclic hydrocarbon group has preferably 2 to 10 carbon atoms, more preferably 3 to 6 carbon atoms, still more preferably 3 or 4 carbon atoms, and most preferably 3 carbon atoms. The branched aliphatic hydrocarbon group is preferably a branched alkylene group, and specific examples thereof include alkylalkylene group groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

The cyclic hydrocarbon group as R¹⁰¹ may contain a hetero atom such as a heterocyclic ring. Specific examples thereof include lactone-containing cyclic groups each represented by General Formulae (a2-r-1) to (a2-r-7), —SO₂-containing cyclic groups each represented by General Formulae (a5-r-1) to (a5-r-4), and other heterocyclic groups each represented by Chemical Formulae (r-hr-1) to (r-hr-16).

Examples of the substituent of the cyclic group as R¹⁰¹ include an alkyl group, an alkoxy group, a halogen atom, a halogenated alkyl group, a hydroxyl group, a carbonyl group, and a nitro group.

The alkyl group as the substituent is preferably an alkyl group having 1 to 5 carbon atoms, and a methyl group, an ethyl group, a propyl group, an n-butyl group, or a tert-butyl group is most preferable.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

Examples of the halogen atom as the substituent include a fluorine atom, a chlorine atom, a bromine atom, and an iodine atom, and a fluorine atom is preferable.

Examples of the above-described halogenated alkyl group as the substituent include a group obtained by substituting part or all hydrogen atoms of an alkyl group having 1 to 5 carbon atoms such as a methyl group, an ethyl group, a propyl group, an n-butyl group, or a tert-butyl group with the above halogen atoms.

The carbonyl group as the substituent is a group that substitutes a methylene group (—CH₂—) constituting the cyclic hydrocarbon group.

The cyclic hydrocarbon group as R¹⁰¹ may be a condensed cyclic group containing a condensed ring obtained by condensing an aliphatic hydrocarbon ring with an aromatic ring. Examples of the condensed ring include a condensed ring obtained by condensing one or more aromatic rings with a polycycloalkane having a crosslinked ring-based polycyclic skeleton. Specific examples of the crosslinked ring-based polycycloalkane include bicycloalkanes such as bicyclo[2.2.1]heptane (norbornane) and bicyclo[2.2.2]octane. The condensed cyclic group is preferably a group containing a condensed ring obtained by condensing two or three aromatic rings with a bicycloalkane, and more preferably a group containing a condensed ring obtained by condensing two or three aromatic rings with bicyclo[2.2.2]octane. Specific examples of the condensed cyclic group as R¹⁰¹ include those represented by General Formulae (r-br-1) to (r-br-2). In the formulae, * represents a bonding site to which Y¹⁰¹ in General Formula (b-1) is bonded.

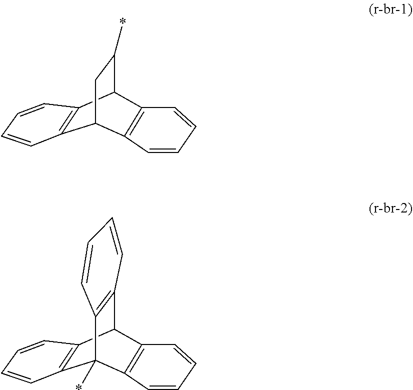

Examples of the substituent which may be contained in the condensed cyclic group as R¹⁰¹ include an alkyl group, an alkoxy group, a halogen atom, a halogenated alkyl group, a hydroxyl group, a carbonyl group, a nitro group, an aromatic hydrocarbon group, and an alicyclic hydrocarbon group.

Examples of the alkyl group, the alkoxy group, the halogen atom, and the halogenated alkyl group, as the substituent of the condensed cyclic group, include the same ones as those described as the substituent of the cyclic group as R¹⁰¹.

Examples of the aromatic hydrocarbon group as the substituent for the condensed cyclic group include a group obtained by removing one hydrogen atom from an aromatic ring (an aryl group, for example, a phenyl group and a naphthyl group), a group obtained by substituting one hydrogen atom in the above aromatic ring with an alkylene group (for example, arylalkyl groups such as a benzyl group, a phenethyl group, a 1-naphthylmethyl group, a 2-naphthylmethyl group, 1-naphthylethyl group, and a 2-naphthylethyl group), and heterocyclic groups each represented by General Formulae (r-hr-1) to (r-hr-6).

Examples of the alicyclic hydrocarbon group as the substituent of the condensed cyclic group include a group obtained by removing one hydrogen atom from a monocycloalkane such as cyclopentane or cyclohexane; a group obtained by removing one hydrogen atom from a polycycloalkane such as adamantane, norbornane, isobornane, tricyclodecane, or tetracyclododecane; lactone-containing cyclic groups each represented by General Formulae (a2-r-1) to (a2-r-7); —SO₂-containing cyclic groups each represented by General Formulae (a5-r-1) to (a5-r-4); and heterocyclic groups each represented by General Formulae (r-hr-7) to (r-hr-16).

Chain alkyl group which may have substituent:

The chain alkyl group as R¹⁰¹ may be linear or branched.

The linear alkyl group has preferably 1 to 20 carbon atoms, more preferably 1 to 15 carbon atoms, and most preferably 1 to 10 carbon atoms.

The branched alkyl group has preferably 3 to 20 carbon atoms, more preferably 3 to 15, and most preferably 3 to 10. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-like alkenyl group which may have substituent:

A chain-like alkenyl group as R¹⁰¹ may be linear or branched, and the chain-like alkenyl group preferably has 2 to 10 carbon atoms, more preferably 2 to 5 carbon atoms, still more preferably 2 to 4 carbon atoms, and particularly preferably 3 carbon atoms. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Among the above, the chain-like alkenyl group is preferably a linear alkenyl group, more preferably a vinyl group or a propenyl group, and particularly preferably a vinyl group.

Examples of the substituent in the chain alkyl group or alkenyl group as R¹⁰¹ include an alkoxy group, a halogen atom, a halogenated alkyl group, a hydroxyl group, a carbonyl group, a nitro group, an amino group, and a cyclic group as R¹⁰¹.

Among the above, R¹⁰¹ is preferably a cyclic group which may have a substituent and more preferably a cyclic hydrocarbon group which may have a substituent. More specific examples thereof preferably include a phenyl group; a naphthyl group; a group obtained by removing one or more hydrogen atoms from a polycycloalkane; a lactone-containing cyclic group represented by any one of General Formulae (a2-r-1) to (a2-r-7); and —SO₂-containing cyclic groups each represented by General Formulae (a5-r-1) to (a5-r-4).

In General Formula (b-1), Y⁰¹⁰ represents a single bond or a divalent linking group containing an oxygen atom.

In a case where Y⁰¹⁰ represents a divalent linking group containing an oxygen atom, Y¹⁰¹ may contain an atom other than the oxygen atom. Examples of the atom other than an oxygen atom include a carbon atom, a hydrogen atom, a sulfur atom, and a nitrogen atom.

Examples of the divalent linking group containing an oxygen atom include: non-hydrocarbon-based oxygen atom-containing linking groups such as an oxygen atom (an ether bond; —O—), an ester bond (—C(═O)—O—), an oxycarbonyl group (—O—C(═O)—), an amide bond (—C(═O)—NH—), a carbonyl group (—C(═O)—), and a carbonate bond (—O—C(═O)—O—); and a combination of the non-hydrocarbon-based oxygen atom-containing linking groups with an alkylene group. Furthermore, a sulfonyl group (—SO₂—) may be linked to the combination. Examples of the divalent linking group containing an oxygen atom include the linking groups each represented by General Formulae (y-a1-1) to (y-a1-7) described above. In General Formulae (y-a1-1) to (y-a1-7), the one that is bonded to R¹⁰¹ in General Formula (b-1) is V′¹⁰¹ in General Formulae (y-a1-1) to (y-a1-7).

Y¹⁰¹ is preferably a divalent linking group containing an ester bond or a divalent linking group containing an ether bond, and more preferably any one of linking groups each represented by General Formulae (y-a1-1) to (y-a1-5).

In General Formula (b-1), V¹⁰¹ represents a single bond, an alkylene group, or a fluorinated alkylene group. The alkylene group and the fluorinated alkylene group as V¹⁰¹ preferably have 1 to 4 carbon atoms. Examples of the fluorinated alkylene group as V¹⁰¹ include a group obtained by substituting part or all hydrogen atoms in the alkylene group as V¹⁰¹ with a fluorine atom. Among them, V¹⁰¹ is preferably a single bond or a fluorinated alkylene group having 1 to 4 carbon atoms.

In General Formula (b-1), R¹⁰² represents a fluorine atom or a fluorinated alkyl group having 1 to 5 carbon atoms. R¹⁰² is preferably a fluorine atom or a perfluoroalkyl group having 1 to 5 carbon atoms and more preferably a fluorine atom.

In a case where Y¹⁰¹ represents a single bond, specific examples of the anion moiety represented by General Formula (b-1) include a fluorinated alkylsulfonate anion such as a trifluoromethanesulfonate anion or a perfluorobutanesulfonate anion; and in a case where Y¹⁰¹ represents a divalent linking group containing an oxygen atom, specific examples thereof include an anion represented by any one of General Formulae (an-1) to (an-3) shown below.

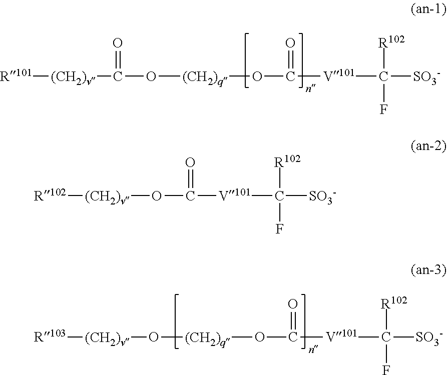

[In the formula, R″¹⁰¹ represents an aliphatic cyclic group which may have a substituent, monovalent heterocyclic groups each represented by Chemical Formulae (r-hr-1) to (r-hr-6), a condensed cyclic group represented by General Formula (r-br-1) or (r-br-2), and a chain alkyl group which may have a substituent. R″¹⁰² is an aliphatic cyclic group which may have a substituent, a condensed cyclic group represented by General Formula (r-br-1) or (r-br-2), lactone-containing cyclic groups each represented by General Formulae (a2-r-1), (a2-r-3) to (a2-r-7), or —SO₂-containing cyclic groups each represented by General Formulae (a5-r-1) to (a5-r-4). R″¹⁰³ represents an aromatic cyclic group which may have a substituent, an aliphatic cyclic group which may have a substituent, or a chain-like alkenyl group which may have a substituent. V″¹⁰¹ represents a single bond, an alkylene group having 1 to 4 carbon atoms, or a fluorinated alkylene group having 1 to 4 carbon atoms. R¹⁰² represents a fluorine atom or a fluorinated alkyl group having 1 to 5 carbon atoms. Each v″ independently represents an integer in a range of 0 to 3, each q″ independently represents an integer in a range of 0 to 20, and n″ represents 0 or 1.]

The aliphatic cyclic group as R″¹⁰¹, R″¹⁰², and R″¹⁰³ which may have a substituent is preferably the group exemplified as the cyclic aliphatic hydrocarbon group as R¹⁰¹ in General Formula (b-1). Examples of the substituent include the same one as the substituent that may be substituted for the cyclic aliphatic hydrocarbon group as R¹⁰¹ in General Formula (b-1).

The aromatic cyclic group which may have a substituent, as R″¹⁰³, is preferably the group exemplified as the aromatic hydrocarbon group for the cyclic hydrocarbon group as R¹⁰¹ in General Formula (b-1). Examples of the substituent include the same one as the substituent that may be substituted for the aromatic hydrocarbon group as R¹⁰¹ in General Formula (b-1).

The chain alkyl group as R″¹⁰¹, which may have a substituent, is preferably the group exemplified as the chain alkyl group as R¹⁰¹ in General Formula (b-1).

The chain-like alkenyl group as R″¹⁰³, which may have a substituent, is preferably the group exemplified as the chain-like alkenyl group as R¹⁰¹ in General Formula (b-1).

Anion in Component (b-2)

in General Formula (b-2), R¹⁰⁴ and R¹⁰⁵ each independently represent a cyclic group which may have a substituent, a chain alkyl group which may have a substituent, or a chain-like alkenyl group which may have a substituent, and examples thereof each include the same one as R¹⁰¹ in General Formula (b-1). However, R¹⁰⁴ and R¹⁰⁵ may be bonded to each other to form a ring.

R¹⁰⁴ and R¹⁰⁵ are preferably a chain alkyl group which may have a substituent and more preferably a linear or branched alkyl group or a linear or branched fluorinated alkyl group.

The chain alkyl group has preferably 1 to 10 carbon atoms, more preferably 1 to 7 carbon atoms, and still more preferably 1 to 3 carbon atoms. It is preferable that the number of carbon atoms in the chain alkyl group as R¹⁰⁴ and R¹⁰⁵ is small since the solubility in a resist solvent is also excellent in this range of the number of carbon atoms. Further, in the chain alkyl group as R¹⁰⁴ and R¹⁰⁵, it is preferable that the number of hydrogen atoms substituted with a fluorine atom is large since the acid strength increases and the transparency to high energy radiation of 250 nm or less or an electron beam is improved. The proportion of fluorine atoms in the chain alkyl group, that is, the fluorination rate is preferably 70% to 100% and more preferably 90% to 100%, and it is most preferable that the chain alkyl group is a perfluoroalkyl group obtained by substituting all hydrogen atoms with fluorine atoms.

In General Formula (b-2), V¹⁰² and V¹⁰³ each independently represent a single bond, an alkylene group, or a fluorinated alkylene group, and examples thereof include the same one as V¹⁰¹ in General Formula (b-1).

In General Formula (b-2), L¹⁰¹ and L¹⁰² each independently represent a single bond or an oxygen atom.

Anion in Component (b-3)

in General Formula (b-3), R¹⁰⁶ to R¹⁰⁸ each independently represent a cyclic group which may have a substituent, chain alkyl group which may have a substituent, or a chain-like alkenyl group which may have a substituent, and examples thereof include the same one as R¹⁰¹ in General Formula (b-1).

In General Formula (b-3), L¹⁰³ to L¹⁰⁵ each independently represent a single bond, —CO—, or —SO₂—.

Among the above, the anion moiety of the component (B) is preferably an anion of the component (b-1). Among these, an anion represented by any one of General Formulae (an-1) to (an-3) is more preferable, an anion represented by any one of General Formula (an-1) or (an-2) is still more preferable, and an anion represented by General Formula (an-2) is particularly preferable.

{Cation Moiety}

In General Formulae (b-1), (b-2), and (b-3) described above, M″^{m+} represents an m-valent onium cation. Among these, a sulfonium cation and an iodonium cation are preferable. m represents an integer of 1 or more.

Examples of the preferred cation moiety ((M′^{m+})_{1/m}) include the organic cations each represented by General Formulae (ca-1) to (ca-5) described above, and the cation represented by General Formula (ca-1) described above is preferable.

In the resist composition according to the present embodiment, the component (B) may be used alone or in a combination of two or more kinds thereof.

In a case where the resist composition contains the component (B), the content of the component (B) in the resist composition is preferably less than 50 parts by mass, more preferably 5 to 40 parts by mass, and still more preferably 8 to 20 parts by mass with respect to 100 parts by mass of the component (A1).

In a case where the content of the component (B) is set to be in the preferred range described above, pattern formation can be sufficiently carried out. Further, in a case where each component of the resist composition is dissolved in an organic solvent, the above range is preferable since a homogeneous solution is easily obtained and the storage stability of the resist composition is improved.

<Base Component (D)>>

The resist composition according to the present embodiment may further contain a base component (a component (D)) other than the compound (D1), which traps (that is, controls the acid diffusion) the acid generated from the component (B) upon exposure. The component (D) acts as a quencher (an acid diffusion controlling agent) which traps the acid generated in the resist composition upon exposure.

Examples of the component (D) include a photodecomposable base (D3) (hereinafter, referred to as the “component (D3)”) that decomposes upon exposure and loses the acid diffusion controllability and a nitrogen-containing organic compound (D3) (hereinafter, referred to as the “component (D2)”) which does not correspond to the component (D2).

In Regard to Component (D3)

In a case where a resist composition containing the component (D3) is obtained, the contrast between exposed portions and unexposed portions of the resist film can be further improved at the time of the formation of a resist pattern.

The component (D3) is not particularly limited as long as it decomposes upon exposure and loses acid diffusion controllability, and it is preferably a compound (hereinafter, a “component (d1-3)”) represented by General Formula (d1-3).

At exposed portions of the resist film, the component (d1-3) decomposes and then loses the acid diffusion controllability (basicity), and thus it does not act as a quencher, whereas it acts as a quencher at unexposed portions of the resist film.

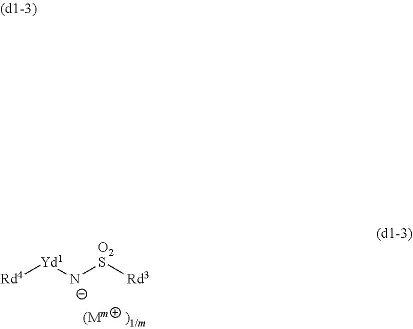

[In the formulae, Rd³ and Rd⁴ each independently represent a cyclic group which may have a substituent, a chain alkyl group which may have a substituent, or a chain-like alkenyl group which may have a substituent. Yd¹ represents a single bond or a divalent linking group. m represents an integer of 1 or more, and M^{m+} represents an m-valent organic cation.]

{Component (d1-3)}

Anion Moiety

In General Formula (d1-3), Rd³ represents a cyclic group which may have a substituent, a chain alkyl group which may have a substituent, or a chain-like alkenyl group which may have a substituent, examples thereof include the same one as R′²⁰¹, and a cyclic group containing a fluorine atom, a chain alkyl group, or a chain-like alkenyl group is preferable. Among the above, a fluorinated alkyl group is preferable, and the same one as the fluorinated alkyl group as Rd¹ described above is more preferable.

In General Formula (d1-3), Rd⁴ represents a cyclic group which may have a substituent, a chain alkyl group which may have a substituent, or a chain-like alkenyl group which may have a substituent, and examples thereof include the same one as R′²⁰¹. Among them, an alkyl group which may have a substituent, an alkoxy group which may have a substituent, an alkenyl group which may have a substituent, or a cyclic group which may have a substituent is preferable.

The alkyl group as Rd⁴ is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group. Part of hydrogen atoms in the alkyl group as Rd⁴ may be substituted with a hydroxyl group, a cyano group, or the like.

The alkoxy group as Rd⁴ is preferably an alkoxy group having 1 to 5 carbon atoms, and specific examples of the alkoxy group having 1 to 5 carbon atoms include a methoxy group, an ethoxy group, an n-propoxy group, an iso-propoxy group, an n-butoxy group, and a tert-butoxy group. Among them, a methoxy group and an ethoxy group are preferable.

Examples of the alkenyl group as Rd⁴ include the same one as the alkenyl group as R′²⁰¹, and a vinyl group, a propenyl group (an allyl group), a 1-methylpropenyl group, or a 2-methylpropenyl group is preferable. These groups may further have an alkyl group having 1 to 5 carbon atoms or a halogenated alkyl group having 1 to 5 carbon atoms, as a substituent.

Examples of the cyclic group as Rd⁴ include the same one as the cyclic group described above as R′²⁰¹, and the cyclic group is preferably an alicyclic group obtained by removing one or more hydrogen atoms from a cycloalkane such as cyclopentane, cyclohexane, adamantane, norbornane, isobornane, tricyclodecane, or tetracyclododecane, or an aromatic group such as a phenyl group or a naphthyl group. In a case where Rd⁴ represents an alicyclic group, the resist composition can be satisfactorily dissolved in an organic solvent, thereby improving lithography characteristics. In a case where Rd⁴ is an aromatic group, the resist composition is excellent in light absorption efficiency and thus has good sensitivity and lithography characteristics in the lithography using EUV or the like as a light source for exposure.

In General Formula (d1-3), Yd¹ represents a single bond or a divalent linking group.

The divalent linking group as Yd¹ is not particularly limited, and examples thereof include a divalent hydrocarbon group (an aliphatic hydrocarbon group or an aromatic hydrocarbon group) which may have a substituent and a divalent linking group containing a hetero atom. Examples of these divalent linking groups each include the same one as the divalent hydrocarbon group which may have a substituent and the divalent linking group containing a hetero atom, which are mentioned in the explanation of the divalent linking group as Ya²¹ in General Formula (a2-1).

Yd¹ is preferably a carbonyl group, an ester bond, an amide bond, an alkylene group, or a combination of these. The alkylene group is more preferably a linear or branched alkylene group and still more preferably a methylene group or an ethylene group.

Specific examples of the preferred anion moiety for the component (d1-3) are as follows.

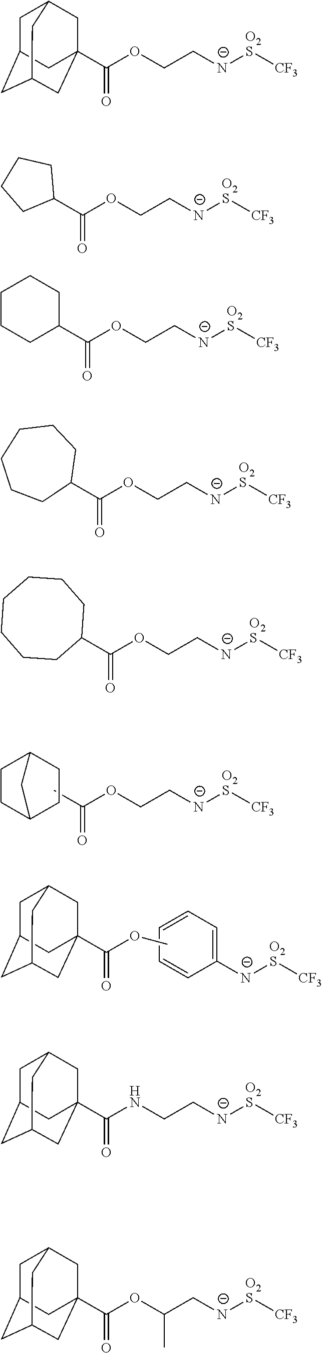

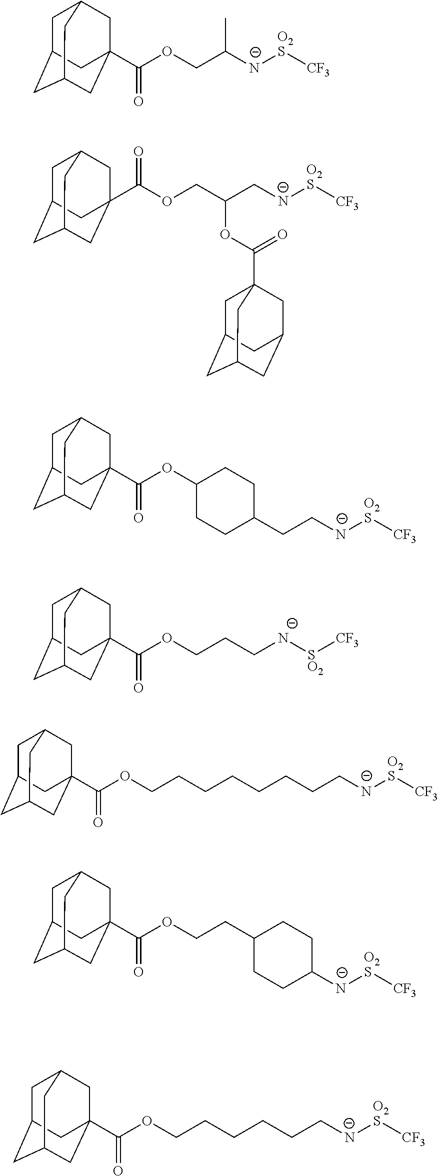

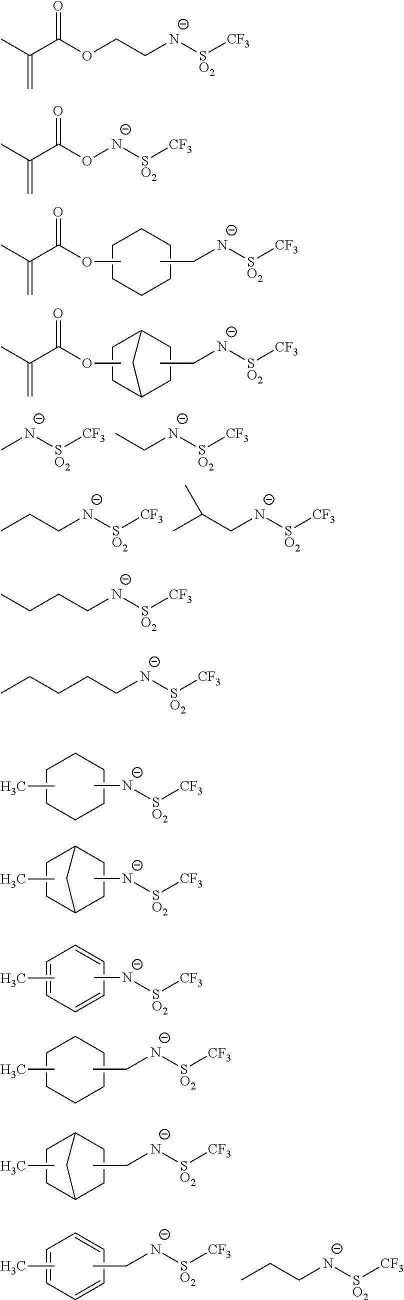

Cation Moiety

In General Formula (d1-3), M^{m+} represents an m-valent organic cation, and specific examples thereof include the organic cations each represented by General Formulae (ca-1) to (ca-5) described above.

The component (d1-3) may be used alone or in a combination of two or more kinds thereof.

One kind of the component (D3) may be used alone, or two or more kinds thereof may be used in combination.

In a case where the resist composition contains the component (D3), the content of the component (D3) is preferably in a range of 0.5 to 20 parts by mass and more preferably in a range of 1 to 15 parts by mass with respect to 100 parts by mass of the component (A1).

Method of Producing Component (D3):

Further, the method of producing the component (d1-3) is not particularly limited, and the component (d1-3) can be produced in the same manner as disclosed in United States patent application, Publication No. 2012-0149916.

In Regard to Component (D2)

The component (D) may contain a nitrogen-containing organic compound component (hereinafter, referred to as the “component (D2)”) which does not correspond to the above-mentioned component (D3).

The component (D2) is not particularly limited as long as it acts as an acid diffusion controlling agent and does not correspond to the component (D3), and any conventionally known component may be used. Among them, an aliphatic amine is preferable, and among the aliphatic amines, a secondary aliphatic amine or a tertiary aliphatic amine is more preferable.

The aliphatic amine is an amine having one or more aliphatic groups, and the aliphatic groups preferably have 1 to 12 carbon atoms.

Examples of the aliphatic amine include an amine obtained by substituting at least one hydrogen atom of ammonia (NH₃) with an alkyl group or hydroxyalkyl group having 12 or fewer carbon atoms (an alkylamine or an alkyl alcohol amine) and a cyclic amine.

Specific examples of the alkylamine and the alkylalcoholamine include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decylamine, and tri-n-dodecylamine; and alkylalcoholamines such as diethanolamine, triethanolamine, diisopropanolamine, triisopropanolamine, di-n-octanolamine, and tri-n-octanolamine. Among these, a trialkylamine having 5 to 10 carbon atoms is still more preferable, and tri-n-pentylamine or tri-n-octylamine is particularly preferable.

Examples of the cyclic amine include heterocyclic compounds containing a nitrogen atom as a hetero atom. The heterocyclic compound may be a monocyclic compound (aliphatic monocyclic amine) or a polycyclic compound (aliphatic polycyclic amine).

Specific examples of the aliphatic monocyclic amine include piperidine and piperazine.

The aliphatic polycyclic amine preferably has 6 to 10 carbon atoms, and specific examples thereof include 1, 5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine, and triethanolamine triacetate, and triethanolamine triacetate is preferable.

In addition, as the component (D2), an aromatic amine may be used.

Examples of the aromatic amine include 4-dimethylaminopyridine, pyrrole, indole, pyrazole, imidazole, or a derivative thereof, tribenzylamine, 2,6-diisopropylaniline, and N-tert-butoxycarbonylpyrrolidine.

The component (D2) may be used alone or in a combination of two or more kinds thereof.

In a case where the resist composition contains the component (D2), the content of the component (D2) in the resist composition is typically used in a range of 0.01 to 5 parts by mass with respect to 100 parts by mass of the component (A1). By setting the content within the above range, the resist pattern shape, the post-exposure temporal stability, and the like are improved.

<<At Least One Compound (E) Selected from the Group Consisting of Organic Carboxylic Acid, Phosphorus Oxo Acid, and Derivatives Thereof>>

For the purpose of preventing any deterioration in sensitivity and improving the resist pattern shape and post-exposure temporal stability, the resist composition according to the present embodiment may contain, as an optional component, at least one compound (E) (hereinafter referred to as the component (E)) selected from the group consisting of an organic carboxylic acid, and a phosphorus oxo acid and a derivative thereof.

Suitable examples of the organic carboxylic acid include acetic acid, malonic acid, citric acid, malic acid, succinic acid, benzoic acid, and salicylic acid.

Examples of the phosphorus oxo acid include phosphoric acid, phosphonic acid, and phosphinic acid.

Among these, phosphonic acid is particularly preferable.

Examples of the phosphorus oxo acid derivative include esters in which a hydrogen atom in the above-described oxo acids is substituted with a hydrocarbon group. Examples of the hydrocarbon group include an alkyl group having 1 to 5 carbon atoms and an aryl group having 6 to 15 carbon atoms.

Examples of the phosphoric acid derivative include phosphoric acid esters such as di-n-butyl phosphate and diphenyl phosphate.

Examples of the phosphonic acid derivative include phosphonic acid esters such as dimethyl phosphonate, di-n-butyl phosphonate, phenylphosphonic acid, diphenyl phosphonate, and dibenzyl phosphonate.

Examples of the phosphinic acid derivative include a phosphinic acid ester and phenylphosphinic acid.

In the resist composition according to the present embodiment, the component (E) may be used alone or in a combination of two or more kinds thereof.

In a case where the resist composition contains the component (E), the content of the component (E) is typically used in a range of 0.01 to 5 parts by mass with respect to 100 parts by mass of the component (A1).

<<Fluorine Additive Component (F)>>

The resist composition according to the present embodiment may further contain a fluorine additive component (hereinafter, referred to as the “component (F)”) in order to impart water repellency to the resist film or to improve lithography characteristics.

As the component (F), a fluorine-containing polymeric compound described in Japanese Unexamined Patent Application, First Publication No. 2010-002870, Japanese Unexamined Patent Application, First Publication No. 2010-032994, Japanese Unexamined Patent Application, First Publication No. 2010-277043, Japanese Unexamined Patent Application, First Publication No. 2011-13569, or Japanese Unexamined Patent Application, First Publication No. 2011-128226 can be used.

Specific examples of the component (F) include polymers having a constitutional unit (f1) represented by General Formula (f1-1). This polymer is preferably a polymer (homopolymer) consisting of only a constitutional unit (f1) represented by General Formula (f1-1) shown below; a copolymer of the constitutional unit (f1) and the constitutional unit (a1); and a copolymer of the constitutional unit (f1), a constitutional unit derived from acrylic acid or methacrylic acid, and the above-described constitutional unit (a1). The constitutional unit (a1) to be copolymerized with the constitutional unit (f1) is preferably a constitutional unit derived from 1-ethyl-1-cyclooctyl (meth)acrylate or a constitutional unit derived from 1-methyl-1-adamantyl (meth)acrylate.

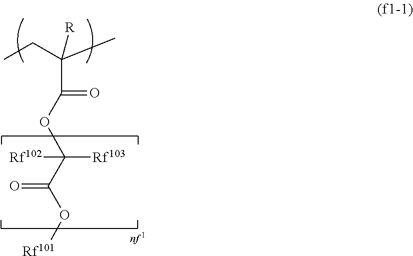

[In the formula, R has the same definition as described above. Rf¹⁰² and Rf¹⁰³ each independently represent a hydrogen atom, a halogen atom, an alkyl group having 1 to 5 carbon atoms, or a halogenated alkyl group having 1 to 5 carbon atoms, and Rf¹⁰² and Rf¹⁰³ may be the same or different from each other. nf¹ represents an integer in a range of 0 to 5, and Rf⁰¹⁰ represents an organic group containing a fluorine atom.]

In General Formula (f1-1), R bonded to the carbon atom at the α-position is the same as that described above. R is preferably a hydrogen atom or a methyl group.

In General Formula (f1-1), the halogen atom as Rf¹⁰² and Rf¹⁰³ is preferably a fluorine atom. Examples of the alkyl group having 1 to 5 carbon atoms as Rf¹⁰² and Rf¹⁰³ include the same one as the alkyl group having 1 to 5 carbon atoms as R, and a methyl group or an ethyl group is preferable. Specific examples of the halogenated alkyl group having 1 to 5 carbon atoms as Rf¹⁰² and Rf¹⁰³ include a group obtained by substituting part or all hydrogen atoms of an alkyl group having 1 to 5 carbon atoms with a halogen atom. The halogen atom is preferably a fluorine atom. Among the above, Rf¹⁰² and Rf¹⁰³ is preferably a hydrogen atom, a fluorine atom, or an alkyl group having 1 to 5 carbon atoms and more preferably a hydrogen atom, a fluorine atom, a methyl group, or an ethyl group.

In General Formula (f1-1), nf¹ represents an integer in a range of 0 to 5, preferably an integer in a range of 0 to 3, and more preferably an integer of 1 or 2.

In General Formula (f1-1), Rf⁰¹⁰ represents an organic group containing a fluorine atom and is preferably a hydrocarbon group containing a fluorine atom.

The hydrocarbon group containing a fluorine atom may be linear, branched, or cyclic, and has preferably 1 to 20 carbon atoms, more preferably 1 to 15 carbon atoms, and particularly preferably 1 to 10 carbon atoms.

In addition, in the hydrocarbon group containing a fluorine atom, preferably 25% or more of the hydrogen atoms in the hydrocarbon group are fluorinated, more preferably 50% or more are fluorinated, and particularly preferably 60% or more are fluorinated, since the hydrophobicity of the resist film during immersion exposure increases.

Among them, Rf¹⁰¹ is preferably a fluorinated hydrocarbon group having 1 to 6 carbon atoms and particularly preferably a trifluoromethyl group, —CH₂—CF₃, —CH₂—CF₂—CF₃, —CH(CF₃)₂, —CH₂—CH₂—CF₃, or —CH₂—CH₂—CF₂—CF₂—CF₂—CF₃.

The weight average molecular weight (Mw) (based on the polystyrene-equivalent value determined by gel permeation chromatography) of the component (F) is preferably 1,000 to 50,000, more preferably 5,000 to 40,000, and most preferably 10,000 to 30,000. In a case where the weight average molecular weight is equal to or smaller than the upper limit value of the above-described range, the resist composition exhibits a solubility in a resist solvent, which is enough for using the resist composition as a resist composition. On the other hand, in a case where the weight average molecular weight is equal to or larger than the lower limit value of the above-described range, water repellency of the resist film is excellent.

Further, the polydispersity (Mw/Mn) of the component (F) is preferably 1.0 to 5.0, more preferably 1.0 to 3.0, and most preferably 1.0 to 2.5.

In the resist composition according to the present embodiment, the component (F) may be used alone or in a combination of two or more kinds thereof.

In a case where the resist composition contains the component (F), the content of the component (F) is typically used in a proportion of 0.5 to 10 parts by mass, with respect to 100 parts by mass of the component (A1).

<<Organic Solvent Component (S)>>

The resist composition according to the present embodiment may be produced by dissolving the resist materials in an organic solvent component (hereinafter, referred to as the “component (S)”).

The component (S) may be any organic solvent which can dissolve each of the components to be used to obtain a homogeneous solution, and any organic solvent can be appropriately selected and used from those which have been conventionally known in the related art as solvents for a chemically amplified resist composition.

Examples of the component (S) include lactones such as γ-butyrolactone; ketones such as acetone, methyl ethyl ketone, cyclohexanone, methyl-n-pentyl ketone, methyl isopentyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkyl ether (such as monomethyl ether, monoethyl ether, monopropyl ether or monobutyl ether) or monophenyl ether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzyl ether, cresylmethyl ether, diphenyl ether, dibenzyl ether, phenetole, butylphenyl ether, ethylbenzene, diethylbenzene, pentylbenzene, isopropylbenzene, toluene, xylene, cymene and mesitylene; and dimethylsulfoxide (DMSO).

In the resist composition according to the present embodiment, the component (S) may be used singly or as a mixed solvent of two or more solvents. Among these, PGMEA, PGME, γ-butyrolactone, EL, and cyclohexanone are preferable.

Further, a mixed solvent obtained by mixing PGMEA with a polar solvent is also preferable as the component (S). The blending ratio (mass ratio) of the mixed solvent can be appropriately determined, taking into consideration the compatibility of the PGMEA with the polar solvent; however, it is preferably in a range of 1:9 to 9:1 and more preferably in a range of 2:8 to 8:2.

More specifically, in a case where EL or cyclohexanone is blended as the polar solvent, the PGMEA:EL or cyclohexanone mass ratio is preferably in a range of 1:9 to 9:1 and more preferably in a range of 2:8 to 8:2. Alternatively, in a case where PGME is blended as the polar solvent, the PGMEA:PGME mass ratio is preferably in a range of 1:9 to 9:1, more preferably in a range of 2:8 to 8:2, and still more preferably in a range of 3:7 to 7:3. Furthermore, a mixed solvent of PGMEA, PGME, and cyclohexanone is also preferable.

Further, the component (S) is also preferably a mixed solvent of at least one selected from PGMEA and EL and γ-butyrolactone. In this case, as the mixing ratio, the mass ratio of the former to the latter is preferably in a range of 70:30 to 95:5.

The amount of the component (S) to be used is not particularly limited and is appropriately set, depending on a thickness of a film to be coated, to a concentration at which the component (S) can be applied onto a substrate or the like. Generally, the component (S) is used such that the concentration of solid contents of the resist composition is in the range of 0.1% to 20% by mass and preferably 0.2% to 15% by mass.

Further, as desired, other miscible additives can be appropriately added to the resist composition according to the present embodiment. Examples of the miscible additives include an additive resin, a dissolution inhibitor, a plasticizer, a stabilizer, a colorant, a halation prevention agent, and a dye for improving the performance of a resist film.

After dissolving the resist material in the component (S), the resist composition according to the present embodiment may be subjected to removing impurities and the like by using a porous polyimide membrane, a porous polyamideimide membrane, or the like. For example, the resist composition may be filtered using a filter made of a porous polyimide membrane, a filter made of a porous polyamideimide membrane, or a filter made of a porous polyimide membrane and a porous polyamideimide membrane. An example of the porous polyimide membrane and the porous polyamideimide membrane include the film disclosed in Japanese Unexamined Patent Application, First Publication No. 2016-155121.

The resist composition according to the present embodiment described above contains the polymeric compound (A01) having the constitutional unit (a01), the constitutional unit (a02), and the constitutional unit (a03) described above, and the compound (D1).

Since the polymeric compound (A01) has the constitutional unit (a01), the solubility of the polymeric compound (A01) in a developing solution can be appropriately adjusted.

Further, since the polymeric compound (A01) has two kinds of constitutional units (the constitutional units (a02) and (a03)) having an acid dissociable group, it is possible to suppress the dissolution of unexposed portions of the resist film due to development while increasing the deprotection reactivity.

In addition, since the compound (D1) is contained, it is possible to improve the contrast between exposed portions and unexposed portions.

Due to the synergistic effect of these combinations, according to the resist composition according to the present embodiment, it is possible to improve all of the roughness reduction property, the collapse margin, and the film remaining in pattern.

The resist composition according to the present embodiment is useful particularly in the formation of a coarse pitch pattern in which the line width is fine as compared with the space width.

(Method of Forming Resist Pattern)

The method of forming a resist pattern according to the second aspect of the present invention is a method including a step of forming a resist film on a support using the resist composition according to the first aspect of the present invention described above, a step of exposing the resist film, and a step of developing the exposed resist film to form a resist pattern.

An example of one embodiment of such a method of forming a resist pattern include a method of forming a resist pattern carried out as described below.

First, the above-described resist composition of the embodiment is applied onto a support with a spinner or the like, and a baking (post-apply baking (PAB)) treatment is carried out, for example, at the temperature condition of 80° C. to 150° C. for 40 to 120 seconds, preferably for 60 to 90 seconds, to form a resist film.

Following the selective exposure carried out on the resist film by, for example, the exposure through a mask (mask pattern) having a predetermined pattern formed on the mask by using a lithography apparatus, for example, an electron beam lithography apparatus and an ArF exposure apparatus, or by the direct irradiation of the resist film for drawing with electron beam without using a mask pattern, baking treatment (post-exposure baking (PEB)) is carried out, for example, under the temperature condition of 80° C. to 150° C. for 40 to 120 seconds and preferably 60 to 90 seconds.

Next, the resist film is subjected to a developing treatment. The developing treatment is carried out using an alkali developing solution in a case of an alkali developing process, and a developing solution containing an organic solvent (organic developing solution) in a case of a solvent developing process.

After the developing treatment, it is preferable to carry out rinse treatment. In a case of an alkali developing process, the rinse treatment is preferably water rinsing using pure water, and in a case of a solvent developing process, a rinse liquid containing an organic solvent is preferably used.

In a case of a solvent developing process, after the developing treatment or the rinse treatment, the developing solution or the rinse liquid remaining on the pattern can be removed by a treatment using a supercritical fluid.

After the developing treatment or the rinse treatment, drying is carried out. As desired, baking treatment (post-baking) can be carried out following the developing treatment.

In this manner, a resist pattern can be formed.

The support is not particularly limited and a conventionally known support in the related art can be used. Examples thereof include a substrate for electronic components, and a substrate for electronic components, having a wiring pattern formed on the substrate. More specific examples of the substrate include silicon wafer, substrates made of metals such as copper, chromium, iron, and aluminum, and a glass substrate. As the material for a wiring pattern, copper, aluminum, nickel, or gold can be used.

Further, as the support, any support having the above-described substrate on which an inorganic and/or an organic film is provided may be used. An example of the inorganic film includes an inorganic antireflection film (inorganic BARC). Examples of the organic film include an organic antireflection film (organic BARC) and an organic film such as a lower-layer organic film used in a multilayer resist method.

Here, the multilayer resist method is a method in which at least one layer of an organic film (lower-layer organic film) and at least one layer of a resist film (upper-layer resist film) are provided on a substrate, and a resist pattern formed on the upper-layer resist film is used as a mask to carry out patterning of the lower-layer organic film. This method is considered as a method capable of forming a pattern having a high aspect ratio. That is, according to the multilayer resist method, a desired thickness can be ensured by the lower-layer organic film, and as a result, the thickness of the resist film can be reduced, and thus a fine pattern with a high aspect ratio can be formed.

The multilayer resist method is classified into a method (double-layer resist method) in which a double-layer structure consisting of an upper-layer resist film and a lower-layer organic film is formed, and a method (triple-layer resist method) in which a multilayer structure having three or more layers that include one or more intermediate layers (thin metal films or the like) provided between the upper-layer resist film and the lower-layer organic film is formed.

The wavelength to be used for exposure is not particularly limited and the exposure can be carried out using radiation such as an ArF excimer laser, a KrF excimer laser, an F₂ excimer laser, an extreme ultraviolet ray (EUV), a vacuum ultraviolet ray (VUV), an electron beam (EB), an X ray, or a soft X ray. The resist composition is highly useful for a KrF excimer laser, an ArF excimer laser, EB, or EUV, and is more useful for an ArF excimer laser.

The exposure method of the resist film can be a general exposure (dry exposure) carried out in air or an inert gas such as nitrogen, or liquid immersion exposure (liquid immersion lithography); however, liquid immersion lithography is more preferable.

In liquid immersion lithography, the region between the resist film and the lens at the lowermost point of the exposure apparatus is pre-filled with a solvent (liquid immersion medium) that has a refractive index higher than the refractive index of air, and exposure (dipping exposure) is carried out in this state.

The liquid immersion medium is preferably a solvent that has a refractive index higher than the refractive index of air but lower than the refractive index of the resist film to be exposed. The refractive index of the solvent is not particularly limited as long as it satisfies the above-described requirements.

Examples of the solvent that exhibits a refractive index that is higher than the refractive index of air but lower than the refractive index of the resist film include water, a fluorine-based inert liquid, a silicone-based solvent, and a hydrocarbon-based solvent.

Specific examples of the fluorine-based inert liquids include liquids containing a fluorine-based compound such as C₃HCl₂F₅, C₄F₉OCH₃, C₄F₉OC₂H₅, or C₅H₃F₇ as the main component, and the boiling point is preferably in a range of 700 to 180° C. and more preferably in a range of 80° to 160° C. A fluorine-based inert liquid having a boiling point in the above-described range is advantageous in that the medium used in the liquid immersion can be removed by a simple method after the exposure.

The fluorine-based inert liquid is particularly preferably a perfluoroalkyl compound obtained by substituting all hydrogen atoms of an alkyl group with fluorine atoms. Examples of the perfluoroalkyl compounds include a perfluoroalkyl ether compound and a perfluoroalkylamine compound.

An specific example of the perfluoroalkyl ether compound includes perfluoro(2-butyl-tetrahydrofuran) (boiling point: 102° C.), and an example of the perfluoroalkylamine compound includes perfluorotributylamine (boiling point: 174° C.).

As the liquid immersion medium, water is preferable in terms of cost, safety, environment, and versatility.

An example of the alkali developing solution used for a developing treatment in an alkali developing process includes a 0.1 to 10% by mass aqueous solution of tetramethylammonium hydroxide (TMAH).

The organic solvent contained in the organic developing solution used for a developing treatment in a solvent developing process may be a solvent that is capable of dissolving the component (A) (prior to exposure) and can be appropriately selected from the conventionally known organic solvents. Specific examples of the organic solvent include polar solvents such as a ketone-based solvent, an ester-based solvent, an alcohol-based solvent, a nitrile-based solvent, an amide-based solvent, and an ether-based solvent, and a hydrocarbon-based solvent.

A ketone-based solvent is an organic solvent containing C—C(═O)—C in the structure thereof. An ester-based solvent is an organic solvent containing C—C(═O)—O—C in the structure thereof. An alcohol-based solvent is an organic solvent containing an alcoholic hydroxyl group in the structure thereof. The “alcoholic hydroxyl group” indicates a hydroxyl group bonded to a carbon atom of an aliphatic hydrocarbon group. A nitrile-based solvent is an organic solvent containing a nitrile group in the structure thereof. An amide-based solvent is an organic solvent containing an amide group in the structure thereof. An ether-based solvent is an organic solvent containing C—O—C in the structure thereof.

Some organic solvents have a plurality of functional groups that characterizes the above-described solvent in the structure thereof. In such a case, the organic solvent corresponds to any type of solvents having the characteristic functional groups. For example, diethylene glycol monomethyl ether corresponds to an alcohol-based solvent or an ether-based solvent.

A hydrocarbon-based solvent consists of a hydrocarbon which may be halogenated and does not have any substituent other than a halogen atom. The halogen atom is preferably a fluorine atom.

Among the above, the organic solvent contained in the organic developing solution is preferably a polar solvent, and more preferably a ketone-based solvent, an ester-based solvent, and a nitrile-based solvent.

Examples of the ketone-based solvent include 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonylalcohol, acetylcarbinol, acetophenone, methyl naphthyl ketone, isophorone, propylenecarbonate, γ-butyrolactone and methyl amyl ketone (2-heptanone). Among these, methyl amyl ketone (2-heptanone) is preferable as a ketone-based solvent.

Examples of ester-based solvent include methyl acetate, butyl acetate, ethyl acetate, isopropyl acetate, amyl acetate, isoamyl acetate, ethyl methoxyacetate, ethyl ethoxyacetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Among these, the ester-based solvent is preferably butyl acetate.

Examples of nitrile-based solvent include acetonitrile, propionitrile, valeronitrile, and butyronitrile.

As necessary, the organic developing solution may be blended with a conventionally known additive. Examples of the additive include surfactants. The surfactant is not particularly limited, and for example, an ionic or non-ionic fluorine and/or a silicone-based surfactant can be used. The surfactant is preferably a non-ionic surfactant and more preferably a non-ionic fluorine surfactant or a non-ionic silicone-based surfactant.

In a case where a surfactant is blended, the amount of the surfactant to be blended is typically 0.001% to 5% by mass, preferably 0.005% to 2% by mass, and more preferably 0.01% to 0.5% by mass with respect to the total amount of the organic developing solution.

The developing treatment can be carried out by a conventionally known developing method. Examples thereof include a method (a dip method) in which the support is dipped in a developing solution for a predetermined period, a method (a puddle method) in which a developing solution is cast onto the surface of the support by surface tension and maintained for a predetermined period, a method (a spray method) in which a developing solution is sprayed onto the surface of the support, and a method (a dynamic dispense method) in which a developing solution is continuously ejected and applied onto the support which rotates at a constant speed while the support is scanned at a constant speed with a developing solution ejecting nozzle.

As the organic solvent contained in the rinse liquid that is used in the rinse treatment after the developing treatment in a case of a solvent developing process, an organic solvent hardly dissolving the resist pattern can be appropriately selected and used, among the organic solvents mentioned as organic solvents that are used for the organic developing solution. In general, at least one kind of solvent selected from the group consisting of a hydrocarbon-based solvent, a ketone-based solvent, an ester-based solvent, an alcohol-based solvent, an amide-based solvent, and an ether-based solvent is used. Among these, at least one kind of solvent selected from the group consisting of a hydrocarbon-based solvent, a ketone-based solvent, an ester-based solvent, an alcohol-based solvent, and an amide-based solvent is preferable, at least one kind of solvent selected from the group consisting of an alcohol-based solvent and an ester-based solvent is more preferable, and an alcohol-based solvent is particularly preferable.

The alcohol-based solvent used for the rinse liquid is preferably a monohydric alcohol of 6 to 8 carbon atoms, and the monohydric alcohol may be linear, branched, or cyclic. Specific examples thereof include 1-hexanol, 1-heptanol, 1-octanol, 2-hexanol, 2-heptanol, 2-octanol, 3-hexanol, 3-heptanol, 3-octanol, 4-octanol, and benzyl alcohol. Among these, 1-hexanol, 2-heptanol, and 2-hexanol are preferable, and 1-hexanol and 2-hexanol are more preferable.

As the organic solvent, one kind of solvent may be used alone, or two or more kinds of solvents may be used in combination. Further, an organic solvent other than the above or water may be mixed for use. However, in consideration of the development characteristics, the amount of water to be blended in the rinse liquid is preferably 30% by mass or less, more preferably 10% by mass or less, still more preferably 5% by mass or less, and particularly preferably 3% by mass or less, with respect to the total amount of the rinse liquid.

A conventionally known additive can be blended with the rinse liquid as necessary. Examples of the additive include surfactants. Examples of the surfactant include the same ones as those described above, a non-ionic surfactant is preferable, and a non-ionic fluorine surfactant or a non-ionic silicone-based surfactant is more preferable.

In a case where a surfactant is blended, the amount of the surfactant to be blended is typically 0.001% to 5% by mass, preferably 0.005% to 2% by mass, and more preferably 0.01% to 0.5% by mass, with respect to the total amount of the rinse liquid.

The rinse treatment (washing treatment) using a rinse liquid can be carried out by a conventionally known rinse method. Examples of the rinse treatment method include a method in which the rinse liquid is continuously ejected and applied onto a support which rotates at a constant rate (a rotational coating method), a method in which a support is dipped in the rinse liquid for a predetermined time (a dip method), and a method in which the rinse liquid is sprayed onto the surface of a support (a spray method).

According to the method of forming a resist pattern according to the present embodiment described above, since the resist composition described above is used, it is possible to form a resist pattern that has a good roughness reduction property, a good collapse margin, and good film remaining in pattern.

In addition, according to the method of forming a resist pattern according to the present embodiment, the roughness reduction property, the collapse margin, and the film remaining in pattern are excellent particularly in the formation of a coarse pitch pattern.

### EXAMPLES

Hereinafter, the present invention will be described in more detail based on Examples, but the present invention is not limited to these Examples.

### Production of Polymeric Compound

Each of polymeric compounds (A1-1) to (A1-11) and (A2-1) to (A2-6) used in present Examples was obtained by carrying out radical polymerization using monomers from which constitutional units constituting each of the polymeric compounds are derived, at a predetermined molar ratio.

The weight average molecular weight (Mw) and the polydispersity (Mw/Mn) of each of the obtained polymeric compounds were determined by GPC measurement (in terms of standard polystyrene-equivalent value).

In addition, the copolymerization composition ratio (the ratio (molar ratio) of each constitutional unit in the structural formula) of each of the obtained polymeric compounds was determined from the carbon 13 nuclear magnetic resonance spectrum (600 MHz_¹³C-NMR).

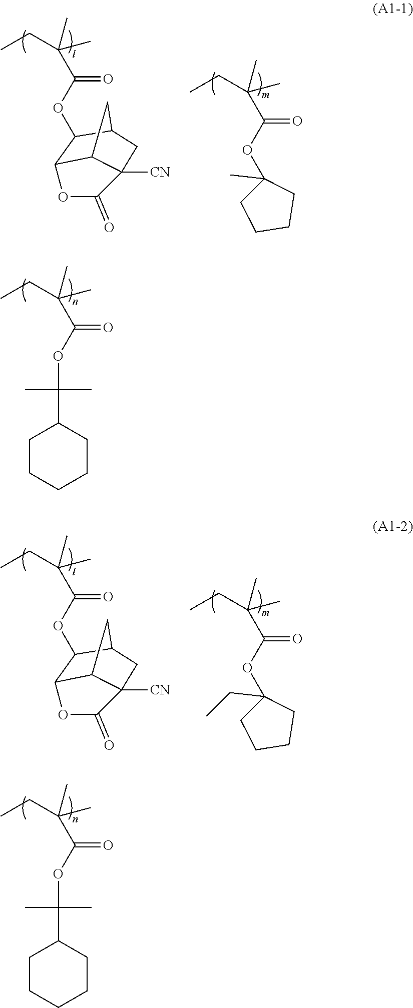

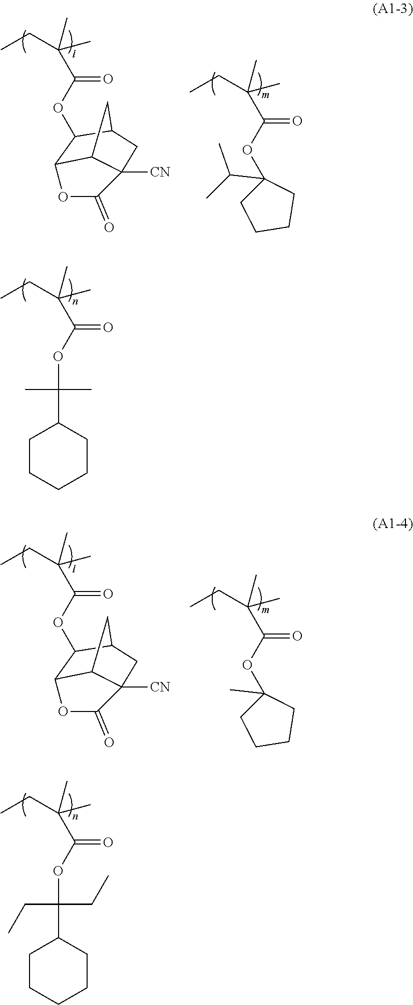

Polymeric compound (A1-1): Weight average molecular weight (Mw): 6,900, polydispersity (Mw/Mn): 1.57, l/m/n=50/10/40.

Polymeric compound (A1-2): Weight average molecular weight (Mw): 7,000, polydispersity (Mw/Mn): 1.60, l/m/n=50/10/40.

Polymeric compound (A1-3): Weight average molecular weight (Mw): 7,200, polydispersity (Mw/Mn): 1.61, l/m/n=50/10/40.

Polymeric compound (A1-4): Weight average molecular weight (Mw): 7,100, polydispersity (Mw/Mn): 1.67, l/m/n=50/10/40.

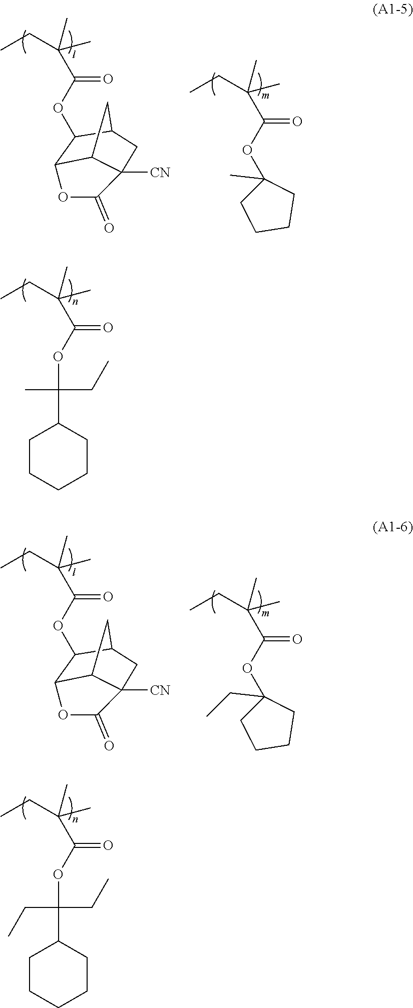

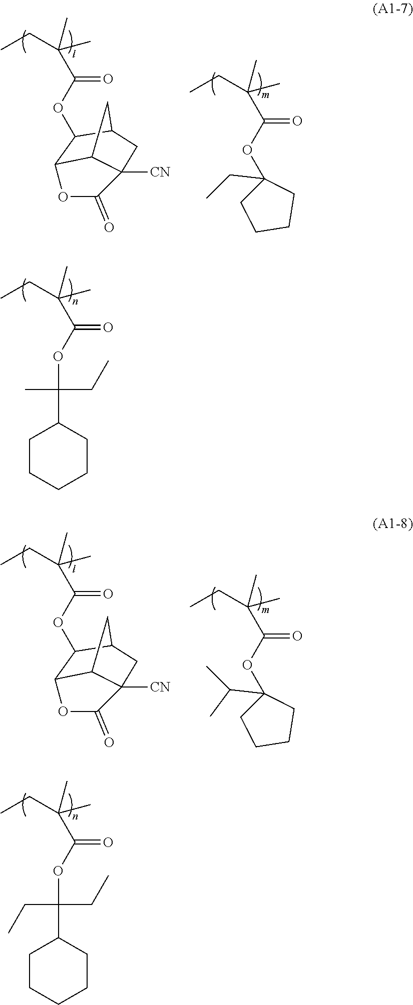

Polymeric compound (A1-5): Weight average molecular weight (Mw): 7,000, polydispersity (Mw/Mn): 1.63, l/m/n=50/10/40.

Polymeric compound (A1-6): Weight average molecular weight (Mw): 6,800, polydispersity (Mw/Mn): 1.59, l/m/n=50/10/40.

Polymeric compound (A1-7): Weight average molecular weight (Mw): 6,600, polydispersity (Mw/Mn): 1.58, l/m/n=50/10/40.

Polymeric compound (A1-8): Weight average molecular weight (Mw): 6,900, polydispersity (Mw/Mn): 1.62, l/m/n=50/10/40.

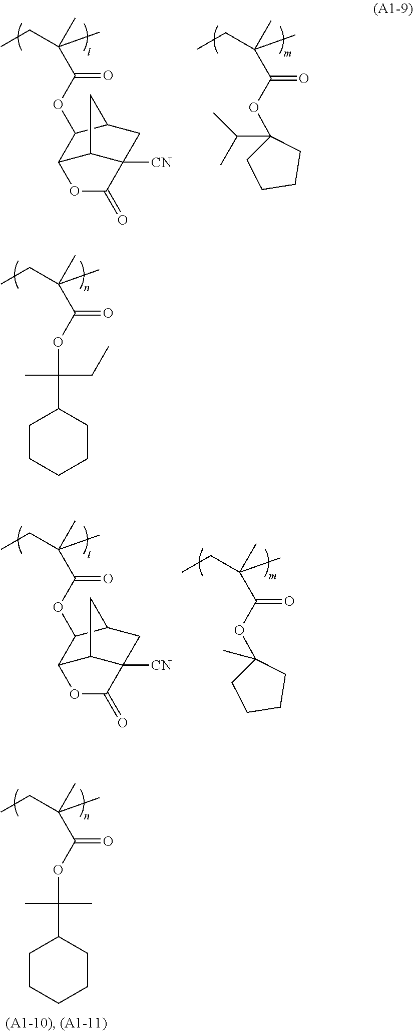

Polymeric compound (A1-9): Weight average molecular weight (Mw): 7,200, polydispersity (Mw/Mn): 1.66, l/m/n=50/10/40.

Polymeric compound (A1-10): Weight average molecular weight (Mw): 7.000, polydispersity (Mw/Mn): 1.59, l/m/n=50/25/25.

Polymeric compound (A1-11): Weight average molecular weight (Mw): 6,800, polydispersity (Mw/Mn): 1.58, l/m/n=50/40/10.

Between the polymeric compounds (A1-1), (A1-10), and (A1-11), the constitutional units contained in the polymeric compounds are the same, and the ratios between the constitutional units are different from each other.

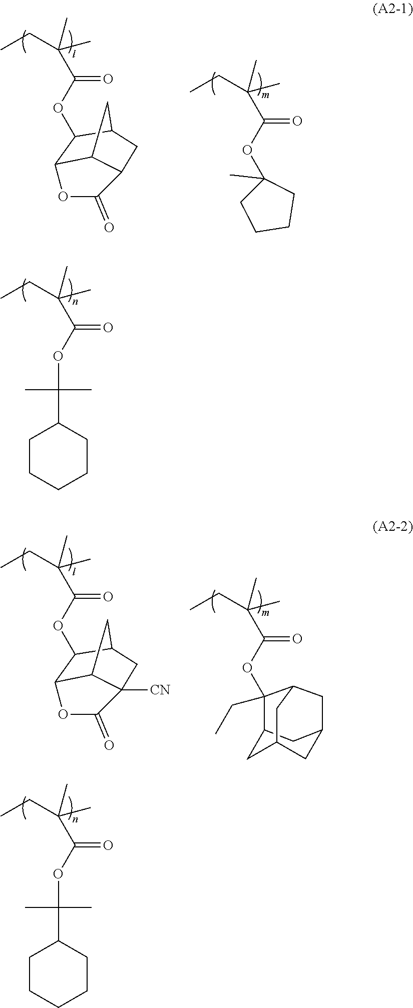

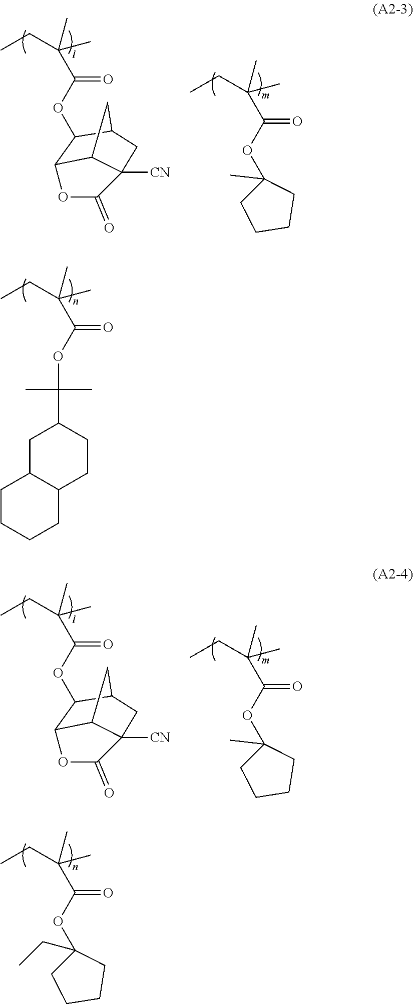

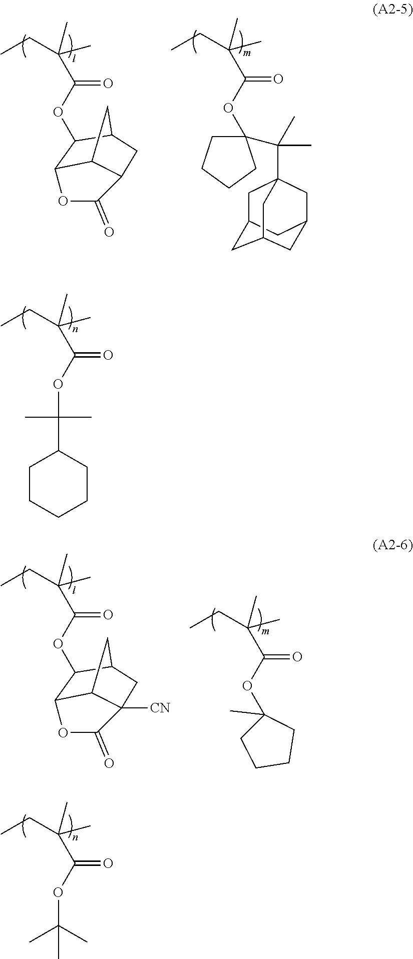

Polymeric compound (A2-1): Weight average molecular weight (Mw): 7,000, polydispersity (Mw/Mn): 1.64, l/m/n=50/10/40.

Polymeric compound (A2-2): Weight average molecular weight (Mw): 6,800, polydispersity (Mw/Mn): 1.50, l/m/n=50/10/40.

Polymeric compound (A2-3): Weight average molecular weight (Mw): 6,800, polydispersity (Mw/Mn): 1.53, l/m/n=50/10/40.

Polymeric compound (A2-4): Weight average molecular weight (Mw): 8,000, polydispersity (Mw/Mn): 1.50, l/m/n=50/10/40.

Polymeric compound (A2-5): Weight average molecular weight (Mw): 7,500, polydispersity (Mw/Mn): 1.60, l/m/n=50/10/40.

Polymeric compound (A2-6): Weight average molecular weight (Mw): 7,200, polydispersity (Mw/Mn): 1.61, l/m/n=50/10/40.

### Preparation of Resist Composition

### Examples 1 to 17 and Comparative Examples 1 to 8

Each of the components shown in Table 1 and 2 was mixed and dissolved to prepare a resist composition of each Example.

TABLE 1

| | Component | Component | Component | Component |
|---|---|---|---|---|
| | (A) | (B) | (D) | (S) |
| Example 1 | (A1)-1 | (B)-1 | (D1)-1 | (S)-1 |
| | [100] | [10.8] | [9.0] | [2275] |
| Example 2 | (A1)-1 | (B)-1 | (D1)-2 | (S)-1 |
| | [100] | [10.8] | [9.0] | [2275] |
| Example 3 | (A1)-1 | (B)-1 | (D1)-3 | (S)-1 |
| | [100] | [10.8] | [6.8] | [2275] |
| Example 4 | (A1)-1 | (B)-1 | (D1)-4 | (S)-1 |
| | [100] | [10.8] | [7.0 | [2275] |
| Example 5 | (A1)-1 | (B)-1 | (D1)-5 | (S)-1 |
| | [100] | [10.8] | [9.0] | [2275] |
| Example 6 | (A1)-2 | (B)-1 | (D1)-1 | (S)-1 |
| | [100] | [10.8] | [9.0] | [2275] |
| Example 7 | (A1)-3 | (B)-1 | (D1)-1 | (S)-1 |
| | [100] | [10.8] | [9.0] | [2275] |
| Example 8 | (A1)-4 | (B)-1 | (D1)-1 | (S)-1 |
| | [100] | [10.8] | [9.0] | [2275] |
| Example 9 | (A1)-5 | (B)-1 | (D1)-1 | (S)-1 |
| | [100] | [10.8] | [9.0] | [2275] |
| Example 10 | (A1)-6 | (B)-1 | (D1)-1 | (S)-1 |
| | [100] | [10.8] | [9.0] | [2275] |
| Example 11 | (A1)-7 | (B)-1 | (D1)-1 | (S)-1 |
| | [100] | [10.8] | [9.0] | [2275] |
| Example 12 | (A1)-8 | (B)-1 | (D1)-1 | (S)-1 |
| | [100] | [10.8] | [9.0] | [2275] |
| Example 13 | (A1)-9 | (B)-1 | (D1)-1 | (S)-1 |
| | [100] | [10.8] | [9.0] | [2275] |
| Example 14 | (A1)-10 | (B)-1 | (D1)-1 | (S)-1 |
| | [100] | [10.8] | [9.0] | [2275] |
| Example 15 | (A1)-11 | (B)-1 | (D1)-1 | (S)-1 |
| | [100] | [10.8] | [9.0] | [2275] |
| Example 16 | (A1)-1 | (B)-1 | (D1)-6 | (S)-1 |
| | [100] | [10.8] | [9.0] | [2275] |
| Example 17 | (A1)-1 | (B)-2 | (D1)-1 | (S)-1 |
| | [100] | [10.8] | [9.0] | [2275] |

TABLE 2

| | Component | Component | Component | Component |
|---|---|---|---|---|
| | (A) | (B) | (D) | (S) |
| Comparative | (A2)-1 | (B)-1 | (D1)-1 | (S)-1 |
| Example 1 | [100] | [10.8] | [9.0] | [2275] |
| Comparative | (A2)-2 | (B)-1 | (D1)-1 | (S)-1 |
| Example 2 | [100] | [10.8] | [9.0] | [2275] |
| Comparative | (A2)-3 | (B)-1 | (D1)-1 | (S)-1 |
| Example 3 | [100] | [10.8] | [9.0] | [2275] |
| Comparative | (A1)-1 | (B)-1 | (D2)-1 | (S)-1 |
| Example 4 | [100] | [10.8] | [5.2] | [2275] |
| Comparative | (A2)-4 | (B)-1 | (D1)-1 | (S)-1 |
| Example 5 | [100] | [10.8] | [9.0] | [2275] |
| Comparative | (A2)-5 | (B)-1 | (D1)-1 | (S)-1 |
| Example 6 | [100] | [10.8] | [9.0] | [2275] |
| Comparative | (A2)-6 | (B)-1 | (D1)-1 | (S)-1 |
| Example 7 | [100] | [10.8] | [9.0] | [2275] |
| Comparative | (A2)-1 | (B)-1 | (D2)-1 | (S)-1 |
| Example 8 | [100] | [10.8] | [5.2] | [2275] |

In Tables 1 and 2, each abbreviation has the following meaning. The numerical value in the bracket indicates the blending amount (parts by mass).

(A1)-1 to (A1)-11: The polymeric compounds (A1-1) to (A1-11).

(A2)-1 to (A2)-6: The polymeric compounds (A2-1) to (A2-6).

(B)-1: An acid generator composed of a compound represented by Chemical Formula (B-1).

(B)-2: An acid generator composed of a compound represented by Chemical Formula (B-2).

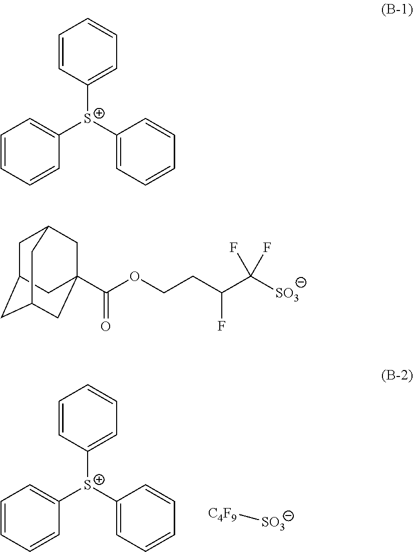

(D1)-1 to (D1)-6: Acid diffusion controlling agents consisting of compounds each represented by Chemical Formulae (D1-1) to (D1-6).

(D2)-1: Tri-n-octylamine

(S)-1: A mixed solvent of propylene glycol monomethyl ether acetate/propylene glycol monomethyl ether/cyclohexanone=60/10/30 (mass ratio)

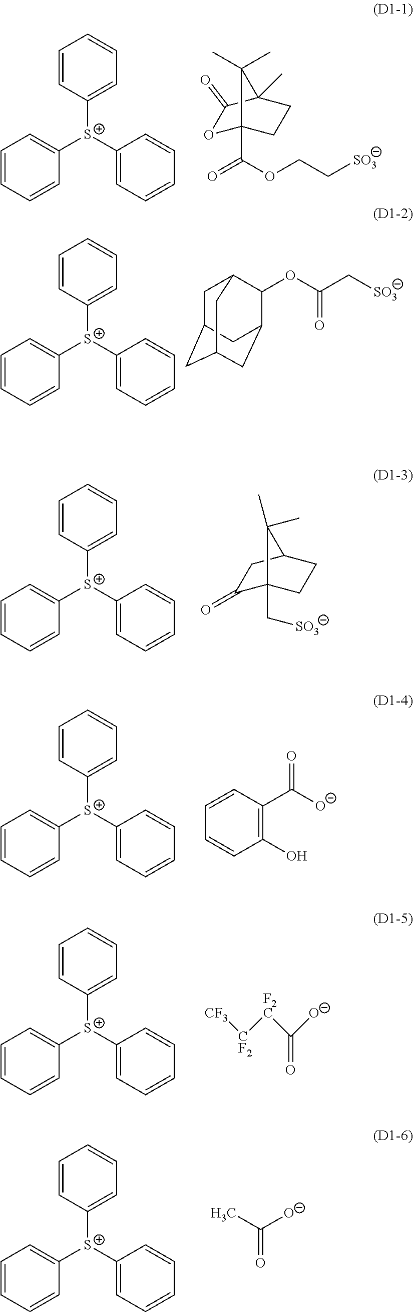

<Formation of Resist Pattern>

An organic antireflection film composition (product name: ARC29A, manufactured by Brewer Science Inc.) was applied onto a 12-inch silicon wafer using a spinner and sintered and dried on a hot plate at 205° C. for 60 seconds to form an organic antireflection film having a thickness of 98 nm.

The resist composition of each Example was applied onto the above antireflection film using a spinner, and a post-apply baking (PAB) treatment was carried out at 130° C. for 60 seconds on a hot plate, followed by drying to form each resist film having a thickness of 80 nm.

Next, a top coat was applied onto the resist film using a spinner, and baking treatment was carried out on a hot plate at 90° C. for 60 seconds to form each topcoat film having a film thickness of 35 nm.

Next, the resist film was selectively irradiated with an ArF excimer laser (193 nm) through a photomask (halftone: 6%) using an ArF exposure apparatus for liquid immersion NXT 1900Gi [manufactured by ASML; numerical aperture (NA)=1.35, Dipole 90X, Sigma (in/out=0.80/0.97) TE-pol, liquid immersion medium: ultrapure water]. Then, PEB treatment was carried out at 90° C. for 60 seconds.

Next, alkali development was carried out with a 2.38% by mass TMAH aqueous solution (product name: NMD-3, manufactured by Tokyo Ohka Kogyo Co., Ltd.) at 23° C. for 15 seconds, and then water rinsing was carried out for 15 seconds using pure water, followed by shake-off drying.

As a result of the above, each line and space pattern (hereinafter, referred to as an LS pattern) having a line width of 30 nm and a pitch of 90 nm (mask size: 40 nm) was formed.

[Evaluation of Optimum Exposure Amount (Eop)]

According to <Formation of resist pattern> described above, an optimum exposure amount Eop (mJ/cm²) for forming the LS pattern having the target size was determined. The results are shown in Table 3 as “Eop (mJ/cm²)”.

[Evaluation of Linewise Roughness (LWR)]

3σ of the LS pattern formed in <Formation of resist pattern> described above, which is a scale indicating LWR, was determined. The results are shown in Table 3 “LWR (nm)”.

“3σ” indicates a triple value (unit: nm) of the standard deviation (a) determined from measurement results obtained by measuring 400 line positions in the longitudinal direction of the line with a critical dimension scanning electron microscope (SEM, acceleration voltage: 500 V, product name: CG5000, manufactured by Hitachi High-Tech Corporation).

The smaller the value of 3a is, the smaller the roughness in the line side wall is, which means an LS pattern having a more uniform width was obtained.

[Evaluation of Collapse Margin]

According to <Formation of resist pattern> described above, an optimum exposure amount Eop for forming the LS pattern having the target size was determined. Then, LS patterns were formed by gradually increasing the exposure amount from the optimum exposure amount Eop described above, and the minimum size of the pattern that was resolved without being collapsed was determined using a critical dimension scanning electron microscope (SEM, acceleration voltage: 500V, product name: CG5000, manufactured by Hitachi High-Tech Corporation). The results are shown in Table 3 as a “Collapse margin (nm)”.

[Evaluation of Film Remaining in Pattern]

The LS pattern formed in <Formation of resist pattern> described above was subjected to the cross section observation by a critical dimension scanning electron microscope (SEM, product name: SU-8000, manufactured by Hitachi High-Tech Corporation), and the film remaining in pattern was measured and evaluated according to the following evaluation criteria. These results are shown in Table 3 as “Film remaining in pattern”.

A: Film remaining in pattern is more than 70 nm and 80 nm or less.

B: Film remaining in pattern is 60 nm or more and 70 nm or less.

C: Film remaining in pattern is less than 60 nm.

TABLE 3

| | | | | | | Film |
|---|---|---|---|---|---|---|
| | | | Eop | | Collapse | remaining |
| | PAB | PEB | [mJ/ | LWR | margin | in |
| | (° C.) | (° C.) | cm²] | [nm] | [nm] | pattern |
| Example 1 | 130 | 90 | 32.5 | 3.20 | 21.5 | A |
| Example 2 | 130 | 90 | 31.8 | 3.18 | 22.0 | A |
| Example 3 | 130 | 90 | 34.5 | 3.25 | 23.8 | A |
| Example 4 | 130 | 90 | 35.0 | 3.46 | 23.0 | A |
| Example 5 | 130 | 90 | 33.2 | 3.50 | 23.4 | A |
| Example 6 | 130 | 90 | 30.6 | 3.21 | 22.3 | A |
| Example 7 | 130 | 90 | 27.2 | 3.32 | 22.4 | A |
| Example 8 | 130 | 90 | 30.4 | 3.29 | 23.0 | A |
| Example 9 | 130 | 90 | 31.5 | 3.23 | 23.3 | A |
| Example 10 | 130 | 90 | 29.4 | 3.15 | 23.5 | A |
| Example 11 | 130 | 90 | 30.2 | 3.22 | 22.8 | A |
| Example 12 | 130 | 90 | 27.4 | 3.30 | 23.0 | A |
| Example 13 | 130 | 90 | 28.0 | 3.30 | 22.5 | A |
| Example 14 | 130 | 90 | 32.8 | 3.47 | 22.2 | A |
| Example 15 | 130 | 90 | 33.0 | 3.66 | 21.4 | A |
| Example 16 | 130 | 90 | 36.3 | 3.61 | 24.1 | A |
| Example 17 | 130 | 90 | 32.0 | 3.81 | 23.7 | A |
| Comparative | 130 | 90 | 40.5 | 4.80 | 25.3 | A |
| Example 1 | | | | | | |
| Comparative | 130 | 90 | 23.4 | 5.91 | 33.6 | A |
| Example 2 | | | | | | |
| Comparative | 130 | 90 | 34.5 | 4.57 | 30.0 | A |
| Example 3 | | | | | | |
| Comparative | 130 | 90 | 38.1 | 5.21 | 24.1 | B |
| Example 4 | | | | | | |
| Comparative | 130 | 90 | 30.1 | 4.27 | 23.4 | C |
| Example 5 | | | | | | |
| Comparative | 130 | 90 | 20.6 | 6.30 | 35.1 | A |
| Example 6 | | | | | | |
| Comparative | 130 | 90 | 42.2 | 4.73 | 27.4 | B |
| Example 7 | | | | | | |
| Comparative | 130 | 90 | 43.0 | 7.21 | 32.6 | B |
| Example 8 | | | | | | |

As shown in Table 3, it has been confirmed that according to the resist composition of Example, all of the sensitivity, the roughness reduction property, and the collapse margin are good as compared with the resist composition of Comparative Example and it is possible to form a resist pattern having a high level of film remaining in pattern.

While preferred embodiments of the invention have been described and illustrated above, it should be understood that these are exemplary of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

What is claimed is:

1. A resist composition which generates acid upon exposure and exhibits changed solubility in a developing solution under action of acid, the resist composition comprising:
a resin component (A1) which exhibits changed solubility in a developing solution under action of acid; and
at least one compound (D1) selected from the group consisting of a compound represented by General Formula (d1-1) and a compound represented by General Formula (d1-2),
wherein the resin component (A1) contains a polymeric compound (A01) having a constitutional unit (a01) represented by General Formula (a0-1), a constitutional unit (a02) represented by General Formula (a0-2), and a constitutional unit (a03) represented by General Formula (a0-3): 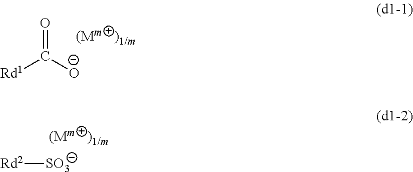
wherein, in the formulae, Rd¹ and Rd² each independently represent a cyclic group which may have a substituent, a chain alkyl group which may have a substituent, or a chain alkenyl group which may have a substituent, provided that a carbon atom adjacent to a S atom in Rd² in General Formula (d1-2) has no fluorine atom bonded thereto, m represents an integer of 1 or more, and each M^{m+} independently represents an m-valent organic cation; 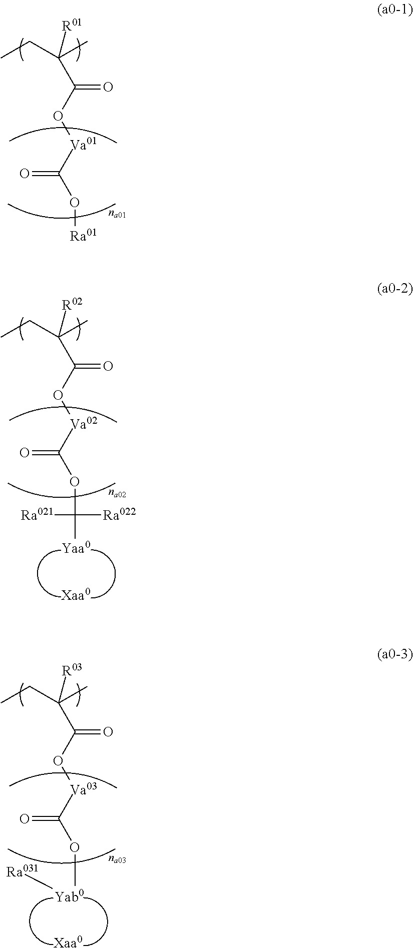
wherein, in General Formula (a0-1), R⁰¹ represents a hydrogen atom, an alkyl group having 1 to 5 carbon atoms, or a halogenated alkyl group having 1 to 5 carbon atoms, Va⁰¹ represents a divalent linking group, nₐ₀₁ represents an integer in a range of 0 to 2, and Ra⁰¹ represents a lactone-containing cyclic group having one or more substituents selected from the group consisting of a halogen atom, a carboxy group, an acyl group, a nitro group, and a cyano group, where the lactone-containing cyclic group may have a substituent other than the substituents in the above group;
in General Formula (a0-2), R⁰² represents a hydrogen atom, an alkyl group having 1 to 5 carbon atoms, or a halogenated alkyl group having 1 to 5 carbon atoms, Va⁰² represents a divalent linking group, nₐ₀₂ represents an integer in a range of 0 to 2, Ra⁰²¹ and Ra⁰²² each independently represent a chain alkyl group, Yaa⁰ represents a carbon atom, and Xaa⁰ represents a group that forms a monocyclic alicyclic hydrocarbon group together with Yaa⁰, where part or all hydrogen atoms contained in the monocyclic alicyclic hydrocarbon group may be substituted; and
in General Formula (a0-3), R⁰³ represents a hydrogen atom, an alkyl group having 1 to 5 carbon atoms, or a halogenated alkyl group having 1 to 5 carbon atoms, Va⁰³ represents a divalent linking group, nₐ₀₃ represents an integer in a range of 0 to 2, Ra⁰³¹ represents a chain alkyl group, Yab⁰ represents a carbon atom, and Xab⁰ represents a group that forms a monocyclic alicyclic hydrocarbon group together with Yab⁰, where part or all hydrogen atoms contained in the monocyclic alicyclic hydrocarbon group may be substituted.

2. The resist composition according to claim 1, wherein the constitutional unit (a01) is a constitutional unit represented by General Formula (a01-1): 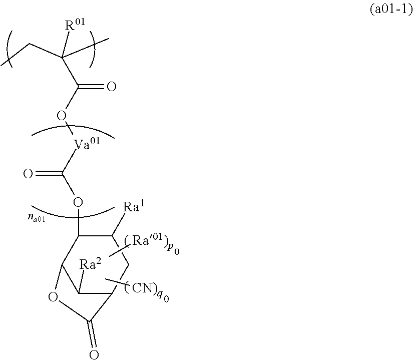
wherein, in General Formula (a01-1), R⁰¹ represents a hydrogen atom, an alkyl group having 1 to 5 carbon atoms, or a halogenated alkyl group having 1 to 5 carbon atoms, Va⁰¹ represents a divalent linking group, nₐ₀₁ represents an integer in a range of 0 to 2, Ra¹ and Ra² each independently represent a hydrogen atom, an alkyl group having 1 to 5 carbon atoms, an alkoxy group, or an alkylthio group, or Ra¹ and Ra² may be bonded to each other to become an alkylene group having 1 to 6 carbon atoms, which may contain an oxygen atom or sulfur atom, or to become an ether bond or a thioether bond, Ra′⁰¹ represents a halogen atom, an alkyl group having 1 to 6 carbon atoms, which may have a halogen atom, a hydroxyalkyl group having 1 to 6 carbon atoms, in which a hydroxy group moiety may be protected by a protecting group and which may have a halogen atom, a carboxy group which may form a salt, or a substituted oxycarbonyl group, p₀ represents an integer in a range of 0 to 8, in a case where two or more Ra′⁰¹'s are present, a plurality of Ra′⁰¹'s may be the same or different from each other, and q₀ represents an integer in a range of 1 to 9.

3. The resist composition according to claim 1, wherein the constitutional unit (a01) is a constitutional unit represented by General Formula (a01-1-1): 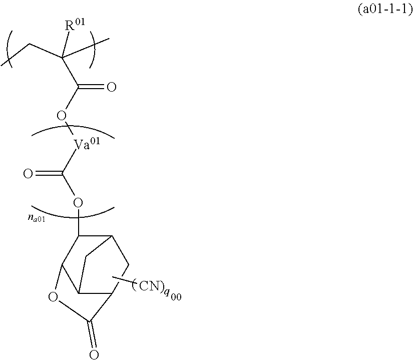
wherein, in General Formula (a01-1-1), R⁰¹ represents a hydrogen atom, an alkyl group having 1 to 5 carbon atoms, or a halogenated alkyl group having 1 to 5 carbon atoms, Va⁰¹ represents a divalent linking group, nₐ₀₁ represents an integer in a range of 0 to 2, and q₀₀ represents an integer in a range of 1 to 3.

4. The resist composition according to claim 1, wherein the compound (D1) contains a compound represented by General Formula (d1-2).

5. The resist composition according to claim 1, wherein in the polymeric compound (A01), a molar ratio of a content of the constitutional unit (a01) to a total content of the constitutional unit (a02) and the constitutional unit (a03) is 60:40 to 40:60.

6. The resist composition according to claim 1, wherein a content of the constitutional unit (a02) in the polymeric compound (A01) is in a range of 20% to 50% by mole based on 100% by mole of all constitutional units constituting the resin component (A01).

7. The resist composition according to claim 1, wherein a content of the compound (D1) is in a range of 3 to 20 parts by mass with respect to 100 parts by mass of the resin component (A1).

8. The resist composition according to claim 1, further comprising an acid generator component (B) that generates acid upon exposure, provided that the compound (D1) is excluded from the acid generator component (B).

9. A method of forming a resist pattern, comprising:
forming a resist film on a support using the resist composition according to claim 1;
exposing the resist film; and
developing the exposed resist film to form a resist pattern.

10. The method of forming a resist pattern according to claim 9, wherein the resist film is subjected to liquid immersion lithography.
